(19) United States
(12) Patent Application Publication
(10) Pub. No.: US 2026/0231695 A1
(43) Pub. Date: Aug. 6, 2026

(54) METHODS AND SYSTEMS FOR HIGHLY PARALLELIZED ENTANGLEMENT OVER A LARGE ATOM ARRAY

(71) Applicant: Atom Computing Inc., Berkeley, CA (US)

(72) Inventors: Mark STONE, Boulder, CO (US); Jonathan SIMON, Palo Alto, CA (US); Benjamin BLOOM, Boulder, CO (US)

(21) Appl. No.: 19/380,803

(22) Filed: Nov. 5, 2025

Related U.S. Application Data
(60) Provisional application No. 63/717,226, filed on Nov. 6, 2024.

(51) Int. Cl. H10N 99/00; G02B 21/00; G02B 21/32; G06N 10/40

(52) U.S. Cl. CPC H10N 99/05; G02B 21/0016; G02B 21/32; G06N 10/40

(57) ABSTRACT

Systems, methods, and computer-readable media for parallelized entanglement generation over an atom array may include an array of spatially distinct optical trapping sites, wherein an optical trapping site of the plurality of optical trapping sites comprises a qubit; an array of optical cavities, wherein a first cavity of the array of optical cavities comprises a first qubit, and wherein a second cavity of the array of optical cavities comprises a second qubit; and an optical assembly connecting the first array comprising the first qubit and the second array comprising the second qubit and forming an entangled state between the first qubit and the second qubit.

### CROSS-REFERENCE

This application claims the benefit of U.S. Provisional Patent Application No. 63/717,226, entitled “METHODS AND SYSTEMS FOR HIGHLY PARALLELIZED ENTANGLEMENT OVER A LARGE ATOM ARRAY,” filed on Nov. 6, 2024, which is incorporated by reference herein in its entirety.

### BACKGROUND

Quantum computers typically make use of quantum-mechanical phenomena, such as superposition and entanglement, to perform operations on data. Quantum computers may be different from digital electronic computers based on transistors. For instance, whereas digital computers require data to be encoded into binary digits (bits), each of which is always in one of two definite states (0 or 1), quantum computation uses quantum bits (qubits), which can be in superpositions of states.

In neutral-atom quantum computers or simulation devices, qubits may be encoded in optically trapped atoms. The qubit can be represented by a linear superposition of its two orthonormal basis states. The two orthonormal basis states are usually denoted as

$$\vert 0 〉 = [ \begin{matrix}1 \\ 0\end{matrix} ]$$

(the “zero state”) and

$$\vert 1 〉 = [ \begin{matrix}0 \\ 1\end{matrix} ]$$

(the “one state”). The two orthonormal basis states, {|0 [symbol] , |1 [symbol] }, together called the computational basis, span the two-dimensional linear vector (Hilbert) space of the qubit. The basis states can also be combined to form product basis states, e.g., |00 [symbol] , |01 [symbol] , |10 [symbol] , |11 [symbol] , each called a quantum register. Generally, n qubits are represented by a superposition state vector in 2ⁿ dimensional Hilbert space.

### SUMMARY

In an aspect, the present application provides a system for parallelized entanglement generation over an array, the system comprising: a first array of optical cavities comprising a first atom; a second array of optical cavities comprising a second atom; and an optical assembly configured to connect the first array of optical cavities comprising the first atom and the second array of optical cavities comprising the second atom and to form an entangled state between a first cavity of the first array of optical cavities comprising the first atom and a second cavity of the second array of optical cavities comprising the second atom.

In some embodiments, the entangled state is formed via pitch-and-catch entanglement. In some embodiments, the optical assembly comprises a plurality of prisms or a plurality of mirrors. In some embodiments, the optical assembly comprises one or more of a corner cube, a cat's eye retroreflector, a porro prism, a pentaprism, a right angle prism, a roof pentaprism, an amici prism, or a beam splitter cube. In some embodiments, the entangled state is formed by coupling a first output of the first cavity into a second output of the second cavity. In some embodiments, the optical assembly is a prism and the prism has a 180 degree deviation. In some embodiments, the prism is a single porro prism. In some embodiments, the prism is a corner cube or cat's eye. In some embodiments, the prism is a pentaprism and a right-angle prism. In some embodiments, the optical system is a mirror or a plurality of mirrors. In some embodiments, the mirror or the plurality of mirrors have a 180 degree deviation. In some embodiments, the optical system comprises a fiber optic or a plurality of fiber optics configured to direct the first output into the second output. In some embodiments, the first array of optical cavities and the second array of optical cavities are not parallel and the optical assembly is aligned to directly couple the first array of optical cavities to the second array of optical cavities. In some embodiments, the entangled state is formed via coincident photon detection entanglement. In some embodiments, the optical assembly comprises a plurality of prisms or a plurality of mirrors. In some embodiments, the optical assembly comprises one or more of a corner cube, a cat's eye retroreflector, a porro prism, a pentaprism, a right angle prism, a roof pentaprism, an amici prism, or a beam splitter cube. In some embodiments, the entangled state is formed by interfering a first output of the first cavity with a second output of the second cavity and directing the subsequently generated beams onto two photodetectors. In some embodiments, the optical assembly is a prism and the prism has a 90 degree deviation. In some embodiments, the prism is a roof pentaprism and a beam splitter cube. In some embodiments, the prism is an amici prism and a beam splitter cube. In some embodiments, the prism is a pentaprism and a beam splitter cube. In some embodiments, the optical system is a mirror or a plurality of mirrors. In some embodiments, the mirror or the plurality of mirrors have a 90 degree deviation. In some embodiments, the optical system comprises a fiber optic or a plurality of fiber optics configured to interfere the first output with the second output. In some embodiments, the first array of optical cavities and the second array of optical cavities are not parallel and the optical assembly is aligned to interfere the first array of optical cavities and the second array of optical cavities. In some embodiments, the first atom and the second atom are more than 10 array units apart, optionally, more than 100 array units apart. In some embodiments, the entanglement between the first cavity and the second cavity comprises pairwise entanglement between the first array of optical cavities and the second array of optical cavities. In some embodiments, the first array of optical cavities, the second array of optical cavities, or both is coupled to an optic fiber or fiber bundle and transported over a distance. In some embodiments, the first array of optical cavities and the second array of optical cavities are in separate vacuum chambers. In some embodiments, the first array of optical cavities and the second array of optical cavities are in separate quantum computers. In some embodiments, the first atom and the second atom are qubits. In some embodiments, the system further comprises an array of spatially distinct optical trapping sites, wherein a first optical trapping site of said array of optical trapping sites comprises said first atom, and wherein a second optical trapping site of said array of optical trapping sites comprises said second atom. In some embodiments, said first optical cavity comprises a first longitudinal mode, wherein said first longitudinal mode, when excited, forms said first optical trapping site of said array of optical trapping sites. In some embodiments, said second optical cavity comprises a second longitudinal mode, wherein said second longitudinal mode, when excited, forms said second optical trapping site of said array of optical trapping sites. In some embodiments, said array of spatially distinct optical trapping sites comprises a plurality of optical dipole traps. In some embodiments, the first optical trapping site and the second optical trapping site are located at a focal plane of the array of optical cavities. In some embodiments, a fluorescence emitted by at least one atom trapped in an optical trapping site of said array of optical trapping sites comprises is transmitted through an output optical element of an optical cavity array. In some embodiments, the array of optical cavities comprises: a plurality of mirrors positioned and oriented to form an outer optical cavity; a first lens system located within the outer optical cavity, the first lens system having a first output facing a first mirror of the plurality of mirrors, the first lens system having a first input facing a second mirror of the plurality of mirrors; and a second lens system located within the outer optical cavity, the second lens system having a second input facing the first input of the first lens system and a second output facing the second mirror. In some embodiments, the outer optical cavity supports a plurality of longitudinal modes that are transversely non-degenerate and form a corresponding plurality of foci that lie along a focal plane axially located between the first input of the first lens system and the second input of the second lens system. In some embodiments, the system further comprises a vacuum chamber, the focal plane lying within the vacuum chamber. In some embodiments, one or both of the first and second mirrors is located inside the vacuum chamber. In some embodiments, one or both of the first and second mirrors is located outside the vacuum chamber. In some embodiments, the plurality of mirrors include three or more mirrors forming a ring cavity; and wherein the ring cavity supports a plurality of longitudinal modes corresponding to a traveling wave that propagates around the ring cavity. In some embodiments, the first and second mirrors are first and second retroreflectors that face each other to form a Fabry-Perot cavity; and wherein the ring cavity supports a plurality of longitudinal modes corresponding to a standing wave that is resonant with the Fabry-Perot cavity. In some embodiments, the second lens system images the focal plane onto an imaging plane; and the second retroreflector is axially located near the imaging plane. In some embodiments, the second retroreflector comprises a polygonal mirror, a cat's-eye array, or a convex mirror array. In some embodiments, the first retroreflector comprises a planar mirror oriented perpendicular to an optical axis of the optical cavity.

In another aspect, the present disclosure provides a method of for parallelized entanglement generation over an array, the method comprising: (a) providing a first array of optical cavities, wherein a first cavity of the first array of optical cavities comprises a first atom; (b) providing a second array of optical cavities, wherein a second cavity of the second array of optical cavities comprises a second atom; and (c) forming an entangled state between said first atom and said second atom by optically connecting said first cavity comprising said first atom and said second cavity comprising said second atom using an optical assembly.

In some embodiments, said optical assembly comprises one or more of a corner cube, a cat's eye retroreflector, a porro prism, a pentaprism, a right-angle prism, a roof pentaprism, an amici prism, or a beam splitter cube. In some embodiments, (b) comprises pitch-and-catch entanglement. In some embodiments, the optical assembly comprises a plurality of prisms or a plurality of mirrors. In some embodiments, the optical assembly comprises one or more of a corner cube, a cat's eye retroreflector, a porro prism, a pentaprism, a right angle prism, a roof pentaprism, an amici prism, or a beam splitter cube. In some embodiments, (b) comprises coupling a first output of the first cavity into a second output of the second cavity. In some embodiments, the optical assembly is a prism and the prism has a 180 degree deviation. In some embodiments, the prism is a single porro prism. In some embodiments, the prism is a corner cube or cat's eye. In some embodiments, the prism is a pentaprism and a right-angle prism. In some embodiments, the optical system is a mirror or a plurality of mirrors. In some embodiments, the mirror or the plurality of mirrors have a 180 degree deviation. In some embodiments, the optical system comprises a fiber optic or a plurality of fiber optics configured to direct the first output into the second output. In some embodiments, the first plurality of cavities and the second plurality of cavities are not parallel and the optical assembly is aligned to directly couple the first plurality of cavities to the second plurality of cavities. In some embodiments, (b) comprises coincident photon detection entanglement. In some embodiments, the optical assembly comprises a plurality of prisms or a plurality of mirrors. In some embodiments, the optical assembly comprises one or more of a corner cube, a cat's eye retroreflector, a porro prism, a pentaprism, a right angle prism, a roof pentaprism, an amici prism, or a beam splitter cube. In some embodiments, (b) comprises interfering a first output of the first cavity with a second output of the second cavity and directing the subsequently generated beams onto two photodetectors. In some embodiments, the optical assembly is a prism and the prism has a 90 degree deviation. In some embodiments, the prism is a roof pentaprism and a beam splitter cube. In some embodiments, the prism is an amici prism and a beam splitter cube. In some embodiments, the prism is a pentaprism and a beam splitter cube. In some embodiments, the optical system is a mirror or a plurality of mirrors. In some embodiments, the mirror or the plurality of mirrors have a 90 degree deviation. In some embodiments, the optical system comprises a fiber optic or a plurality of fiber optics configured to interfere the first output with the second output. In some embodiments, the first plurality of cavities and the second plurality of cavities are not parallel and the optical assembly is aligned to interfere the plurality of cavities and the second plurality of cavities. In some embodiments, the first atom and the second atom are more than 10 array units apart. In some embodiments, the first atom and the second atom are more than 100 array units apart. In some embodiments, forming the entanglement between the first cavity and the second cavity comprises pairwise entanglement between the first array of optical cavities and the second array of optical cavities. In some embodiments, the method further comprises coupling the first array of optical cavities, the second array of optical cavities, or both to an optic fiber or fiber bundle and transported over a distance. In some embodiments, the first array of optical cavities and the second array of optical cavities are in separate vacuum chambers. In some embodiments, the first array of optical cavities and the second method of cavities are in separate quantum computers. In some embodiments, the first atom and the second atom are qubits. In some embodiments, the method further comprises an array of spatially distinct optical trapping sites, wherein a first optical trapping site of said array of optical trapping sites comprises said first atom, and wherein a second optical trapping site of said array of optical trapping sites comprises said second atom. In some embodiments, the method further comprises forming said first optical trapping site of said array of optical trapping sites at least in part by exciting a longitudinal mode of said first optical cavity. In some embodiments, the method further comprises forming said second optical trapping site of said array of optical trapping sites at least in part by exciting a longitudinal mode of said second optical cavity. In some embodiments, said array of spatially distinct optical trapping sites comprises a plurality of optical dipole traps. In some embodiments, the first optical trapping site and the second optical trapping site are located at a focal plane of the array of optical cavities. In some embodiments, the method further comprises transmitting through an output optical element of an optical cavity array a fluorescence emitted by at least one atom trapped in an optical trapping site of said array of optical trapping sites. In some embodiments, the array of optical cavities comprises: a plurality of mirrors positioned and oriented to form an outer optical cavity; a first lens system located within the outer optical cavity, the first lens system having a first output facing a first mirror of the plurality of mirrors, the first lens system having a first input facing a second mirror of the plurality of mirrors; and a second lens system located within the outer optical cavity, the second lens system having a second input facing the first input of the first lens system and a second output facing the second mirror. In some embodiments, the outer optical cavity supports a plurality of longitudinal modes that are transversely non-degenerate and form a corresponding plurality of foci that lie along a focal plane axially located between the first input of the first lens system and the second input of the second lens system. In some embodiments, the method further comprises a vacuum chamber, the focal plane lying within the vacuum chamber. In some embodiments, one or both of the first and second mirrors is located inside the vacuum chamber. In some embodiments, one or both of the first and second mirrors is located outside the vacuum chamber. In some embodiments, the plurality of mirrors include three or more mirrors forming a ring cavity; and wherein the ring cavity supports a plurality of longitudinal modes corresponding to a traveling wave that propagates around the ring cavity. In some embodiments, the first and second mirrors are first and second retroreflectors that face each other to form a Fabry-Perot cavity; and wherein the ring cavity supports a plurality of longitudinal modes corresponding to a standing wave that is resonant with the Fabry-Perot cavity. In some embodiments, the second lens system images the focal plane onto an imaging plane; and the second retroreflector is axially located near the imaging plane. In some embodiments, the second retroreflector comprises a polygonal mirror, a cat's-eye array, or a convex mirror array. In some embodiments, the first retroreflector comprises a planar mirror oriented perpendicular to an optical axis of the optical cavity.

In another aspect, the present disclosure provides a system for parallelized entanglement generation over an atom array, the system comprising: an array of spatially distinct optical trapping sites, wherein an optical trapping site of the plurality of optical trapping sites comprises a qubit; an array of optical cavities, wherein a first cavity of the array of optical cavities comprises a first qubit, and wherein a second cavity of the array of optical cavities comprises a second qubit; and an optical assembly connecting the first array comprising the first qubit and the second array comprising the second qubit and forming an entangled state between the first qubit and the second qubit.

In some embodiments, the optical assembly comprises a plurality of prisms or a plurality of mirrors. In some embodiments, the entangled state is formed via pitch-and-catch entanglement. In some embodiments, the entangled state is formed via coincident photon detection entanglement. In some embodiments, the first qubit and the second qubit are more than 10 array units apart, optionally, more than 100 array units apart.

In another aspect, the present disclosure provides a system for parallelized entanglement generation over an array, the system comprising: a first array of optical cavities comprising a first atom; a second array of optical cavities comprising a second atom; and an optical assembly configured to connect the first array of optical cavities comprising the first atom and the second array of optical cavities comprising the second atom by parallelized entanglement between the first array of optical cavities and the second array of optical cavities.

In another aspect, the present disclosure provides a method of for parallelized entanglement generation over an array, the method comprising: (a) providing a first array of optical cavities, wherein a first cavity of the first array of optical cavities comprises a first atom; (b) providing a second array of optical cavities, wherein a second cavity of the array of optical cavities comprises a second atom; and (c) forming parallelized entanglement between the first array of optical cavities and the second array of optical cavities.

Another aspect of the present disclosure provides a system comprising one or more computer processors and computer memory coupled thereto. The computer memory comprises machine executable code that, upon execution by the one or more computer processors, implements any of the methods above or elsewhere herein.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

FIG. 1 shows a computer control system that is programmed or otherwise configured to implement methods provided herein;

FIG. 2 shows an example of a system for performing a non-classical computation;

FIG. 3A shows an example of an optical trapping unit;

FIG. 3B shows an example of a plurality of optical trapping sites;

FIG. 3C shows an example of an optical trapping unit that is partially filled with atoms;

FIG. 3D shows an example of an optical trapping unit that is completely filled with atoms;

FIG. 4 shows an example of an electromagnetic delivery unit;

FIG. 5 shows an example of a state preparation unit;

FIG. 6 shows a flowchart for an example of a first method for performing a non-classical computation;

FIG. 7 shows a flowchart for an example of a second method for performing a non-classical computation;

FIG. 8 shows a flowchart for an example of a third method for performing a non-classical computation;

FIG. 9 shows an energy level structure for single-qubit and multi-qubit operations in strontium-87;

FIG. 10 shows an example method for error corrected non-classical computation;

FIG. 11 shows an example of a system for error corrected non-classical computing that is programmed or otherwise configured to implement methods provided herein;

FIG. 12 shows an example process for performing continuous, non-classical computation;

FIG. 13A shows example of a plurality of mirrors configured to provide a plurality of optical cavities;

FIG. 13B shows example of a spacer with a complicated set of cavities to be aligned, including example views and images of Rayleigh scattered light taken from each view;

FIG. 14 provides a non-limiting example of a cavity array, in accordance with some embodiments herein;

FIG. 15A provides a first embodiment for a polygonal mirror, in accordance with some embodiments herein;

FIG. 15B provides a second embodiment for a polygonal mirror, in accordance with some embodiments herein;

FIG. 15C provides an example of a retroreflector assembly, in accordance with some embodiments herein;

FIG. 16 provides an alternate embodiment of a cavity array, in accordance with some embodiments herein;

FIG. 17 provides an example of an array of cavities, in accordance with some embodiments herein;

FIG. 18 provides a non-limiting example of a system for highly parallelized entanglement, in accordance with some embodiments herein;

FIG. 19A illustrates an example of a pitch-and-catch entanglement scheme, in accordance with some embodiments herein;

FIG. 19B illustrates an alternate view of a pitch-and-catch entanglement scheme, in accordance with some embodiments herein

FIG. 20A illustrates an example of a coincident photon detection entanglement scheme, in accordance with some embodiments herein;

FIG. 20B illustrates an alternate view of a coincident photon detection entanglement scheme, in accordance with some embodiments herein; and

FIG. 21 provides a non-limiting example of a method for highly parallelized entanglement, in accordance with some embodiments herein.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

This disclosure hereby incorporates by reference for all purposes, International Patent Publication Nos. WO2023/220415 and WO2023/192167.

### Overview

Generating entanglement between atoms or qubits can provide significant advantages in non-classical computing. In some cases, entangling atoms or qubits allows their states to be correlated in a way that increases the computational power provided by a non-classical computer. Entanglement may be used in quantum algorithms to leverage the unique properties of non-classical computers to solve computationally intensive or intractable problems. Additionally, entanglement may be used in error correction schemes to improve coherence of logical qubits.

When the quantum state of two or more atoms or qubits are linked, such that a change in the state of one is linked to the change in state of another, we say these atoms or qubits are entangled. In many cases, entanglement may only be formed between adjacent atoms or qubits, as the conditions required to entangle their quantum states require specific interactions between them. Additionally, the entangled state is highly susceptible to collapse due to noise or interference, so moving entangled atoms or qubits to other regions of a non-classical computer or array can risk disrupting the entangled state.

In many cases, increasing the computational power of non-classical computers involves increasing the number of atoms or qubits available to perform computational tasks. In some cases, this involves large arrays of atoms or qubits, which can be separated by large distances or located in distinct regions of a non-classical computer. In order to perform certain computations or error correction schemes, it may be necessary to entangle atoms or qubits which are not adjacent to each other in these arrays or are located in different regions of a non-classical computer or network of non-classical computers.

Recognized herein is the need for systems and methods which can generate entanglement between non-adjacent atoms or qubits of an array.

### Systems and Methods for Optical Cavity Arrays

In an aspect, provided herein are systems and methods for optical cavity arrays. In some cases, optical cavity arrays disclosed herein may be used to create a plurality of longitudinal modes within an optical cavity. These longitudinal modes may be transversely separated from each other, which can provide the advantage that each longitudinal mode may not be coupled to another. Using a system of optical devices, these transversely separated longitudinal modes may be arranged to form a plurality of transversely separated foci in a focal plane within the optical cavity. These transversely separated longitudinal modes forming the plurality of transversely separated foci are transversely non-degenerate.

In some cases, each foci of the plurality of transversely separated foci may be used as an optical trap, described herein, or optical tweezers, described herein. In some cases, each foci of the plurality of transversely separated foci may be used to trap an atom described herein. In some cases, the plurality of transversely separated foci may be thought of as forming an optical tweezer array, described herein.

In some cases, the plurality of optical foci may be transversely separated to form an array. In some examples, the plurality of optical foci may be transversely separated by a distance of a few microns or more.

In some examples, the plurality of optical foci may be separated by about one micron or less. In some examples, the plurality of optical foci may be separated by about one micron to about 10 microns and increments therein. In some examples, the plurality of optical foci may be separated by about 10 microns. In some examples, the plurality of optical foci may be separated by about 10 microns to about 100 microns and increments therein. In some examples, the plurality of optical foci may be separated by about 100 microns. In some examples, the plurality of optical foci may be separated by about 100 microns or more.

In some cases, the systems and methods for optical cavity arrays, described herein, can generate an array of optical foci without the aberration sensitivity and resonator stability limitations which may be present when an array of optical foci is generated using a degenerate or “imaging” resonator. In some cases, systems and methods for optical cavity arrays, described herein, provide an array of optical foci having properties as if each optical foci was generated by its own optical resonator or optical cavity, each having its own unique path. Advantageously, systems and methods herein may provide an array of optical foci as if each optical foci was generated by its own optical resonator or optical cavity, while using bulk components.

In some cases, the systems and method for optical cavity arrays, described herein, can generated an array of optical foci extending transverse to the optical direction in one direction or two dimensions. In some cases, each transversely separated longitudinal mode forming the plurality of optical foci of the array is independently stable. Each transversely separated longitudinal mode may be operated far from any mode degeneracies, which may prevent susceptibility to mode mixing or aberration-induced instabilities, in some cases.

An optical cavity array includes a plurality of mirrors that form an optical cavity, a first lens system located within the optical cavity, and a second lens system located within the optical cavity. The first lens system has a first output facing a first mirror of the plurality of mirrors and a second output facing a second mirror of the plurality of mirrors. The second lens system has a second input facing the first input and a second output facing the second mirror. The first and second lens systems are configured such that the optical cavity supports longitudinal modes that are transversely non-degenerate, forming spatially separated waists that lie along a focal plane that is axially located between the first and second inputs. When the longitudinal modes are excited, the waists may be used as an array of optical dipole traps.

### Examples of Cavity Quantum Electrodynamics

Cavity quantum electrodynamics (cQED) is the study of the interaction between light and matter inside a resonant cavity. The matter may be an atom, ion, molecule, or other type of quantum particle or emitter that couples to light. The quantum particle may be trapped near the waist of an excited mode of the cavity, giving rise to intracavity optical tweezers.

In cavity quantum electrodynamics (cQED), it is frequently ideal to engineer the single-particle cooperativity n to be as large as possible. Defined as i=g2/if, the cooperativity 77 quantifies the competition between (i) coherent information exchange at rate g between a cavity and an atom (e.g., a neutral atom or ion) located within the cavity and (ii) the decoherence rates r and K of the atom and cavity, respectively. Increasing i increases the photon collection probability Pc=77/(1+n) that the atom emits into (or absorbs from) a mode of the cavity as opposed to free space. Increasing y also reduces the failure rate 2m/y1/2 of cavity-mediated quantum information transfer between two atoms trapped in separate optical cavities.

Another way to express the cooperativity is n0.2 A2/wd, where is the cavity finesse, w0 is the minimum diffraction-limited waist of the cavity mode, and A is the wavelength of the atomic transition and cavity resonance. The finesse .F can be interpreted as the number of round trips that light in the optical cavity makes before lost due to absorption or transmission through a cavity mirror. This alternative expression for i can be interpreted geometrically: the resonant cross-section that an atom presents for absorption of light is—A2 and the area of the cavity mode going past the atom is—4. Therefore, for each pass of the cavity light past the atom, the absorption probability is—A.2/wd. The optical cavity simply enhances this single-pass absorption probability by the number of passes T.

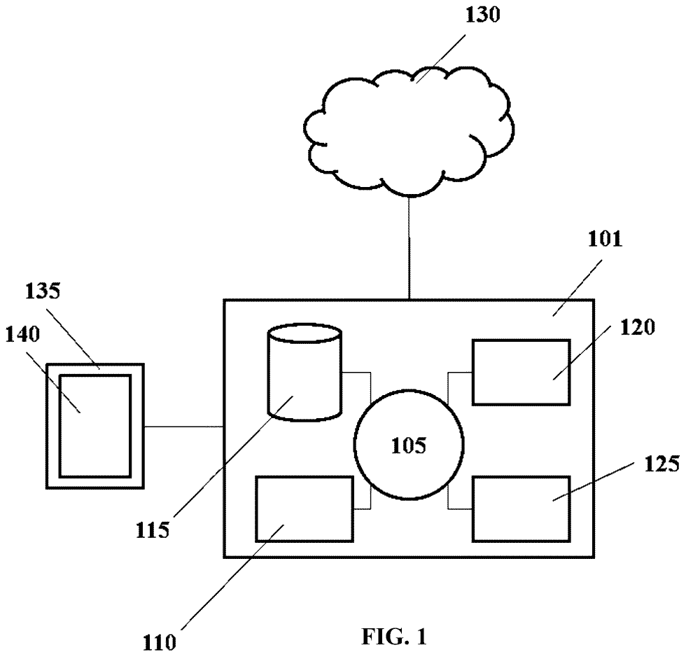

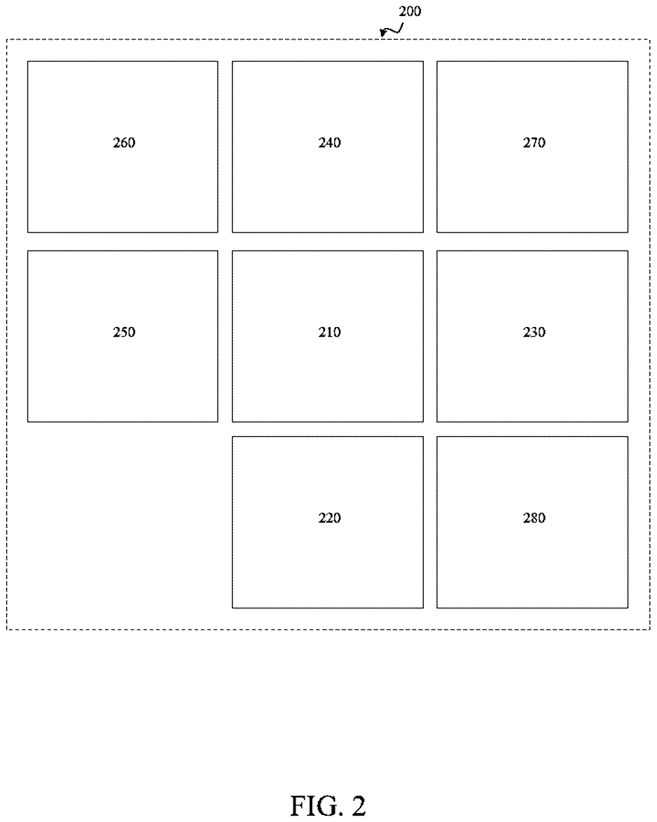

Prior-art optical cavities used for cQED achieve a high cooperativity n by employing a relatively large waist wo and very high finesse F. Such optical cavities (e.g., see FIGS. 1 and 2) are typically fabricated using concave mirrors having very high reflectivities, typically greater than 99.999%. The highest finesses of nearly 106 have been achieved by improving superpolishing and dielectric coatings of these mirrors. Due to their high finesse Y, these prior-art optical cavities are challenging to align and stabilize. Furthermore, specialized handling techniques are needed to prevent airborne particulate matter (e.g., dust) from landing on the mirror surfaces; such contamination reduces the finesse .T by increasing scatter. Similarly, mounting the optical cavity inside a vacuum chamber, as needed for atom trapping, puts stringent cleanliness requirements on the vacuum system to prevent contaminants (e.g., oil) from landing on the mirrors.

One aspect of the present embodiments is the realization that increasing the single-particle cooperativity 71 places no significant restrictions on the cavity length L. The idea that cQED requires a small mode volume V is a misnomer that arose by writing the Purcell factor as Fp=3A3 Q/(47-1-2V). The Purcell factor Fp quantifies how much an emitter's spontaneous emission rate is enhanced when it is located inside a resonant cavity having quality factor Q. The expression makes small mode volume V seem advantageous to increasing the Purcell factor Fp, but ignores the fact that the Q drops as the cavity length L decreases. What is relevant for cQED is actually the finesse .F=Qc/2Lfc, where L is the resonant frequency of the cavity mode. When written in terms of the finesse and assuming that the mode volume V-L4, the Purcell factor Fp is identical, up to unit factors, to the single-particle cooperativity ij and therefore only depends on .T, A, and wo. Thus, for a fixed value of A there are only two independent experimental parameters that control the cooperativity ij: the finesse P and the waist wo.

The present embodiments use intracavity lenses to achieve a waist wo that is smaller than that achieved with the prior-art optical cavities described above. Since i«1/wd, the smaller waist wo results in a significantly larger cooperativity i that can be used to lower the finesse F. For example, the optical cavity can generate a waist of w0 r=: 500 nm at A=780 nm (the D2 transition for Rb), yielding a cooperativity of n=9.4 for a finesse of only Y=20. This value of the cooperativity i is so large that an atom trapped near the waist emits a photon ten times faster into the optical cavity than into free space. When the atom is implemented as a qubit, the emitted photon has a greater-than-90% change of being collected by the optical cavity. Furthermore, due to the lower finesse .F, the cavity length L only needs to be stabilized to within A/(2F)=A/20, making the optical cavity easier to align and stabilize than prior-art optical cavities. Also due to the lower finesse Y, additional optical components can be placed within the cavity without significantly degrading the finesse F. The lower finesse also eases requirements on handling, assembly, and vacuum cleanliness since an increase in optical scatter off of surface contaminants no longer significantly degrades the finesse .F.

The increase in photon collection probability Pc will substantially improve state detection of tweezer-array apparatus and cQED setups. Accordingly, the present embodiments may be used to create a photonic-matter interface that efficiently converts quantum information between photonic qubits and matter-based qubits (e.g., trapped ions, neutral atoms, defects in diamond, etc.). Such an optical coupling system could increase the number of qubits in a quantum computer, thereby improving qubit scaling. For example, the optical coupling setup could be used to efficiently transfer optical information between spatially disparate ion traps, thereby enabling quantum computing beyond the melting-size limit of a single ion crystal.

Another application of the present embodiments is sensing with color centers. Here, the optical cavity improves light gathering, thereby enabling faster, more accurate readout of the color center state. Such a scanning-cavity microscope would rely upon the a small waist Ivo rather than high finesse, greatly relaxing material constraints. As another application, the optical cavity could be used for an orders-of-magnitude speed-up in state detection for atom-array quantum simulators and computers, thereby enabling optically-mediated non-local gates and real-time feedback-based error correction.

### Systems for Optical Cavity Arrays

In some cases, systems and methods for highly parallelized entanglement over a large atom array, described herein, provides systems for optical cavity arrays. Systems and methods for optical cavity arrays are described in, for instance, commonly owned International Patent Publication No. WO2023/220415, which is incorporated by reference herein in its entirety for all purposes.

In some embodiments, an optical cavity array has an array of foci that are spatially separated by a few microns near the focal plane of an imaging system with a high numerical aperture (NA). In some cases, this configuration may advantageously avoid the aberration sensitivity and resonator stability limitations present when many foci are generating with a “degenerate” resonator (also known as an “imaging resonator”). Each foci may be thought of as being generated by its own optical resonator, or cavity, that has its own unique path. However, most (if not all) of the optical components are bulk, in some cases. These optical-resonator paths form an array that extends transversely to the optical axis in either one or two dimensions. Each optical-resonator path of the array is independently stable and may be operated far from any mode degeneracies that would render it susceptible to mode-mixing, aberration-induced instabilities, or both.

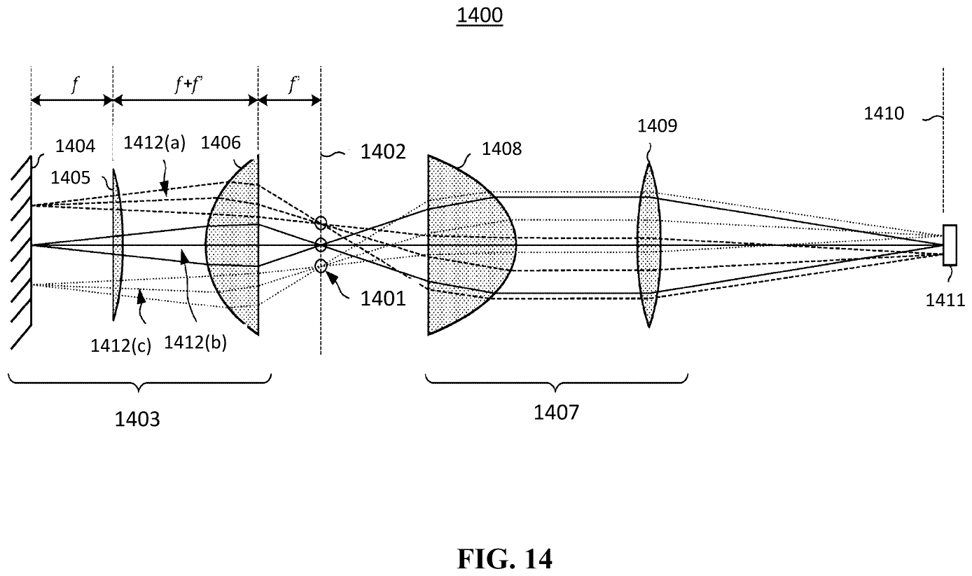

A non-limiting example of a cavity array 1400 is provided in FIG. 14. The optical cavity array 1400 may be used to generate an array of foci 1401, or waists, that are located on an focal plane 1402. In some cases, the foci 1401 extend along x. which is perpendicular to the optical axis (which is parallel z). For clarity in FIG. 14, only three foci 1401 are shown. However, there may be only two foci 1401, or more than three foci 1401, without departing from the scope hereof. While the foci 1401 are shown extending along x, the foci 1401 may alternatively or additionally extend along y. For clarity, each of the foci 1401 is enclosed by a small circle.

In some cases, the optical cavity array 1400 includes a high-NA retroreflector 1403 that is located on one side of the focal plane 1402. In one example, the high-NA retroreflector 1403 includes a planar retroreflecting mirror 1404, a first lens 1405 with a focal length f, and a first high-NA lens 1406 with a focal length f. The first lens 1405 may bilocated one focal length f in front of the mirror 1404 (i.e., parallel to the optical axis in the +z direction). The first lens 1405 may be a plano-convex lens, as shown in FIG. 14, or another type of lens (e.g., aspheric, bi-convex lens, etc.). The first high-NA lens 1406 may be located one focal length f in front of (i.e., in the +z direction) the first lens 1405. The first high-NA lens 1406 may be an aspheric lens, microscope objective, compound lens systems (e.g., telescope), or another type of lens. Herein, the term “high NA” may mean values of the NA greater than or equal to about 0.5. However, the NA of any lens may be less than 0.5 without departing from the scope hereof.

In some cases, the optical cavity array 1400 also includes a finite-conjugate-ratio imaging system 1407 that is located on the other side of the focal plane 1402 from the high-NA retroreflector 1403. In some cases, the imaging system 1407 includes a second high-NA lens 1408 and a second lens 1409 that cooperate to image the focal plane 1402 onto an imaging plane 1410. In some cases, the optical cavity array 1400 also includes a retroreflector 1411 whose reflective face (or faces, in some embodiments) reflects the images back on themselves. The retroreflector 1411 may be positioned near the imaging plane 1410, but does not exactly coincide with it in some cases.

In FIG. 14, the formation of the foci 1401 may be illustrated by ray tracing. One of the foci 1401 is formed from rays illustrated as dashed lines. These rays indicate a first mode 1412(a) of the optical cavity array 1400 whose waist is said one of the foci 1403. A second of the foci 1401 may be formed from rays illustrated as solid lines (this foci lies on the optical axis). These rays indicate a second mode 1412(b) of the optical cavity array 1400 whose waist is said second of the foci 1401. A third of the foci 1401 may be formed from rays illustrated as dotted lines. These rays indicate a third mode 1412(c) of the optical cavity array 1400 whose waist is said third of the foci 1401. Thus, the terms “waist” and “focus” may be synonymous herein. It should be understood that the rays shown in FIG. 14 are for illustration only, and do not fully illustrate the shape (i.e., intensity distribution) of the modes 1412.

The modes 1412 of the optical cavity array 1400 can be excited by transmitting light through the mirror 1404, through the retroreflector 1411, or both. The light may be a single monochromatic laser beam, or several monochromatic laser beams that are transversely displaced from each other. The light may be any light source, described herein. In some cases, light in the optical cavity array 1400 can also leak out by transmitting through the mirror 1404, the retroreflector 1411, or both. Alternatively or additionally, light can be coupled out of the optical cavity array 1400 with a beam sampler. This beam sampler may be placed in a low-NA region (i.e.,) to minimize aberrations, in some cases.

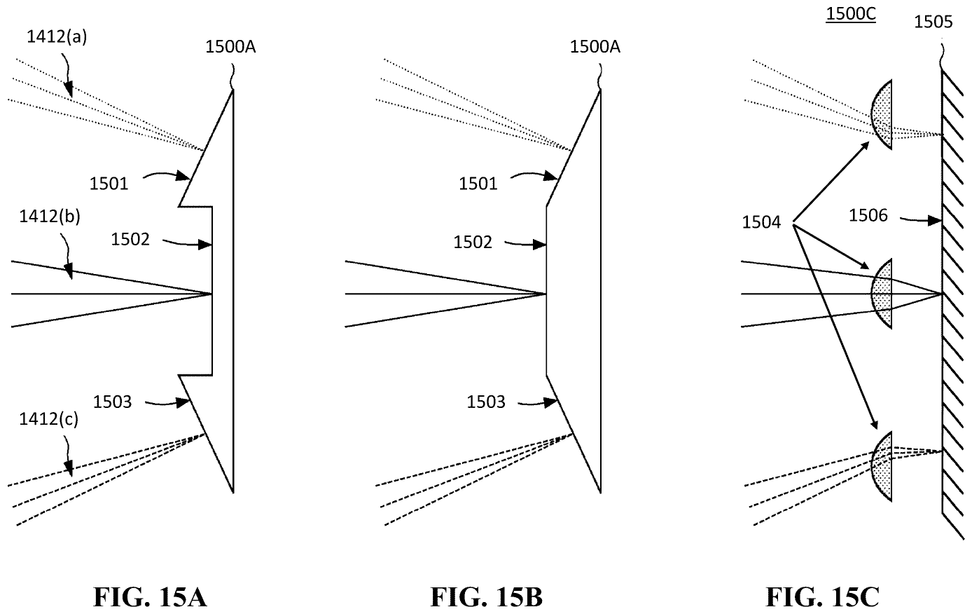

FIGS. 15A-15C provide non-limiting examples of polygonal mirrors, in accordance with some embodiments of the disclosure. FIG. 15A depicts a side view of a polygonal mirror 1500A that is one example of the retroreflector 1411. The polygonal mirror 1500A has a first face 1501 that forms a first oblique angle with the optical axis, a second face 1502 that is perpendicular to the optical axis, and a third face 1503 that forms a second oblique angle with the optical axis. The faces 1501, 1502, and 1503 may be positioned to retroreflect light thereon back onto itself. More specifically, the first oblique angle may be selected such that the third mode 1412(c) retroreflects off the first face 1501. Similarly, the second oblique angle may be selected such that the first model 1412(a) retroreflects off the third face 1503.

FIG. 15B depicts a side view of an alternative embodiment of a polygonal mirror 1500B that is similar to the polygonal mirror 1500A except that the second face 1502 is not recessed. Specifically, the second face 1502 is located farther in the +x direction in the polygonal mirror 1500A, as compared to the polygonal mirror 1500B. In some cases, the polygonal mirror 1500B may be easier to fabricate than the polygonal mirror 1500A.

FIG. 15C depicts a side view of a cat's-eye retroreflector array 1500C that is another example of the retroreflector 1411 of FIG. 14. In some cases, the cat's-eye array 1500C includes an array of microlenses 1504 that are all located at the same position along the optical axis (i.e., along z), but different transverse positions. In some cases, there is one microlens 1504 for each of the modes 1412. In some cases, the microlenses 1504 have the same focal length f″. In some cases, the cat's-eye array also includes a planar mirror 1505 located behind the microlenses 1504. In some cases, the planar mirror 1505 is positioned such that a reflective face 1506 of the planar mirror 1505 is approximately one focal length f″ away from the microlenses 1504.

In another embodiment, the cat's-eye retroreflector 1500C may be implemented with a spherical micromirror array (i.e., a one or two dimensional array of curved mirrors fabricated on a common substrate). One way to fabricate this spherical micromirror array would be to deposit a dielectric high-reflectivity coating on the spherical surface of a microlens array. In this case, each micromirror is convex.

In some cases, the polygonal mirror 1500A, polygonal mirror 1500B, or cat's-eye array 1500C may be replaced with a single planar mirror if said mirror is placed precisely in the image plane 1410. While, in some cases, this may provide a simpler embodiment for fabricating the optical cavity array 1400, it may a fully degenerate cavity that is highly susceptible to mode mixing and all variety of aberrations that can mix the resonator modes, in some cases.

In another embodiment, the retroreflector 1411 may be a curved mirror. For example, the curved mirror may be a spherical concave mirror that faces the second lens 1409 and has radius of curvature denoted ROC. Assuming the second lens 1409 has a focal length f2, the distance between the curved mirror and the second lens 1409 may be approximately f2+ROC. This arrangement creates a stable array of foci 1401. Assuming ROC=1 cm, the diameter of the resulting field of view is approximately 200 μm, limited by the spherical aberrations of the curved mirror. Advantageously, the optical cavity array 1400 may be simpler and less expensive to fabricate with this curved mirror instead of the polygonal mirror 1500A, polygonal mirror 1500B, or cat's eye retroreflector 1500C, in some cases.

Depending upon the quality of the optics, it may be necessary to individually tune the resonators (into resonance with atoms for example). In this case a low-loss transmissive phase modulator could be installed near the image plane 1410 (i.e., between the image plane 1410 and second lens 1409). Alternatively, once the necessary phase shifts are determined, a custom antireflection-coated phase plate could be installed within the cavity, which would advantageously incur lower optical loss as compared to the phase modulator.

When the optical cavity array 1400 is excited with light (as described above), an optical dipole trap is formed at each of the foci 1401. The resulting array of optical dipole traps (also referred to as an array of optical tweezers) may be used to trap cold or ultracold atoms therein. Advantageously, this array of optical dipole traps is located far any physical surface (e.g., the high-NA lenses 1406 and 1408), thereby ensuring that cold atoms will not be ejected upon colliding with such a surface. To further facilitate cold-atom trapping, the optical cavity array 1400 may be arranged such that the array of foci 1401 is located inside in an ultra-high vacuum environment. However, some conventional vacuum chambers are so large that the high-NA lenses 1406 and 1408 cannot be placed outside of the vacuum chamber, in some cases, as they will then be too far apart from each other to produce foci 1401 (i.e., waists) that are tight enough for the application at hand. In such cases, the lenses 1406 and 1408 can be brought closer to each other by mounting both of them inside the vacuum chamber. In some cases, additional components of the optical cavity array 1400 may be mounted inside the vacuum chamber. Vacuum windows may be used to on the vacuum system to allow light to pass therethrough.

Once the atoms spatially trapped, they may then be driven, measured, coupled, or probed, as needed for the application at hand. The close proximity of the optical dipole traps to each other advantageously allows the atoms to directly couple to each other. Such coupling between individual trapped atoms could be used, for example, to construct highly parallelized entanglement, as described herein.

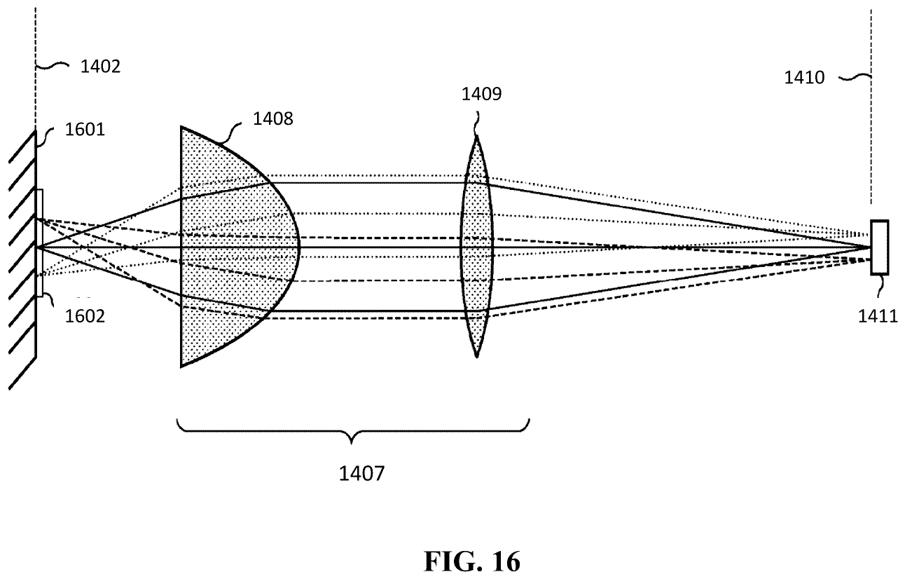

FIG. 16 provides a side view of an alternate embodiment of an optical cavity array 1600 that is similar to the optical cavity array 1400 except that the high-NA retroreflector 1403 has been replaced with a planar mirror 1601 whose optically reflective surface coincides with the focal plane 1402. In some cases, the foci 1401 may be located at the reflective surface of the mirror 1601, which coincides with the focal plane 1402. In some cases, affixed to the front face of the planar mirror 1601 is a sample of non-linear emitters 1602. Examples of such non-linear emitters 1602 include, but are not limited to, rare-earth ions, quantum dots, and solid-state color centers (e.g., silicon vacancy centers in diamond, nitrogen vacancy centers in diamond, etc.). Advantageously, no trapping techniques (e.g., magnetic or optical trapping of atoms) are needed to confine the emitters 1602 at this position, in some cases.

In embodiments, multiple quantum emitters in any of the present embodiments can be coupled to each other by employing beam steering optics (e.g., near the cat's-eye array 1500C) to couple the modes 1412 together.

### Example of Parallelized Entanglement Schemes Over an Atom Array

In some cases, the present disclosure provides systems and methods to collect photons with high probability across an array. Collecting photons with high probability across an array may advantageously allow systems and methods herein to generate entanglement between separated pairs of atoms or qubits in an array. In neutral atom quantum computers, entanglement may be generated by two-qubit gates that act on closely spaced atoms or qubits (often nearest neighbors), so that generating long-distance entanglement requires either a long series of nearest-neighbor gates or transporting distant atoms or qubits near to each other. In other examples, generating entanglement may be accomplished between distant atom or qubit array modules by coupling each atom to one microcavity in a cavity array, described herein, then connecting the two distant cavity arrays via an optical assembly, described herein.

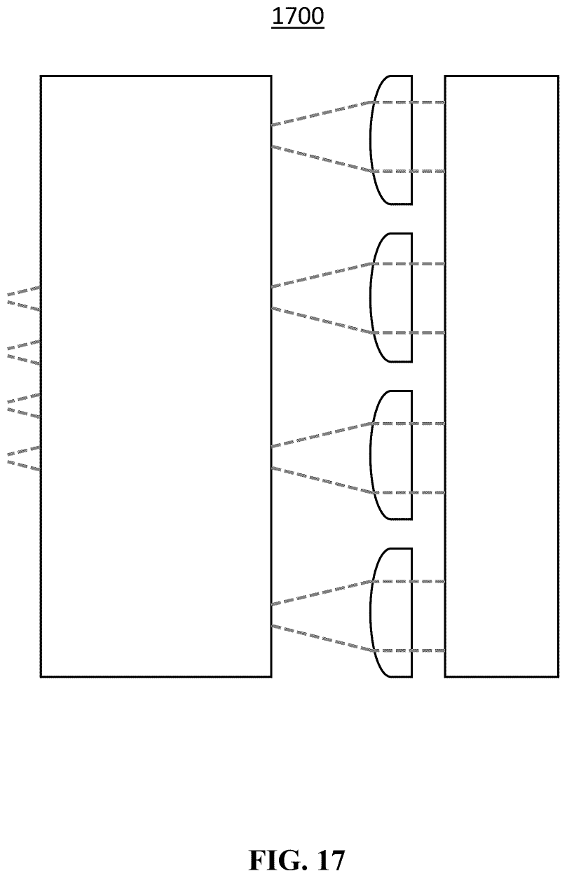

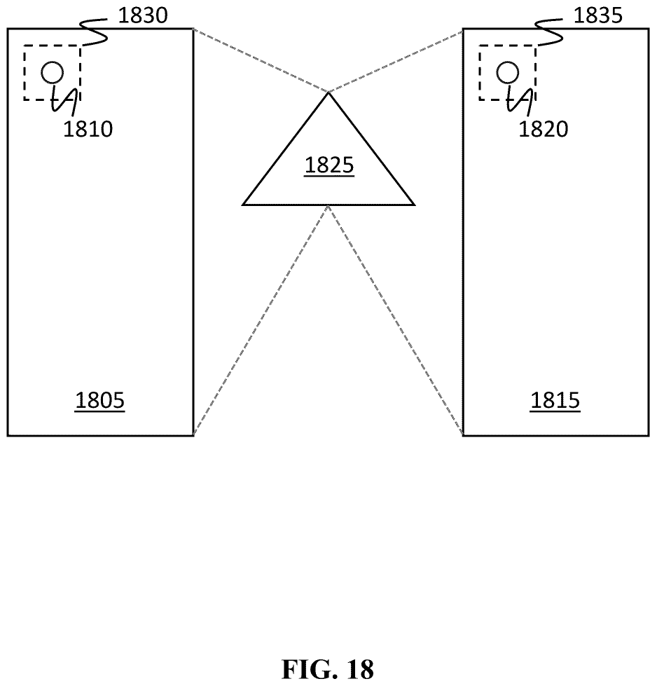

FIG. 17 illustrates an example optical setup for a system of microcavity arrays 1700, in accordance with some embodiments herein. An example of cavity arrays 1700 which may be use in the systems and method disclosed herein is described at WO2023/220415, which is incorporated by reference for all purposes. In some examples, FIG. 17 may be an example of any microcavity array disclosed in WO2023/220415. In some cases, the microcavity array may be the optical cavity array 1400 or the optical cavity array 1600 herein. As shown, each microcavity of 1700 emits into a beam on the right side of the figure, creating a 2D array of beams.

In some cases, systems and methods for highly parallelized entanglement, described herein, provide a system for parallelized entanglement generation 1800. In some cases, the system for parallelized entanglement generation 1800 comprises a first array of optical cavities 1805 comprising a first atom 1810, and a second array of optical cavities 1815 comprising a second atom 1820, and an optical assembly 1825, configured to connect the first array of optical cavities 1805 comprising the first atom 1810 and the second array of optical cavities 1815 comprising the second atom 1820 and to form an entangled state between a first cavity 1830 of the first array of optical cavities 1805 comprising the first atom 1810 and a second cavity 1835 of the second array of optical cavities 1815 comprising the second atom 1820.

In some cases, the optical assembly 1825 is configured to optically connect the first array of optical cavities 1805 and the second array of optical cavities 1820 so that entangled Bell pairs can be generated across the array in a single step. The form of the optical assembly 1825 may be different for “pitch-and-catch” style Bell pair generation, versus “coincident photon detection” style, and within each group different optical elements can be used to change the connectivity.

In some cases, the entangled state between the first cavity 1830 of the first array of optical cavities 1805 comprising the first atom 1810 and the second cavity 1835 of the second array of optical cavities 1815 comprising the second atom 1820 may be formed by pitch-and-catch style entanglement. In some cases, the entangled state between the first cavity 1830 of the first array of optical cavities 1805 comprising the first atom 1810 and the second cavity 1835 of the second array of optical cavities 1815 comprising the second atom 1820 may be formed by any other form of entanglement.

In some embodiments, the first array of optical cavities 1805, the second array of optical cavities 1815, the first cavity 1830, and the second cavity 1835 may be microcavity arrays, described herein. In some cases, the first array of optical cavities 1805 and the second array of optical cavities 1815 comprise the same array of optical cavities. In some cases, the first array of optical cavities 1805 and the second array of optical cavities 1815 are not parallel, and the optical assembly 1825 is aligned to directly couple the first array of optical cavities 1805 and the second array of optical cavities 1815.

In the case where entanglement is formed between the first cavity 1830 comprising the first atom 1810 and the second cavity 1835 comprising the second atom 1820 using pitch-and-catch entanglement, the optical assembly 1825 may comprise a specific configuration of optical elements to create a 180° deviation between optical devices about some symmetry plane of the optical assembly 1825. In some examples, the optical assembly 1825 comprises a plurality of prisms and a plurality of mirrors. In some examples, the optical assembly 1825 comprises one or more of a corner cube, a cat's eye retroreflector, a porro prism, a pentaprism, a right-angle prism, a roof pentaprism, an amici prism, or a beam splitter cube. In some examples, the optical assembly 1825 comprises a plurality of mirrors which may perform a 180° deviation about some symmetry plane of the optical assembly 1825.

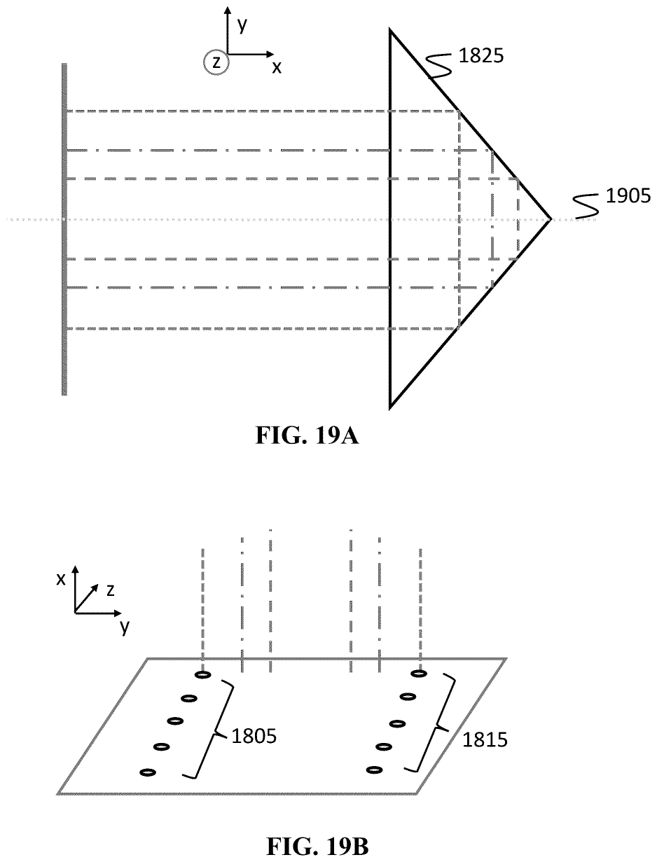

FIGS. 19A-19B illustrates one embodiment of a pitch-and-catch entanglement scheme 1900 implementing systems and method of the present disclosure. As shown, the output of the first array of optical cavities 1805 may be directed to the input of the second array of optical cavities 1815. In one non-limiting example as shown, the optical assembly 1825 comprises a single Porro prism to connect each cavity with its inverse about a horizontal line 1905 (parallel to the x-axis).

In one example, for pitch-and-catch entanglement, the output of a first cavity 1830 may be directly coupled to the input of a second cavity 1835. In some cases, this can be implemented for an entire (or substantially entire) array of optical cavities simultaneously (or substantially simultaneously) by directing the output of the array into an optical assembly 1825 with 180° deviation. This may be used to form parallelized entanglement across a plurality of cavities, where parallelized entanglement refers to relating the cavities of a plurality of cavities using one or more symmetry operations. In one example of parallelized entanglement, the one or more symmetry operations include a pairwise matching of cavities across a plane 1905 of the optical assembly 1825. For example, a Porro prism may connect each cavity with its inversion about a plane defined by the prism 1905 (see, for example, FIG. 19A-19B), while a corner-cube retroreflector (or cat's-eye retroreflector) may connect each microcavity with one rotated 180 degrees around the center of the retroreflector. Either of these cases may connect cavities on one edge of an array of cavities on the opposite edge, and the atoms inside can be entangled using a pitch-and-catch entanglement.

In some cases, the optical assembly 1825 is a prism with a 180° deviation. Some non-limiting examples of prisms with a 180° deviation include a porro prims, a corner cube, a cat's eye, a pentaprism and a right-angle prism. In some cases, the optical assembly 1825 is a plurality of mirrors with a 180° deviation.

In some cases, the entangled state between the first cavity 1830 of the first array of optical cavities 1805 comprising the first atom 1810 and the second cavity 1835 of the second array of optical cavities 1815 comprising the second atom 1820 may be formed by coincident photon detection. In some cases, the entangled state between the first cavity 1830 of the first array of optical cavities 1805 comprising the first atom 1810 and the second cavity 1835 of the second array of optical cavities 1815 comprising the second atom 1820 may be formed by any other form of entanglement.

In the case where entanglement is formed between the first cavity 1830 comprising the first atom 1810 and the second cavity 1835 comprising the second atom 1820 using coincident photon detection entanglement, the optical assembly 1825 may comprise a specific configuration of optical elements to create a 90° deviation between optical devices about some symmetry plane 1905 of the optical assembly 1825. In some examples, the optical assembly 1825 comprises a plurality of prisms and a plurality of mirrors. In some examples, the optical assembly 1825 comprises one or more of a corner cube, a cat's eye retroreflector, a porro prism, a pentaprism, a right-angle prism, a roof pentaprism, an amici prism, or a beam splitter cube. In some examples, the optical assembly 1825 comprises a plurality of mirrors which may perform a 90° deviation about some symmetry plane of the optical assembly 1825.

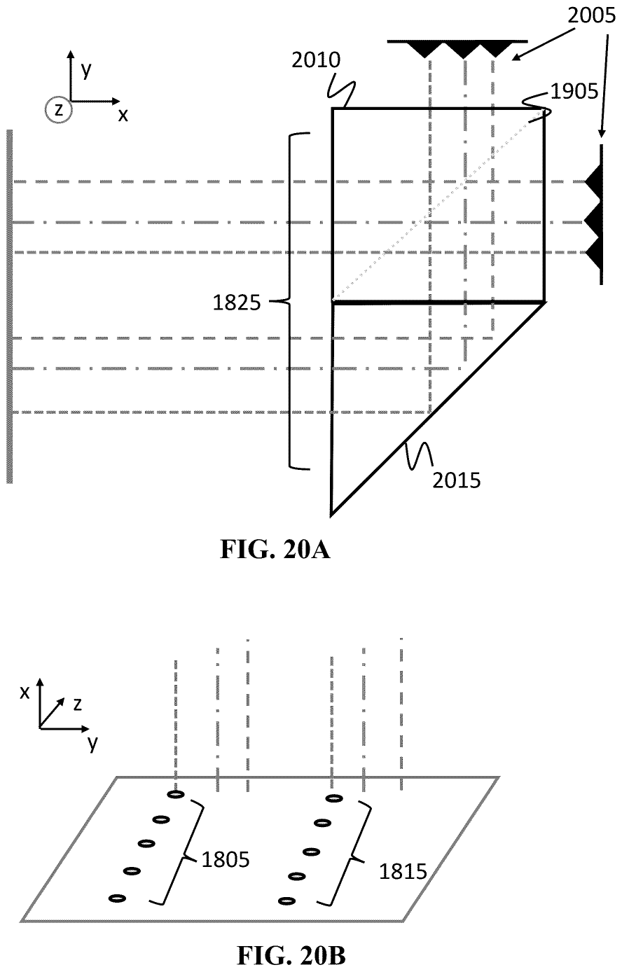

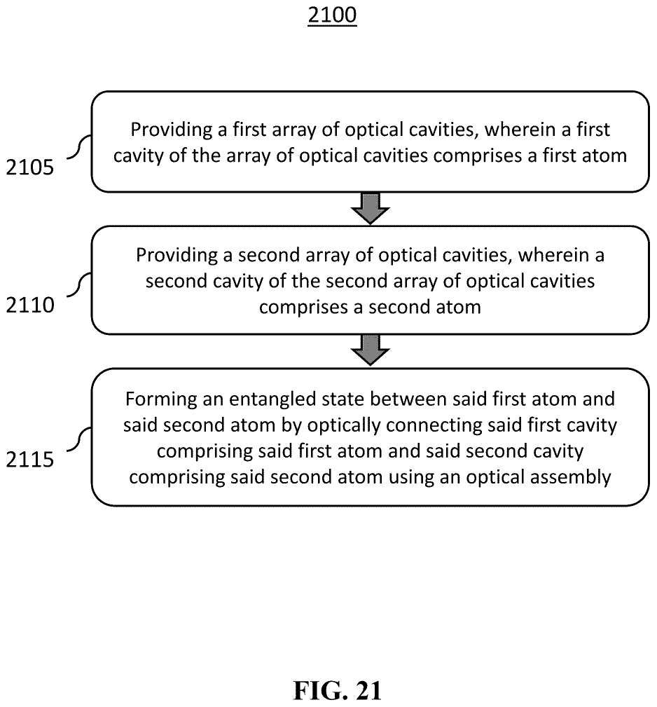

FIG. 20A-20B illustrates an example of a coincident photon detection entanglement scheme 2000 implementing systems and method of the present disclosure. In some cases, the coincident photon detection entanglement is formed by interfering a first output of the first cavity 1830 with a second output of the second cavity 1835, and directing the subsequently generated beam onto two photodetectors 2005. As shown, the outputs of two microcavities may be interfered where the optical assembly 1825 comprises a 50/50 beamsplitter 2010, and each of the two output ports may be directed to a photodetector 2005. As shown, the optical assembly 1825 further comprises a right angle prism 2015 in addition to the beamsplitter cube 2010 which connects the first array of cavities 1805 to the second array of cavities 1815 translated vertically with a 90° deviation.

For coincident photon detection entanglement, the output of a first cavity 1830 may be interfered with the output of a second cavity 1835. In some cases, this can be implemented for an entire (or substantially entire) array of cavities simultaneously (or substantially simultaneously) by directing two halves of the output of the array into an optical assembly 1825 with a 90° deviation, and interfering both halves using the optical assembly 1825. This may be used to form parallelized entanglement across a plurality of cavities, where parallelized entanglement refers to relating the cavities of a plurality of cavities using one or more symmetry operations. In one example of parallelized entanglement, the one or more symmetry operations may include pairwise matching of cavities using translational symmetry. For example, a bonded right-angle prism 2015 and a beamsplitter 2010 may connect one half of the array to the translated other half (see, for example, FIG. 20A-20B), while a bonded Amici roof prism and beamsplitter cube additionally invert the connection about a line. Either of these cases may connect cavities on one edge of an array of cavities on the opposite edge, and the atoms inside can be entangled using a pitch-and-catch entanglement.

In some cases, the optical assembly 1825 is a prism with a 90° deviation. Some non-limiting examples of prisms with a 90° deviation include a roof pentaprism and a beam splitter cube, an amici prism and a beam splitter cube, a pentaprism and a beam splitter cube, a right-angle prism and a beam splitter cube. In some cases, the optical assembly 1825 is a plurality of mirrors with a 90° deviation.

For either entanglement method, different prism configurations for the optical assembly 1825 can be chosen according to whether they invert along a horizontal or vertical line. The following tables list an option for each type of inversion as an illustrative example:

TABLE 1
Pitch-and-catch (180° deviation)

| | Invert about | No invert about |
|---|---|---|
| | horizontal | horizontal |
| Invert about vertical | Corner cube (or cat's-eye) | Porro prism |
| No invert about vertical | Porro prism | Pentaprism + |
| | | right-angle prism |

TABLE 2
Coincident photon (90° deviation)

| | Invert about | No invert about |
|---|---|---|
| | horizontal | horizontal |
| Invert about | Roof pentaprism + | Amici prism + BS cube |
| vertical | BS cube | Or |
| | | Pentaprism + BS cube |
| No invert about | Amici prism + BS cube | Right angle prism + |
| vertical | Or | BS cube |
| | Pentaprism + BS cube | |

While prism systems are disclosed herein, systems and methods of the present disclosure may be implemented with mirror systems. The prisms can generally be replaced with mirror systems of a similar geometry.

In some cases, the systems and methods for highly parallelized arrays, described herein, provide a method for parallelized entanglement generation 2100. In some cases, the method for parallelized entanglement generation 2100 comprises, providing at 2105 a first array of optical cavities, wherein a first cavity of the first array of optical cavities comprises a first atom, providing at 2110 a second array of optical cavities, wherein a second cavity of the second array of optical cavities comprises a second atom, and forming at 2115 an entangled state between said first atom and said second atom by optically connecting said first cavity comprising said first atom and said second cavity comprising said second atom using an optical assembly.

In some cases, forming an entangled state at 2115 comprises pitch-and-catch entanglement. In some cases, forming an entangled state at 2115 comprises coincident photon detection entanglement. In some cases, forming an entangled state at 2115 comprises another form of entanglement.

### Systems and Methods for a Highly Parallelized Entanglement Network

In some cases, the method 2100 further comprises coupling the first array of cavities, the second array of cavities, or both to an optic fiber or fiber bundle and transporting an optical output over a distance. Advantageously, this can allow the method 2100 to generate a network between arrays of optical cavities. In some cases, the first array of optical cavities may be within the same array of optical cavities as the second array of optical cavities. In some cases, the first array of optical cavities may be within a different array of optical cavities as the second array of optical cavities. In one example, the first array of optical cavities may be located in one region of a non-classical computer, and the second array of optical cavities may be located in another region of a non-classical computer. In a further example, the first array of optical cavities may be located in a first non-classical computer, and the second array of optical cavities may be located in a second non-classical computer, where the first non-classical computer and the second non-classical computer are connected by a network.

In this way, systems and methods for highly parallelized entanglement, described herein, can enable generation of a network between separate arrays of cavities, or separate non-classical computers comprising the arrays. In some cases, the network between separate arrays of cavities, or separate non-classical computers may be generated, at least in part, using the optical assembly 1825.

In some cases, to generate a network between separate arrays of cavities, or separate non-classical computers, the optical assembly 1825 comprises one or more optical fibers or fiber bundles. In some cases, the optical assembly 1825 comprises a fiber optic or a plurality of fiber optics configured to connect an output of the first cavity 1830 and to an input of the second cavity 1835. In some examples, the connection between the first output of the first cavity 1830 and the input of the second cavity 1835 may be used to generate pitch-and-catch entanglement. In some examples, the connection between the first output of the first cavity 1830 and the input of the second cavity 1835 may be used to generate any style of entanglement.

In some cases, to generate a network between separate arrays of cavities, or separate non-classical computers, the optical assembly 1825 comprises one or more optical fibers or fiber bundles. In some cases, the optical assembly 1825 comprises a fiber optic or a plurality of fiber optics configured to interfere the first output of the first cavity 1830 and a second output of the second cavity 1835. In some examples, the interference between the first output of the first cavity 1830 and a second output of the second cavity 1835 may be used to generate coincident photon detection entanglement. In some embodiments, the interference between the first output of the first cavity 1830 and a second output of the second cavity 1835 may be used to generate any style of entanglement.

In some cases, the first atom 1810 and the second atom 1820 may be spatially separated in an array. In some cases, the first atom 1810 and the second atom 1820 are more than 10 array units apart. In some cases, the first atom 1810 and the second atom 1820 are more than 100 array units apart. In some cases, the first atom 1810 and the second atom 1820 are located in distinct regions of a quantum computer. In some cases, the first atom 1810 and the second atom 1820 are located in distinct regions of a quantum network. In some cases, the first atom 1810 and the second atom 1820 comprise any atom described herein. In some cases, the first atom 1810 and the second atom 1820 comprise qubits, described herein.

In some cases, the first array of optical cavities 1805 and the second array of optical cavities 1815 are in separate vacuum chambers. In some cases, the first array of optical cavities 1805 and the second array of optical cavities 1815 are in separate quantum computers.

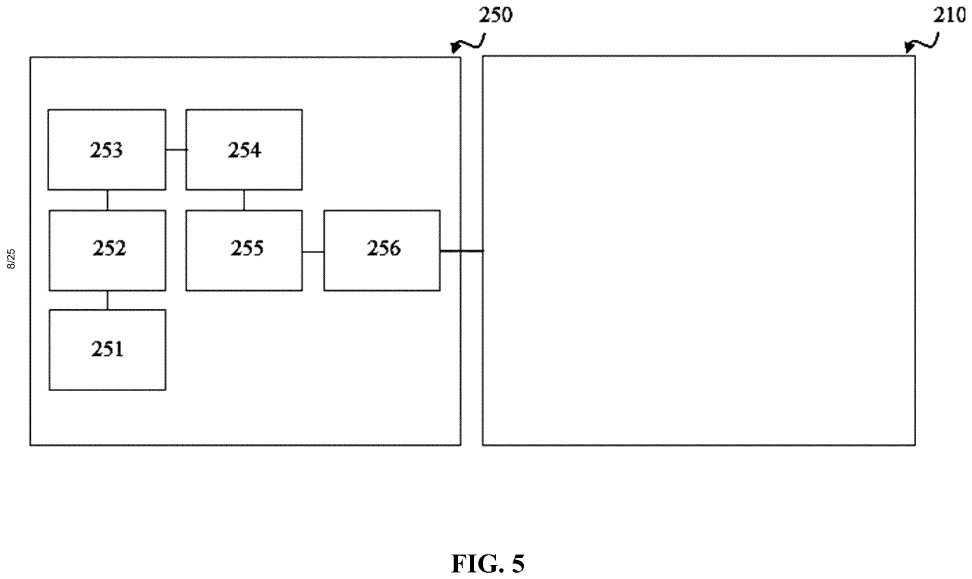

In some cases, the system 1800 further comprises an array of spatially distinct optical trapping sites, described herein, wherein a first optical trapping site of said array of optical trapping sites comprises said first atom 1810 and wherein a second optical trapping site of said array of optical trapping sites comprises said second atom 1820. In some cases, the array of spatially distinct optical trapping sites are the same array of optical trapping sites in 260 of FIG. 5. In some cases, the array of spatially distinct optical trapping sites comprise a plurality of optical dipole traps, described herein.

In some cases, the first optical cavity comprises a first longitudinal mode, wherein said first longitudinal mode, when excited, forms said first optical trapping site of said array of optical trapping sites. In some cases the second optical cavity comprises a second longitudinal mode, wherein said second longitudinal mode, when excited, forms said second optical trapping site of said array of optical trapping sites. In some cases, the first optical trapping site and the second optical trapping site are located at a focal plane of the array of optical cavities. In some cases, fluorescence emitted by at least one atom trapped in an optical trapping site of the array of optical trapping sites is transmitted through an output optical element of an optical cavity array.

### Examples of Systems for Performing a Non-Classical Computation

FIG. 2 shows an example of a system 200 for performing a non-classical computation. The non-classical computation may comprise a quantum computation. The quantum computation may comprise a gate-model quantum computation.

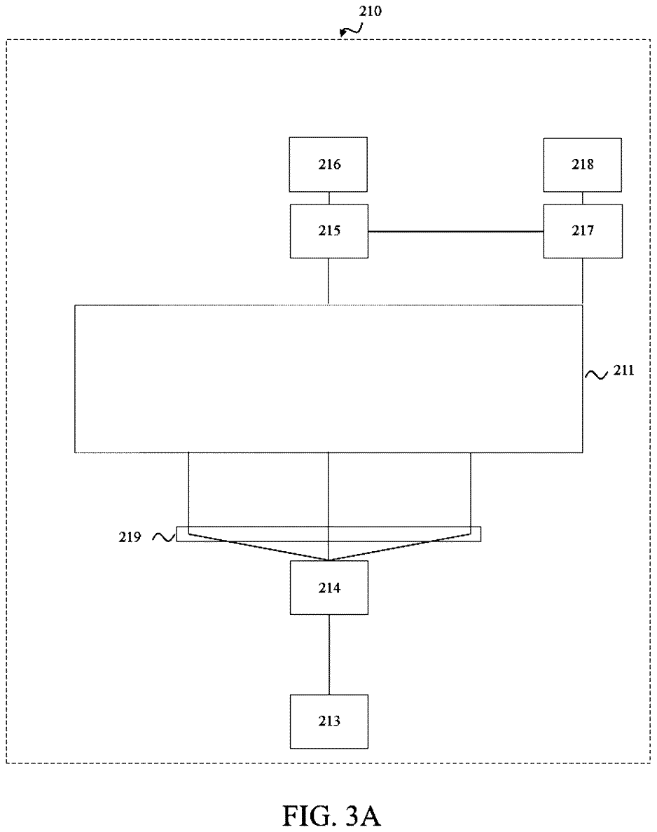

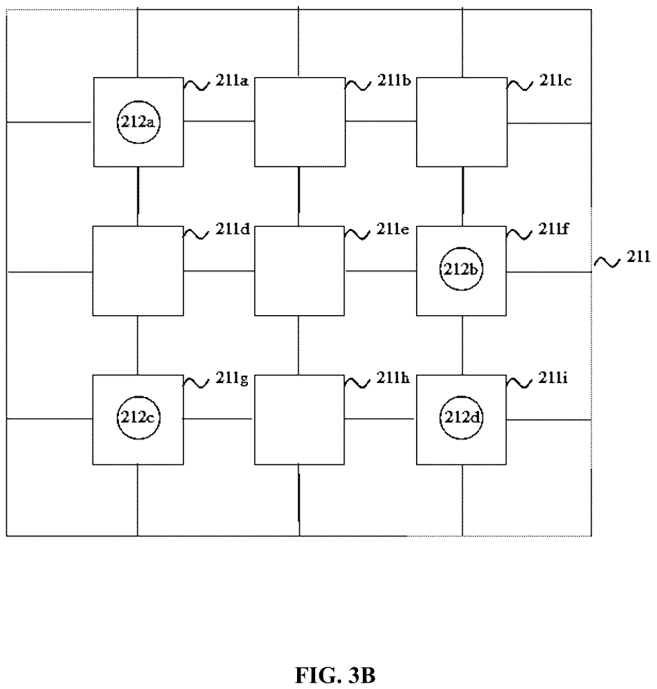

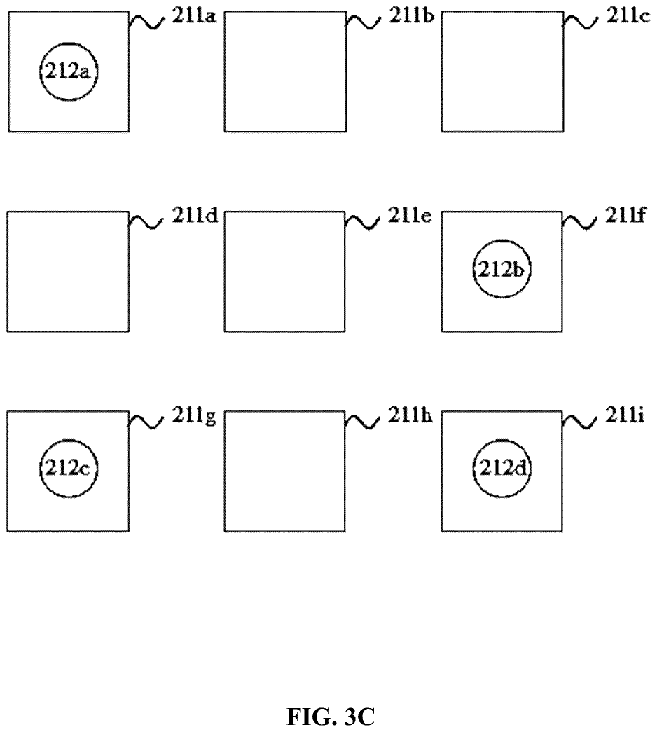

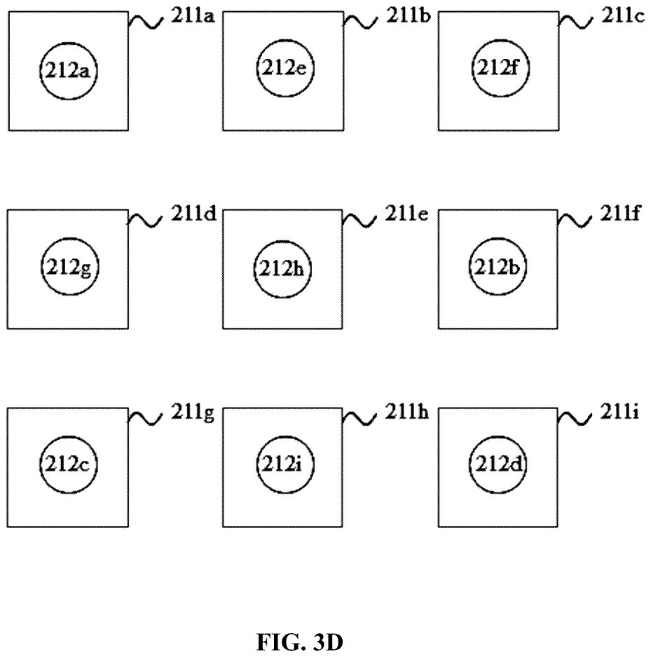

The system 200 may comprise one or more trapping units 210. The trapping units may comprise one or more optical trapping units. The optical trapping units may comprise any optical trapping unit described herein, such as an optical trapping unit described herein with respect to FIG. 3A. The optical trapping units may be configured to generate a plurality of optical trapping sites. The optical trapping units may be configured to generate a plurality of spatially distinct optical trapping sites. For instance, the optical trapping units may be configured to generate at least about 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, 20,000, 30,000, 40,000, 50,000, 60,000, 70,000, 80,000, 90,000, 100,000, 200,000, 300,000, 400,000, 500,000, 600,000, 700,000, 800,000, 900,000, 1,000,000, or more optical trapping sites. The optical trapping units may be configured to generate at most about 1,000,000, 900,000, 800,000, 700,000, 600,000, 500,000, 400,000, 300,000, 200,000, 100,000, 90,000, 80,000, 70,000, 60,000, 50,000, 40,000, 30,000, 20,000, 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, or fewer optical trapping sites. The optical trapping units may be configured to trap a number of optical trapping sites that is within a range defined by any two of the preceding values.

The optical trapping units may be configured to trap a plurality of atoms. For instance, the optical trapping units may be configured to trap at least about 10, 20, 30, 40, 50, 60, 70, 80, 90, 100, 200, 300, 400, 500, 600, 700, 800, 900, 1,000, 2,000, 3,000, 4,000, 5,000, 6,000, 7,000, 8,000, 9,000, 10,000, 20,000, 30,000, 40,000, 50,000, 60,000, 70,000, 80,000, 90,000, 100,000, 200,000, 300,000, 400,000, 500,000, 600,000, 700,000, 800,000, 900,000, 1,000,000, or more atoms. The optical trapping units may be configured to trap at most about 1,000,000, 900,000, 800,000, 700,000, 600,000, 500,000, 400,000, 300,000, 200,000, 100,000, 90,000, 80,000, 70,000, 60,000, 50,000, 40,000, 30,000, 20,000, 10,000, 9,000, 8,000, 7,000, 6,000, 5,000, 4,000, 3,000, 2,000, 1,000, 900, 800, 700, 600, 500, 400, 300, 200, 100, 90, 80, 70, 60, 50, 40, 30, 20, 10, or fewer atoms. The optical trapping units may be configured to trap a number of atoms that is within a range defined by any two of the preceding values.

Each optical trapping site of the optical trapping units may be configured to trap at least about 1, 2, 3, 4, 5, 6, 7, 8, 9, 10, or more atoms. Each optical trapping site may be configured to trap at most about 10, 9, 8, 7, 6, 5, 4, 3, 2, 1, or fewer atoms. Each optical trapping site may be configured to trap a number of atoms that is within a range defined by any two of the preceding values. Each optical trapping site may be configured to trap a single atom.

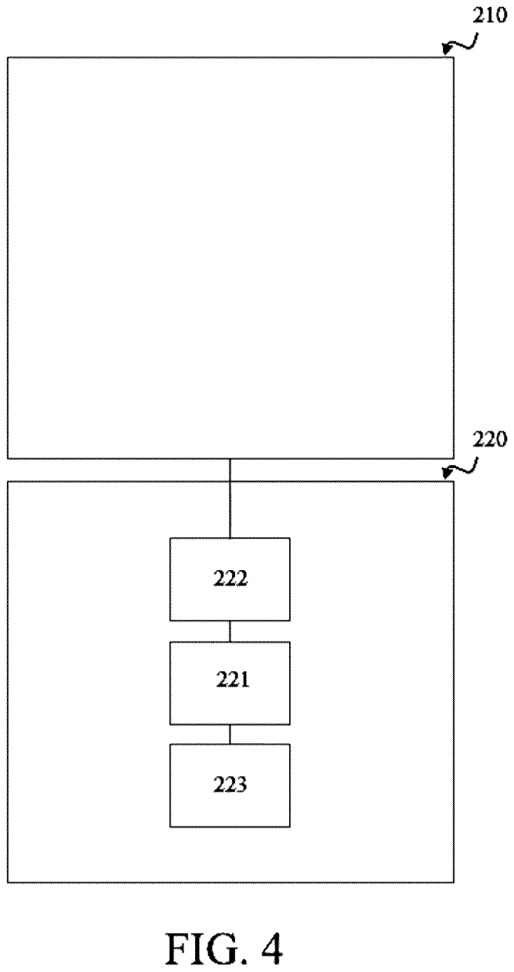

One or more atoms of the plurality of atoms may comprise qubits, as described herein (for instance, with respect to FIG. 4). Two or more atoms may be quantum mechanically entangled. Two or more atoms may be quantum mechanically entangled with a coherence lifetime of at least about 1 microsecond (μs), 2 μs, 3 μs, 4 μs, 5 μs, 6 μs, 7 μs, 8 μs, 9 μs, 10 μs, 20 μs, 30 μs, 40 μs, 50 μs, 60 μs, 70 μs, 80 μs, 90 μs, 100 μs, 200 μs, 300 μs, 400 μs, 500 μs, 600 μs, 700 μs, 800 μs, 900 μs, 1 millisecond (ms), 2 ms, 3 ms, 4 ms, 5 ms, 6 ms, 7 ms, 8 ms, 9 ms, 10 ms, 20 ms, 30 ms, 40 ms, 50 ms, 60 ms, 70 ms, 80 ms, 90 ms, 100 ms, 200 ms, 300 ms, 400 ms, 500 ms, 600 ms, 700 ms, 800 ms, 900 ms, 1 second(s), 2 s, 3 s, 4 s, 5 s, 6 s, 7 s, 8 s, 9 s, 10 s, or more. Two or more atoms may be quantum mechanically entangled with a coherence lifetime of at most about 10 s, 9 s, 8 s, 7 s, 6 s, 5 s, 4 s, 3 s, 2 s, 1 s, 900 ms, 800 ms, 700 ms, 600 ms, 500 ms, 400 ms, 300 ms, 200 ms, 100 ms, 90 ms, 80 ms, 70 ms, 60 ms, 50 ms, 40 ms, 30 ms, 20 ms, 10 ms, 9 ms, 8 ms, 7 ms, 6 ms, 5 ms, 4 ms, 3 ms, 2 ms, 1 ms, 900 μs, 800 μs, 700 μs, 600 μs, 500 μs, 400 μs, 300 μs, 200 μs, 100 μs, 90 μs, 80 μs, 70 μs, 60 μs, 50 μs, 40 μs, 30 μs, 20 μs, 10 μs, 9 μs, 8 μs, 7 μs, 6 μs, 5 μs, 4 μs, 3 μs, 2 μs, 1 μs, or less. Two or more atoms may be quantum mechanically entangled with a coherence lifetime that is within a range defined by any two of the preceding values. One or more atoms may comprise neutral atoms. One or more atoms may comprise uncharged atoms.

One or more atoms may comprise alkali atoms. One or more atoms may comprise lithium (Li) atoms, sodium (Na) atoms, potassium (K) atoms, rubidium (Rb) atoms, or cesium (Cs) atoms. One or more atoms may comprise lithium-6 atoms, lithium-7 atoms, sodium-23 atoms, potassium-39 atoms, potassium-40 atoms, potassium-41 atoms, rubidium-85 atoms, rubidium-87 atoms, or caesium-133 atoms. One or more atoms may comprise alkaline earth atoms. One or more atoms may comprise beryllium (Be) atoms, magnesium (Mg) atoms, calcium (Ca) atoms, strontium (Sr) atoms, or barium (Ba) atoms. One or more atoms may comprise beryllium-9 atoms, magnesium-24 atoms, magnesium-25 atoms, magnesium-26 atoms, calcium-40 atoms, calcium-42 atoms, calcium-43 atoms, calcium-44 atoms, calcium-46 atoms, calcium-48 atoms, strontium-84 atoms, strontium-86 atoms, strontium-87 atoms, strontium-88 atoms, barium-130 atoms, barium-132 atoms, barium-133 atoms, barium-134 atoms, barium-135 atoms, barium-136 atoms, barium-137 atoms, or barium-138 atoms. One or more atoms may comprise rare earth atoms. One or more atoms may comprise scandium (Sc) atoms, yttrium (Y) atoms, lanthanum (La) atoms, cerium (Ce) atoms, praseodymium (Pr) atoms, neodymium (Nd) atoms, samarium (Sm) atoms, europium (Eu) atoms, gadolinium (Gd) atoms, terbium (Tb) atoms, dysprosium (Dy) atoms, holmium (Ho) atoms, erbium (Er) atoms, thulium (Tm) atoms, ytterbium (Yb) atoms, or lutetium (Lu) atoms. One or more atoms may comprise scandium-45 atoms, yttrium-89 atoms, lanthanum-139 atoms, cerium-136 atoms, cerium-138 atoms, cerium-140 atoms, cerium-142 atoms, praseodymium-141 atoms, neodymium-142 atoms, neodymium-143 atoms, neodymium-145 atoms, neodymium-146 atoms, neodymium-148 atoms, samarium-144 atoms, samarium-149 atoms, samarium-150 atoms, samarium-152 atoms, samarium-154 atoms, europium-151 atoms, europium-153 atoms, gadolinium-154 atoms, gadolinium-155 atoms, gadolinium-156 atoms, gadolinium-157 atoms, gadolinium-158 atoms, gadolinium-160 atoms, terbium-159 atoms, dysprosium-156 atoms, dysprosium-158 atoms, dysprosium-160 atoms, dysprosium-161 atoms, dysprosium-162 atoms, dysprosium-163 atoms, dysprosium-164 atoms, erbium-162 atoms, erbium-164 atoms, erbium-166 atoms, erbium-167 atoms, erbium-168 atoms, erbium-170 atoms, holmium-165 atoms, thulium-169 atoms, ytterbium-168 atoms, ytterbium-170 atoms, ytterbium-171 atoms, ytterbium-172 atoms, ytterbium-173 atoms, ytterbium-174 atoms, ytterbium-176 atoms, lutetium-175 atoms, or lutetium-176 atoms.

The plurality of atoms may comprise a single element selected from the group consisting of Li, Na, K, Rb, Cs, Be, Mg, Ca, Sr, and Ba. The plurality of atoms may comprise a mixture of elements selected from the group consisting of Li, Na, K, Rb, Cs, Be, Mg, Ca, Sr, and Ba. The plurality of atoms may comprise a natural isotopic mixture of one or more elements selected from the group consisting of Li, Na, K, Rb, Cs, Be, Mg, Ca, Sr, and Ba. The plurality of atoms may comprise an isotopically enriched mixture of one or more elements selected from the group consisting of Li, Na, K, Rb, Cs, Be, Mg, Ca, Sr, and Ba. The plurality of atoms may comprise a natural isotopic mixture of one or more elements selected from the group consisting of Sc, Y, La, Ce, Pr, Nd, Sm, Eu, Gd, Tb, Dy, Ho, Er, Tm, Yb, and Lu. The plurality of atoms may comprise an isotopically enriched mixture of one or more elements selected from the group consisting of Sc, Y, La, Ce, Pr, Nd, Sm, Eu, Gd, Tb, Dy, Ho, Er, Tm, Yb, and Lu. atoms may comprise rare earth atoms. For instance, the plurality of atoms may comprise lithium-6 atoms, lithium-7 atoms, sodium-23 atoms, potassium-39 atoms, potassium-40 atoms, potassium-41 atoms, rubidium-85 atoms, rubidium-87 atoms, caesium-133 atoms, beryllium-9 atoms, magnesium-24 atoms, magnesium-25 atoms, magnesium-26 atoms, calcium-40 atoms, calcium-42 atoms, calcium-43 atoms, calcium-44 atoms, calcium-46 atoms, calcium-48 atoms, strontium-84 atoms, strontium-86 atoms, strontium-87 atoms, strontium-88 atoms, barium-130 atoms, barium-132 atoms, barium-133 atoms, barium-134 atoms, barium-135 atoms, barium-136 atoms, barium-137 atoms, barium-138 atoms, scandium-45 atoms, yttrium-89 atoms, lanthanum-139 atoms, cerium-136 atoms, cerium-138 atoms, cerium-140 atoms, cerium-142 atoms, praseodymium-141 atoms, neodymium-142 atoms, neodymium-143 atoms, neodymium-145 atoms, neodymium-146 atoms, neodymium-148 atoms, samarium-144 atoms, samarium-149 atoms, samarium-150 atoms, samarium-152 atoms, samarium-154 atoms, europium-151 atoms, europium-153 atoms, gadolinium-154 atoms, gadolinium-155 atoms, gadolinium-156 atoms, gadolinium-157 atoms, gadolinium-158 atoms, gadolinium-160 atoms, terbium-159 atoms, dysprosium-156 atoms, dysprosium-158 atoms, dysprosium-160 atoms, dysprosium-161 atoms, dysprosium-162 atoms, dysprosium-163 atoms, dysprosium-164 atoms, erbium-162 atoms, erbium-164 atoms, erbium-166 atoms, erbium-167 atoms, erbium-168 atoms, erbium-170 atoms, holmium-165 atoms, thulium-169 atoms, ytterbium-168 atoms, ytterbium-170 atoms, ytterbium-171 atoms, ytterbium-172 atoms, ytterbium-173 atoms, ytterbium-174 atoms, ytterbium-176 atoms, lutetium-175 atoms, or lutetium-176 atoms enriched to an isotopic abundance of at least about 50%, 60%, 70%, 80%, 90%, 91%, 92%, 93%, 94%, 95%, 96%, 97%, 98%, 99%, 99.1%, 99.2%, 99.3%, 99.4%, 99.5%, 99.6%, 99.7%, 99.8%, 99.9%, 99.91%, 99.92%, 99.93%, 99.94%, 99.95%, 99.96%, 99.97%, 99.98%, 99.99%, or more. The plurality of atoms may comprise lithium-6 atoms, lithium-7 atoms, sodium-23 atoms, potassium-39 atoms, potassium-40 atoms, potassium-41 atoms, rubidium-85 atoms, rubidium-87 atoms, caesium-133 atoms, beryllium-9 atoms, magnesium-24 atoms, magnesium-25 atoms, magnesium-26 atoms, calcium-40 atoms, calcium-42 atoms, calcium-43 atoms, calcium-44 atoms, calcium-46 atoms, calcium-48 atoms, strontium-84 atoms, strontium-86 atoms, strontium-87 atoms, strontium-88 atoms, barium-130 atoms, barium-132 atoms, barium-133 atoms, barium-134 atoms, barium-135 atoms, barium-136 atoms, barium-137 atoms, barium-138 atoms, scandium-45 atoms, yttrium-89 atoms, lanthanum-139 atoms, cerium-136 atoms, cerium-138 atoms, cerium-140 atoms, cerium-142 atoms, praseodymium-141 atoms, neodymium-142 atoms, neodymium-143 atoms, neodymium-145 atoms, neodymium-146 atoms, neodymium-148 atoms, samarium-144 atoms, samarium-149 atoms, samarium-150 atoms, samarium-152 atoms, samarium-154 atoms, europium-151 atoms, europium-153 atoms, gadolinium-154 atoms, gadolinium-155 atoms, gadolinium-156 atoms, gadolinium-157 atoms, gadolinium-158 atoms, gadolinium-160 atoms, terbium-159 atoms, dysprosium-156 atoms, dysprosium-158 atoms, dysprosium-160 atoms, dysprosium-161 atoms, dysprosium-162 atoms, dysprosium-163 atoms, dysprosium-164 atoms, erbium-162 atoms, erbium-164 atoms, erbium-166 atoms, erbium-167 atoms, erbium-168 atoms, erbium-170 atoms, holmium-165 atoms, thulium-169 atoms, ytterbium-168 atoms, ytterbium-170 atoms, ytterbium-171 atoms, ytterbium-172 atoms, ytterbium-173 atoms, ytterbium-174 atoms, ytterbium-176 atoms, lutetium-175 atoms, or lutetium-176 atoms enriched to an isotopic abundance of at most about 99.99%, 99.98%, 99.97%, 99.96%, 99.95%, 99.94%, 99.93%, 99.92%, 99.91%, 99.9%, 99.8%, 99.7%, 99.6%, 99.5%, 99.4%, 99.3%, 99.2%, 99.1%, 99%, 98%, 97%, 96%, 95%, 94%, 93%, 92%, 91%, 90%, 80%, 70%, 60%, 50%, or less. The plurality of atoms may comprise lithium-6 atoms, lithium-7 atoms, sodium-23 atoms, potassium-39 atoms, potassium-40 atoms, potassium-41 atoms, rubidium-85 atoms, rubidium-87 atoms, caesium-133 atoms, beryllium-9 atoms, magnesium-24 atoms, magnesium-25 atoms, magnesium-26 atoms, calcium-40 atoms, calcium-42 atoms, calcium-43 atoms, calcium-44 atoms, calcium-46 atoms, calcium-48 atoms, strontium-84 atoms, strontium-86 atoms, strontium-87 atoms, strontium-88 atoms, barium-130 atoms, barium-132 atoms, barium-133 atoms, barium-134 atoms, barium-135 atoms, barium-136 atoms, barium-137 atoms, barium-138 atoms, scandium-45 atoms, yttrium-89 atoms, lanthanum-139 atoms, cerium-136 atoms, cerium-138 atoms, cerium-140 atoms, cerium-142 atoms, praseodymium-141 atoms, neodymium-142 atoms, neodymium-143 atoms, neodymium-145 atoms, neodymium-146 atoms, neodymium-148 atoms, samarium-144 atoms, samarium-149 atoms, samarium-150 atoms, samarium-152 atoms, samarium-154 atoms, europium-151 atoms, europium-153 atoms, gadolinium-154 atoms, gadolinium-155 atoms, gadolinium-156 atoms, gadolinium-157 atoms, gadolinium-158 atoms, gadolinium-160 atoms, terbium-159 atoms, dysprosium-156 atoms, dysprosium-158 atoms, dysprosium-160 atoms, dysprosium-161 atoms, dysprosium-162 atoms, dysprosium-163 atoms, dysprosium-164 atoms, erbium-162 atoms, erbium-164 atoms, erbium-166 atoms, erbium-167 atoms, erbium-168 atoms, erbium-170 atoms, holmium-165 atoms, thulium-169 atoms, ytterbium-168 atoms, ytterbium-170 atoms, ytterbium-171 atoms, ytterbium-172 atoms, ytterbium-173 atoms, ytterbium-174 atoms, ytterbium-176 atoms, lutetium-175 atoms, or lutetium-176 atoms enriched to an isotopic abundance that is within a range defined by any two of the preceding values.

The system 200 may comprise one or more first electromagnetic delivery units 220. The first electromagnetic delivery units may comprise any electromagnetic delivery unit described herein, such as an electromagnetic delivery unit described herein with respect to FIG. 4. The first electromagnetic delivery units may be configured to apply first electromagnetic energy to one or more atoms of the plurality of atoms. Applying the first electromagnetic energy may induce the atoms to adopt one or more superposition states of a first atomic state and a second atomic state that is different from the first atomic state.

The first atomic state may comprise a first single-qubit state. The second atomic state may comprise a second single-qubit state. The first atomic state or second atomic state may be elevated in energy with respect to a ground atomic state of the atoms. The first atomic state or second atomic state may be equal in energy with respect to the ground atomic state of the atoms.

The first atomic state may comprise a first hyperfine electronic state and the second atomic state may comprise a second hyperfine electronic state that is different from the first hyperfine electronic state. For instance, the first and second atomic states may comprise first and second hyperfine states on a multiplet manifold, such as a triplet manifold. The first and second atomic states may comprise first and second hyperfine states, respectively, on a ³P₁ or ³P₂ manifold. The first and second atomic states may comprise first and second hyperfine states, respectively, on a ³P₁ or ³P₂ manifold of any atom described herein, such as a strontium-87 ³P₁ manifold or a strontium-87 ³P₂ manifold.

In some cases, the first and second atomic states are first and second hyperfine states of a first electronic state. Optical excitation may be applied between a first electronic state and a second electronic state. The optical excitation may excite the first hyperfine state or the second hyperfine state to the second electronic state. A single-qubit transition may comprise a two-photon transition between two hyperfine states within the first electronic state using a second electronic state as an intermediate state. To drive a single-qubit transition, a pair of frequencies, each detuned from a single-photon transition to the intermediate state, may be applied to drive a two-photon transition. In some cases, the first and second hyperfine states are hyperfine states of the ground electronic state. The ground electronic state may not decay by spontaneous or stimulated emission to a lower electronic state. The hyperfine states may comprise nuclear spin states.

In some cases, the hyperfine states comprise nuclear spin states of a strontium-87 ¹S₀ manifold and the qubit transition drives one or both of two nuclear spin states of strontium-87 ¹S₀ to a state detuned from or within the ³P₂ or ³P¹ manifold. In some cases, the one-qubit transition is a two photon Raman transition between nuclear spin states of strontium-87 ¹S₀ via a state detuned from or within the ³P₂ or ³P¹ manifold. In some cases, the nuclear spin states may be Stark shifted nuclear spin states. A Stark shift may be driven optically. An optical Stark shift may be driven off resonance with any, all, or a combination of a single-qubit transition, a two-qubit transition, a shelving transition, an imaging transition, etc.

In some cases, the hyperfine states comprise nuclear spin states of ytterbium.

The first atomic state may comprise a first nuclear spin state and the second atomic state may comprise a second nuclear spin state that is different from the first nuclear spin state. The first and second atomic states may comprise first and second nuclear spin states, respectively, of a quadrupolar nucleus. The first and second atomic states may comprise first and second nuclear spin states, respectively, of a spin-1, spin-3/2, spin-2, spin-5/2, spin-3, spin-7/2, spin-4, or spin-9/2 nucleus. The first and second atomic states may comprise first and second nuclear spin states, respectively, of any atom described herein, such as first and second spin states of strontium-87.

For first and second nuclear spin states associated with a nucleus comprising a spin greater than 1/2 (such as a spin-1, spin-3/2, spin-2, spin-5/2, spin-3, spin-7/2, spin-4, or spin-9/2 nucleus), transitions between the first and second nuclear spin states may be accompanied by transitions between other spin states on the nuclear spin manifold. For instance, for a spin-9/2 nucleus in the presence of a uniform magnetic field, all of the nuclear spin levels may be separated by equal energy. Thus, a transition (such as a Raman transition) designed to transfer atoms from, for instance, an m_{N}=9/2 spin state to an m_{N}=7/2 spin state, may also drive m_{N}=7/2 to m_{N}=5/2, m_{N}=5/2 to m_{N}=3/2, m_{N}=3/2 to m_{N}=1/2, m_{N}=1/2 to m_{N}=−1/2, m_{N}=−1/2 to m_{N}=−3/2, m_{N}=−3/2 to m_{N}=−5/2, m_{N}=−5/2 to m_{N}=−7/2, and m_{N}=−7/2 to m_{N}=−9/2, where m_{N} is the nuclear spin state. Similarly, a transition (such as a Raman transition) designed to transfer atoms from, for instance, an m_{N}=9/2 spin state to an m_{N}=5/2 spin state, may also drive m_{N}=7/2 to m_{N}=3/2, m_{N}=5/2 to m_{N}=1/2, m_{N}=3/2 to m_{N}=−1/2, m_{N}=1/2 to m_{N}=−3/2, m_{N}=−1/2 to m_{N}=−5/2, m_{N}=−3/2 to m_{N}=−7/2, and m_{N}=−5/2 to m_{N}=−9/2. Such a transition may thus not be selective for inducing transitions between particular spin states on the nuclear spin manifold.

It may be desirable to instead implement selective transitions between particular first and second spins states on the nuclear spin manifold. This may be accomplished by providing light from a light source that provides an AC Stark shift and pushes neighboring nuclear spin states out of resonance with a transition between the desired transition between the first and second nuclear spin states. For instance, if a transition from first and second nuclear spin states having m_{N}=−9/2 and m_{N}=−7/2 is desired, the light may provide an AC Stark shift to the m_{N}=−5/2 spin state, thereby greatly reducing transitions between the m_{N}=−7/2 and m_{N}=−5/2 states. Similarly, if a transition from first and second nuclear spin states having m_{N}=−9/2 and m_{N}=−5/2 is desired, the light may provide an AC Stark shift to the m_{N}=−1/2 spin state, thereby greatly reducing transitions between the m_{N}=−5/2 and m_{N}=−1/2 states. This may effectively create a two-level subsystem within the nuclear spin manifold that is decoupled from the remainder of the nuclear spin manifold, greatly simplifying the dynamics of the qubit systems. It may be advantageous to use nuclear spin states near the edge of the nuclear spin manifold (e.g., m_{N}=−9/2 and m_{N}=−7/2, m_{N}=7/2 and m_{N}=9/2, m_{N}=−9/2 and m_{N}=−5/2, or m_{N}=5/2 and m_{N}=9/2 for a spin-9/2 nucleus) such that only one AC Stark shift is required. Alternatively, nuclear spin states farther from the edge of the nuclear spin manifold (e.g., m_{N}=−5/2 and m_{N}=−3/2 or m_{N}=−5/2 and m_{N}=−1/2) may be used and two AC Stark shifts may be implemented (e.g., at m_{N}=−7/2 and m_{N}=−1/2 or m_{N}=−9/2 and m_{N}=3/2).

Stark shifting of the nuclear spin manifold may shift neighboring nuclear spin states out of resonance with the desired transition between the first and second nuclear spin states and a second electronic state or a state detuned therefrom. Stark shifting may decrease leakage from the first and second nuclear spin state to other states in the nuclear spin manifold. Starks shifts may be achievable up to 100s of kHz for less than 10 mW beam powers. Upper state frequency selectivity may decrease scattering from imperfect polarization control. Separation of different angular momentum states in the ³P₁ manifold may be many gigahertz from the single and two-qubit gate light. Leakage to other states in the nuclear spin manifold may lead to decoherence. The Rabi frequency for two-qubit transitions (e.g., how quickly the transition can be driven) may be faster than the decoherence rate. Scattering from the intermediate state in the two-qubit transition may be a source of decoherence. Detuning from the intermediate state may improve fidelity of two-qubit transitions.

Qubits based on nuclear spin states in the electronic ground state may allow exploitation of long-lived metastable excited electronic states (such as a ³P₀ state in strontium-87) for qubit storage. Atoms may be selectively transferred into such a state to reduce cross-talk or to improve gate or detection fidelity. Such a storage or shelving process may be atom-selective using the SLMs or AODs described herein. A shelving transition may comprise a transition between the ¹S₀ state in strontium-87 to the ³P₀ or ³P₂ state in strontium-87.

The clock transition (also a “shelving transition” or a “storage transition” herein) may be qubit-state selective. The upper state of the clock transition may have a very long natural lifetime, e.g., greater than 1 second. The linewidth of the clock transition may be much narrower than the qubit energy spacing. This may allow direct spectral resolution. Population may be transferred from one of the qubit states into the clock state. This may allow individual qubit states to be read out separately, by first transferring population from one qubit state into the clock state, performing imaging on the qubits, then transferring the population back into the ground state from the clock state and imaging again. In some cases, a magic wavelength transition is used to drive the clock transition.

The clock light for shelving can be atom-selective or not atom-selective. In some cases, the clock transition is globally applied (e.g., not atom selective). A globally applied clock transition may include directing the light without passing through a microscope objective or structuring the light. In some cases, the clock transition is atom-selective. Clock transition which are atom-selective may potentially allow us to improve gate fidelities by minimizing cross-talk. For example, to reduce cross talk in an atom, the atom may be shelved in the clock state where it may not be affected by the light. This may reduce cross-talk between neighboring qubits undergoing transitions. To implement atom-selective clock transitions, the light may pass through one or more microscope objectives or may be structured on one or more of a spatial light modulator, digital micromirror device, crossed acousto-optic deflectors, etc.

The system 200 may comprise one or more readout units 230. The readout units may comprise one or more readout optical units. The readout optical units may be configured to perform one or more measurements of the one or more superposition states to obtain the non-classical computation. The readout optical units may comprise one or more optical detectors. The detectors may comprise one or more photomultiplier tubes (PMTs), photodiodes, avalanche diodes, single-photon avalanche diodes, single-photon avalanche diode arrays, phototransistors, reverse-biased light emitting diodes (LEDs), charge coupled devices (CCDs), or complementary metal oxide semiconductor (CMOS) cameras. The optical detectors may comprise one or more fluorescence detectors. The readout optical unit may comprise one or more objectives, such as one or more objective having a numerical aperture (NA) of at least about 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1, or more. The objective may have an NA of at most about 1, 0.95, 0.9, 0.85, 0.8, 0.75, 0.7, 0.65, 0.6, 0.55, 0.5, 0.45, 0.4, 0.35, 0.3, 0.25, 0.2, 0.15, 0.1, or less. The objective may have an NA that is within a range defined by any two of the preceding values.

The one or more readout optical units 230 may make measurements, such as projective measurements, by applying light resonant with an imaging transition. The imaging transition may cause fluorescence. An imaging transition may comprise a transition between the ¹S₀ state in strontium-87 to the ¹P₁ state in strontium-87. The ¹P₁ state in strontium-87 may fluoresce. The lower state of the qubit transition may comprise two nuclear spin states in the ¹S₀ manifold. The one or more states may be resonant with the imaging transition. A measurement may comprise two excitations. In a first excitation, one of the two lower states may be excited to the shelving state (e.g., ³P₀ state in strontium-87). In a second excitation, the imaging transition may be excited. The first transition may reduce cross-talk between neighboring atoms during computation. Fluorescence generated from the imaging transition may be collected on one or more readout optical units 230.

The imaging units may be used to determine if one or more atoms were lost from the trap. The imaging units may be used to observe the arrangement of atoms in the trap.

The system 200 may comprise one or more vacuum units 240. The one or more vacuum units may comprise one or more vacuum pumps. The vacuum units may comprise one or more roughing vacuum pumps, such as one or more rotary pumps, rotary vane pumps, rotary piston pumps, diaphragm pumps, piston pumps, reciprocating piston pumps, scroll pumps, or screw pumps. The one or more roughing vacuum pumps may comprise one or more wet (for instance, oil-sealed) or dry roughing vacuum pumps. The vacuum units may comprise one or more high-vacuum pumps, such as one or more cryosorption pumps, diffusion pumps, turbomolecular pumps, molecular drag pumps, turbo-drag hybrid pumps, cryogenic pumps, ions pumps, or getter pumps.

The vacuum units may comprise any combination of vacuum pumps described herein. For instance, the vacuum units may comprise one or more roughing pumps (such as a scroll pump) configured to provide a first stage of rough vacuum pumping. The roughing vacuum pumps may be configured to pump gases out of the system 200 to achieve a low vacuum pressure condition. For instance, the roughing pumps may be configured to pump gases out of the system 200 to achieve a low vacuum pressure of at most about 103 Pascals (Pa). The vacuum units may further comprise one or more high-vacuum pumps (such as one or more ion pumps, getter pumps, or both) configured to provide a second stage of high vacuum pumping or ultra-high vacuum pumping. The high-vacuum pumps may be configured to pump gases out of the system 200 to achieve a high vacuum pressure of at most about 10⁻³ Pa or an ultra-high vacuum pressure of at most about 10⁻⁶ Pa once the system 200 has reached the low vacuum pressure condition provided by the one or more roughing pumps.

The vacuum units may be configured to maintain the system 200 at a pressure of at most about 10⁻⁶ Pa, 9×10⁻⁷ Pa, 8×10⁻⁷ Pa, 7×10⁻⁷ Pa, 6×10⁻⁷ Pa, 5×10⁻⁷ Pa, 4×10⁻⁷ Pa, 3×10⁻⁷ Pa, 2×10⁻⁷ Pa, 10⁻⁷ Pa, 9×10⁻⁸ Pa, 8×10⁻⁸ Pa, 7×10⁻⁸ Pa, 6×10⁻⁸ Pa, 5×10⁻⁸ Pa, 4×10⁻⁸ Pa, 3×10⁻⁸ Pa, 2×10⁻⁸ Pa, 10⁻⁸ Pa, 9×10⁻⁹ Pa, 8×10⁻⁹ Pa, 7×10⁻⁹ Pa, 6×10⁻⁹ Pa, 5×10⁻⁹ Pa, 4×10⁻⁹ Pa, 3×10⁻⁹ Pa, 2×10⁻⁹ Pa, 10⁻⁹ Pa, 9×10⁻¹⁰ Pa, 8×10⁻¹⁰ Pa, 7×10⁻¹⁰ Pa, 6×10⁻¹⁰ Pa, 5×10⁻¹⁰ Pa, 4×10⁻¹⁰ Pa, 3×10⁻¹⁰ Pa, 2×10⁻¹⁰ Pa, 10-10 Pa, 9×10⁻¹¹ Pa, 8×10⁻¹¹ Pa, 7×10⁻¹¹ Pa, 6×10⁻¹¹ Pa, 5×10⁻¹¹ Pa, 4×10⁻¹¹ Pa, 3×10⁻¹¹ Pa, 2×10⁻¹¹ Pa, 10⁻¹¹ Pa, 9×10⁻¹² Pa, 8×10⁻¹² Pa, 7×10⁻¹² Pa, 6×10⁻¹² Pa, 5×10⁻¹² Pa, 4×10⁻¹² Pa, 3×10⁻¹² Pa, 2×10⁻¹² Pa, 10⁻¹² Pa, or lower. The vacuum units may be configured to maintain the system 200 at a pressure of at least about 10⁻¹² Pa, 2×10⁻¹² Pa, 3×10⁻¹² Pa, 4×10⁻¹² Pa, 5×10⁻¹² Pa, 6×10⁻¹² Pa, 7×10⁻¹² Pa, 8×10⁻¹² Pa, 9×10⁻¹² Pa, 10⁻¹¹ Pa, 2×10⁻¹¹ Pa, 3×10⁻¹¹ Pa, 4×10⁻¹¹ Pa, 5×10⁻¹¹ Pa, 6×10⁻¹¹ Pa, 7×10⁻¹¹ Pa, 8×10⁻¹¹ Pa, 9×10⁻¹¹ Pa, 10⁻¹⁰ Pa, 2×10⁻¹⁰ Pa, 3×10⁻¹⁰ Pa, 4×10⁻¹⁰ Pa, 5×10⁻¹⁰ Pa, 6×10⁻¹⁰ Pa, 7×10⁻¹⁰ Pa, 8×10⁻¹⁰ Pa, 9×10⁻¹⁰ Pa, 10⁻⁹ Pa, 2×10⁻⁹ Pa, 3×10⁻⁹ Pa, 4×10⁻⁹ Pa, 5×10⁻⁹ Pa, 6×10⁻⁹ Pa, 7×10⁻⁹ Pa, 8×10⁻⁹ Pa, 9×10⁻⁹ Pa, 10⁻⁸ Pa, 2×10⁻⁸ Pa, 3×10⁻⁸ Pa, 4×10⁻⁸ Pa, 5×10⁻⁸ Pa, 6×10⁻⁸ Pa, 7×10⁻⁸ Pa, 8×10⁻⁸ Pa, 9×10⁻⁸ Pa, 10⁻⁷ Pa, 2×10⁻⁷ Pa, 3×10⁻⁷ Pa, 4×10⁻⁷ Pa, 5×10⁻⁷ Pa, 6×10⁻⁷ Pa, 7×10⁻⁷ Pa, 8×10⁻⁷ Pa, 9×10⁻⁷ Pa, 10⁻⁶ Pa, or higher. The vacuum units may be configured to maintain the system 200 at a pressure that is within a range defined by any two of the preceding values.

The system 200 may comprise one or more state preparation units 250. The state preparation units may comprise any state preparation unit described herein, such as a state preparation unit described herein with respect to FIG. 5. The state preparation units may be configured to prepare a state of the plurality of atoms.

The system 200 may comprise one or more atom reservoirs 260. The atom reservoirs may be configured to supply one or more replacement atoms to replace one or more atoms at one or more optical trapping sites upon loss of the atoms from the optical trapping sites. The atom reservoirs may be spatially separated from the optical trapping units. For instance, the atom reservoirs may be located at a distance from the optical trapping units.

Alternatively or in addition, the atom reservoirs may comprise a portion of the optical trapping sites of the optical trapping units. A first subset of the optical trapping sites may be utilized for performing quantum computations and may be referred to as a set of computationally-active optical trapping sites, while a second subset of the optical trapping sites may serve as an atom reservoir. For instance, the first subset of optical trapping sites may comprise an interior array of optical trapping sites, while the second subset of optical trapping sites comprises an exterior array of optical trapping sites surrounding the interior array. The interior array may comprise a rectangular, square, rectangular prism, or cubic array of optical trapping sites.

The system 200 may comprise one or more atom movement units 270. The atom movement units may be configured to move the one or more replacement atoms from the one or more atoms reservoirs to the one or more optical trapping sites. For instance, the one or more atom movement units may comprise one or more electrically tunable lenses, acousto-optic deflectors (AODs), or spatial light modulators (SLMs).

The system 200 may comprise one or more entanglement units 280. The entanglement units may be configured to quantum mechanically entangle at least a first atom of the plurality of atoms with at least a second atom of the plurality of atoms. The first or second atom may be in a superposition state at the time of quantum mechanical entanglement. Alternatively or in addition, the first or second atom may not be in a superposition state at the time of quantum mechanical entanglement. The first atom and the second atom may be quantum mechanically entangled through one or more magnetic dipole interactions, induced magnetic dipole interactions, electric dipole interactions, or induced electric dipole interactions. The entanglement units may be configured to quantum mechanically entangle any number of atoms described herein.

The entanglement units may also be configured to quantum mechanically entangle at least a subset of the atoms with at least another atom to form one or more multi-qubit units. The multi-qubit units may comprise two-qubit units, three-qubit units, four-qubit units, or n-qubit units, where n may be 5, 6, 7, 8, 9, 10, or more. For instance, a two-qubit unit may comprise a first atom quantum mechanically entangled with a second atom, a three-qubit unit may comprise a first atom quantum mechanically entangled with a second and third atom, a four-qubit unit may comprise a first atom quantum mechanically entangled with a second, third, and fourth atom, and so forth. The first, second, third, or fourth atom may be in a superposition state at the time of quantum mechanical entanglement. Alternatively or in addition, the first, second, third, or fourth atom may not be in a superposition state at the time of quantum mechanical entanglement. The first, second, third, and fourth atom may be quantum mechanically entangled through one or more magnetic dipole interactions, induced magnetic dipole interactions, electric dipole interactions, or induced electric dipole interactions.

The entanglement units may comprise one or more Rydberg units. The Rydberg units may be configured to electronically excite the at least first atom to a Rydberg state or to a superposition of a Rydberg state and a lower-energy atomic state, thereby forming one or more Rydberg atoms or dressed Rydberg atoms. The Rydberg units may be configured to induce one or more quantum mechanical entanglements between the Rydberg atoms or dressed Rydberg atoms and the at least second atom. The second atom may be located at a distance of at least about 200 nanometers (nm), 300 nm, 400 nm, 500 nm, 600 nm, 700 nm, 800 nm, 900 nm, 1 micrometer (μm), 2 μm, 3 μm, 4 μm, 5 μm, 6 μm, 7 μm, 8 μm, 9 μm, 10 μm, or more from the Rydberg atoms or dressed Rydberg atoms. The second atom may be located at a distance of at most about 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, or less from the Rydberg atoms or dressed Rydberg atoms. The second atom may be located at a distance from the Rydberg atoms or dressed Rydberg atoms that is within a range defined by any two of the preceding values. The Rydberg units may be configured to allow the Rydberg atoms or dressed Rydberg atoms to relax to a lower-energy atomic state, thereby forming one or more two-qubit units. The Rydberg units may be configured to induce the Rydberg atoms or dressed Rydberg atoms to relax to a lower-energy atomic state. The Rydberg units may be configured to drive the Rydberg atoms or dressed Rydberg atoms to a lower-energy atomic state. For instance, the Rydberg units may be configured to apply electromagnetic radiation (such as RF radiation or optical radiation) to drive the Rydberg atoms or dressed Rydberg atoms to a lower-energy atomic state. The Rydberg units may be configured to induce any number of quantum mechanical entanglements between any number of atoms of the plurality of atoms.

The Rydberg units may comprise one or more light sources (such as any light source described herein) configured to emit light having one or more ultraviolet (UV) wavelengths. The UV wavelengths may be selected to correspond to a wavelength that forms the Rydberg atoms or dressed Rydberg atoms. For instance, the light may comprise one or more wavelengths of at least about 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, or more. The light may comprise one or more wavelengths of at most about 400 nm, 390 nm, 380 nm, 370 nm, 360 nm, 350 nm, 340 nm, 330 nm, 320 nm, 310 nm, 300 nm, 290 nm, 280 nm, 270 nm, 260 nm, 250 nm, 240 nm, 230 nm, 220 nm, 210 nm, 200 nm, or less. The light may comprise one or more wavelengths that are within a range defined by any two of the preceding values. For instance, the light may comprise one or more wavelengths that are within a range from 300 nm to 400 nm.

The Rydberg units may be configured to induce a two-photon transition to generate an entanglement. The Rydberg units may be configured to induce a two-photon transition to generate an entanglement between two atoms. The Rydberg units may be configured to selectively induce a two-photon transition to selectively generate an entanglement between two atoms. For instance, the Rydberg units may be configured to direct electromagnetic energy (such as optical energy) to particular optical trapping sites to selectively induce a two-photon transition to selectively generate the entanglement between the two atoms. The two atoms may be trapped in nearby optical trapping sites. For instance, the two atoms may be trapped in adjacent optical trapping sites. The two-photon transition may be induced using first and second light from first and second light sources, respectively. The first and second light sources may each comprise any light source described herein (such as any laser described herein). The first light source may be the same or similar to a light source used to perform a single-qubit operation described herein. Alternatively, different light sources may be used to perform a single-qubit operation and to induce a two-photon transition to generate an entanglement. The first light source may emit light comprising one or more wavelengths in the visible region of the optical spectrum (e.g., within a range from 400 nm to 800 nm or from 650 nm to 700 nm). The second light source may emit light comprising one or more wavelengths in the ultraviolet region of the optical spectrum (e.g., within a range from 200 nm to 400 nm or from 300 nm to 350 nm). The first and second light sources may emit light having substantially equal and opposite spatially-dependent frequency shifts.

The Rydberg atoms or dressed Rydberg atoms may comprise a Rydberg state that may have sufficiently strong interatomic interactions with nearby atoms (such as nearby atoms trapped in nearby optical trapping sites) to enable the implementation of multi-qubit operations. The Rydberg states may comprise a principal quantum number of at least about 50, 60, 70, 80, 90, 100, or more. The Rydberg states may comprise a principal quantum number of at most about 100, 90, 80, 70, 60, 50, or less. The Rydberg states may comprise a principal quantum number that is within a range defined by any two of the preceding values. The Rydberg states may interact with nearby atoms through van der Waals interactions. The van der Waals interactions may shift atomic energy levels of the atoms.

State selective excitation of atoms to Rydberg levels may enable the implementation of multi-qubit operations. The multi-qubit operations may comprise two-qubit operations, three-qubit operations, or n-qubit operations, where n is 4, 5, 6, 7, 8, 9, 10, or more. Two-photon transitions may be used to excite atoms from a ground state (such as a ¹S₀ ground state) to a Rydberg state (such as an n³S₁ state, wherein n is a principal quantum number described herein). State selectivity may be accomplished by a combination of laser polarization and spectral selectivity. The two-photon transitions may be implemented using first and second laser sources, as described herein. The first laser source may emit pi-polarized light, which may not change the projection of atomic angular momentum along a magnetic field. The second laser may emit circularly polarized light, which may change the projection of atomic angular momentum along the magnetic field by one unit. The first and second qubit levels may be excited to Rydberg level using this polarization. However, the Rydberg levels may be more sensitive to magnetic fields than the ground state so that large splittings (for instance, on the order of 100s of MHz) may be readily obtained. This spectral selectivity may allow state selective excitation to Rydberg levels.

Multi-qubit operations (such as two-qubit operations, three-qubit operations, four-qubit operations, and so forth) may rely on energy shifts of levels due to van der Waals interactions described herein. Such shifts may either prevent the excitation of one atom conditional on the state of the other or change the coherent dynamics of excitation of the two-atom system to enact a two-qubit operation. In some cases, “dressed states” may be generated under continuous driving to enact two-qubit operations without requiring full excitation to a Rydberg level (for instance, as described in www.arxiv.org/abs/1605.05207, which is incorporated herein by reference in its entirety for all purposes).

The system 200 may comprise one or more second electromagnetic delivery units (not shown in FIG. 2). The second electromagnetic delivery units may comprise any electromagnetic delivery unit described herein, such as an electromagnetic delivery unit described herein with respect to FIG. 4. The first and second electromagnetic delivery units may be the same. The first and second electromagnetic delivery units may be different. The second electromagnetic delivery units may be configured to apply second electromagnetic energy to the one or more multi-qubit units. The second electromagnetic energy may comprise one or more pulse sequences. The first electromagnetic energy may precede, be simultaneous with, or follow the second electromagnetic energy.

The pulse sequences may comprise any number of pulses. For instance, the pulse sequences may comprise at least about 1, 2, 3, 4, 5, 6, 7, 8, 9, 10, 20, 30, 40, 50, 60, 70, 80, 90, 100, 200, 300, 400, 500, 600, 700, 800, 900, 1,000, or more pulses. The pulse sequences may comprise at most about 1,000, 900, 800, 700, 600, 500, 400, 300, 200, 100, 90, 80, 70, 60, 50, 40, 30, 20, 10, 9, 8, 7, 6, 5, 4, 3, 2, or 1 pulses. The pulse sequences may comprise a number of pulses that is within a range defined by any two of the preceding values. Each pulse of the pulse sequence may comprise any pulse shape, such as any pulse shape described herein.

The pulse sequences may be configured to decrease the duration of time required to implement multi-qubit operations, as described herein (for instance, with respect to Example 3). For instance, the pulse sequences may comprise a duration of at least about 10 nanoseconds (ns), 20 ns, 30 ns, 40 ns, 50 ns, 60 ns, 70 ns, 80 ns, 90 ns, 100 ns, 200 ns, 300 ns, 400 ns, 500 ns, 600 ns, 700 ns, 800 ns, 900 ns, 1 microsecond (μs), 2 μs, 3 μs, 4 μs, 5 μs, 6 μs, 7 μs, 8 μs, 9 μs, 10 μs, 20 μs, 30 μs, 40 μs, 50 μs, 60 μs, 70 μs, 80 μs, 90 μs, 100 μs, or more. The pulse sequences may comprise a duration of at most about 100 μs, 90 μs, 80 μs, 70 μs, 60 μs, 50 μs, 40 μs, 30 μs, 20 μs, 10 μs, 9 μs, 8 μs, 7 μs, 6 μs, 5 μs, 4 μs, 3 μs, 2 μs, 1 μs, 900 ns, 800 ns, 700 ns, 600 ns, 500 ns, 400 ns, 300 ns, 200 ns, 100 ns, 90 ns, 80 ns, 70 ns, 60 ns, 50 ns, 40 ns, 30 ns, 20 ns, 10 ns, or less. The pulse sequences may comprise a duration that is within a range defined by any two of the preceding values.

The pulse sequences may be configured to increase the fidelity of multi-qubit operations, as described herein. For instance, the pulse sequences may enable multi-qubit operations with a fidelity of at least about 0.5, 0.6, 0.7, 0.8, 0.9, 0.91, 0.92, 0.93, 0.94, 0.95, 0.96, 0.97, 0.98, 0.99, 0.991, 0.992, 0.993, 0.994, 0.995, 0.996, 0.997, 0.998, 0.999, 0.9991, 0.9992, 0.9993, 0.9994, 0.9995, 0.9996, 0.9997, 0.9998, 0.9999, 0.99991, 0.99992, 0.99993, 0.99994, 0.99995, 0.99996, 0.99997, 0.99998, 0.99999, 0.999991, 0.999992, 0.999993, 0.999994, 0.999995, 0.999996, 0.999997, 0.999998, 0.999999, or more. The pulse sequences may enable multi-qubit operations with a fidelity of at most about 0.999999, 0.999998, 0.999997, 0.999996, 0.999995, 0.999994, 0.999993, 0.999992, 0.999991, 0.99999, 0.99998, 0.99997, 0.99996, 0.99995, 0.99994, 0.99993, 0.99992, 0.99991, 0.9999, 0.9998, 0.9997, 0.9996, 0.9995, 0.9994, 0.9993, 0.9992, 0.9991, 0.999, 0.998, 0.997, 0.996, 0.995, 0.994, 0.993, 0.992, 0.991, 0.99, 0.98, 0.97, 0.96, 0.95, 0.94, 0.93, 0.92, 0.91, 0.9, 0.8, 0.7, 0.6, 0.5, or less. The pulse sequences may enable multi-qubit operations with a fidelity that is within a range defined by any two of the preceding values.

The pulse sequences may enable the implementation of multi-qubit operations on non-adiabatic timescales while maintaining effectively adiabatic dynamics. For instance, the pulse sequences may comprise one or more of shortcut to adiabaticity (STA) pulse sequences, transitionless quantum driving (TQD) pulse sequences, superadiabatic pulse sequences, counterdiabatic driving pulse sequences, derivative removal by adiabatic gate (DRAG) pulse sequences, and weak anharmonicity with average Hamiltonian (Wah Wah) pulse sequences. For instance, the pulse sequences may be similar to those described in M. V. Berry, “Transitionless Quantum Driving,” Journal of Physics A: Mathematical and Theoretical 42 (36), 365303 (2009), www.doi.org/10.1088/1751-8113/42/36/365303; Y.-Y. Jau et al., “Entangling Atomic Spins with a Strong Rydberg-Dressed Interaction,” Nature Physics 12(1), 71-74(2016); T. Keating et al., “Robust Quantum Logic in Neutral Atoms via Adiabatic Rydberg Dressing,” Physical Review A 91, 012337 (2015); A. Mitra et al., “Robust Mölmer-Sörenson Gate for Neutral Atoms Using Rapid Adiabatic Rydberg Dressing,” www.arxiv.org/abs/1911.04045 (2019); or L. S. Theis et al., “Counteracting Systems of Diabaticities Using DRAG Controls: The Status after 10 Years,” Europhysics Letters 123(6), 60001(2018), each of which is incorporated herein by reference in its entirety for all purposes.

The pulse sequences may further comprise one or more optimal control pulse sequences. The optimal control pulse sequences may be derived from one or more procedures, including gradient ascent pulse engineering (GRAPE) methods, Krotov's method, chopped basis methods, chopped random basis (CRAB) methods, Nelder-Mead methods, gradient optimization using parametrization (GROUP) methods, genetic algorithm methods, and gradient optimization of analytic controls (GOAT) methods. For instance, the pulse sequences may be similar to those described in N. Khaneja et al., “Optimal Control of Coupled Spin Dynamics: Design of NMR Pulse Sequences by Gradient Ascent Algorithms,” Journal of Magnetic Resonance 172(2), 296-305 (2005); or J. T. Merrill et al., “Progress in Compensating Pulse Sequences for Quantum Computation,” Advances in Chemical Physics 154, 241-294 (2014), each of which is incorporated by reference in its entirety for all purposes.

### Examples of Cloud Computing

The system 200 may be operatively coupled to a digital computer described herein (such as a digital computer described herein with respect to FIG. 1) over a network described herein (such as a network described herein with respect to FIG. 1). The network may comprise a cloud computing network.

### Examples of Optical Trapping Units

FIG. 3A shows an example of an optical trapping unit 210. The optical trapping unit may be configured to generate a plurality 211 of spatially distinct optical trapping sites, as described herein. For instance, as shown in FIG. 3B, the optical trapping unit may be configured to generate a first optical trapping site 211a, second optical trapping site 211b, third optical trapping site 211c, fourth optical trapping site 211d, fifth optical trapping site 211e, sixth optical trapping site 211f, seventh optical trapping site 211g, eighth optical trapping site 211h, and ninth optical trapping site 211i, as depicted in FIG. 3A. The plurality of spatially distinct optical trapping sites may be configured to trap a plurality of atoms, such as first atom 212a, second atom 212b, third atom 212c, and fourth atom 212d, as depicted in FIG. 3A. As depicted in FIG. 3B, each optical trapping site may be configured to trap a single atom. As depicted in FIG. 3B, some of the optical trapping sites may be empty (i.e., not trap an atom).

As shown in FIG. 3B, the plurality of optical trapping sites may comprise a two-dimensional (2D) array. The 2D array may be perpendicular to the optical axis of optical components of the optical trapping unit depicted in FIG. 3A. Alternatively, the plurality of optical trapping sites may comprise a one-dimensional (1D) array or a three-dimensional (3D) array.

Although depicted as comprising nine optical trapping sites filled by four atoms in FIG. 3B, the optical trapping unit 210 may be configured to generate any number of spatially distinct optical trapping sites described herein and may be configured to trap any number of atoms described herein.

Each optical trapping site of the plurality of optical trapping sites may be spatially separated from each other optical trapping site by a distance of at least about 200 nm, 300 nm, 400 nm, 500 nm, 600 nm, 700 nm, 800 nm, 900 nm, 1 μm, 2 μm, 3 μm, 4 μm, 5 μm, 6 μm, 7 μm, 8 μm, 9 μm, 10 μm, or more. Each optical trapping site may be spatially separated from each other optical trapping site by a distance of at most about 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, or less. Each optical trapping site maybe spatially separated from each other optical trapping site by a distance that is within a range defined by any two of the preceding values.

The optical trapping sites may comprise one or more optical tweezers. Optical tweezers may comprise one or more focused laser beams to provide an attractive or repulsive force to hold or move the one or more atoms. The beam waist of the focused laser beams may comprise a strong electric field gradient. The atoms may be attracted or repelled along the electric field gradient to the center of the laser beam, which may contain the strongest electric field. The optical trapping sites may comprise one or more optical lattice sites of one or more optical lattices. The optical trapping sites may comprise one or more optical lattice sites of one or more one-dimensional (1D) optical lattices, two-dimensional (2D) optical lattices, or three-dimensional (3D) optical lattices. For instance, the optical trapping sites may comprise one or more optical lattice sites of a 2D optical lattice, as depicted in FIG. 3B.

The optical lattices may be generated by interfering counter-propagating light (such as counter-propagating laser light) to generate a standing wave pattern having a periodic succession of intensity minima and maxima along a particular direction. A 1D optical lattice may be generated by interfering a single pair of counter-propagating light beams. A 2D optical lattice may be generated by interfering two pairs of counter-propagating light beams. A 3D optical lattice may be generated by interfering three pairs of counter-propagating lights beams. The light beams may be generated by different light sources or by the same light source. Therefore, an optical lattice may be generated by at least about 1, 2, 3, 4, 5, 6, or more light sources or at most about 6, 5, 4, 3, 2, or 1 light sources.

Returning to the description of FIG. 3A, the optical trapping unit may comprise one or more light sources configured to emit light to generate the plurality of optical trapping sites as described herein. For instance, the optical trapping unit may comprise a single light source 213, as depicted in FIG. 3A. Though depicted as comprising a single light source in FIG. 3A, the optical trapping unit may comprise any number of light sources, such as at least about 1, 2, 3, 4, 5, 6, 7, 8, 9, 10, or more light sources or at most about 10, 9, 8, 7, 6, 5, 4, 3, 2, or 1 light sources. The light sources may comprise one or more lasers. The lasers may be configured to operate at a resolution limit of the lasers. For example, the lasers can be configured to provide diffraction limited spot sizes for optical trapping.

The lasers may comprise one or more continuous wave lasers. The lasers may comprise one or more pulsed lasers. The lasers may comprise one or more gas lasers, such as one or more helium-neon (HeNe) lasers, argon (Ar) lasers, krypton (Kr) lasers, xenon (Xe) ion lasers, nitrogen (N₂) lasers, carbon dioxide (CO₂) lasers, carbon monoxide (CO) lasers, transversely excited atmospheric (TEA) lasers, or excimer lasers. For instance, the lasers may comprise one or more argon dimer (Ar₂) excimer lasers, krypton dimer (Kr₂) excimer lasers, fluorine dimer (F₂) excimer lasers, xenon dimer (Xe₂) excimer lasers, argon fluoride (ArF) excimer lasers, krypton chloride (KrCl) excimer lasers, krypton fluoride (KrF) excimer lasers, xenon bromide (XeBr) excimer lasers, xenon chloride (XeCl) excimer lasers, or xenon fluoride (XeF) excimer lasers. The laser may comprise one or more dye lasers.

The lasers may comprise one or more metal-vapor lasers, such as one or more helium-cadmium (HeCd) metal-vapor lasers, helium-mercury (HeHg) metal-vapor lasers, helium-selenium (HeSe) metal-vapor lasers, helium-silver (HeAg) metal-vapor lasers, strontium (Sr) metal-vapor lasers, neon-copper (NeCu) metal-vapor lasers, copper (Cu) metal-vapor lasers, gold (Au) metal-vapor lasers, manganese (Mn) metal-vapor laser, or manganese chloride (MnCl₂) metal-vapor lasers.

The lasers may comprise one or more solid-state lasers, such as one or more ruby lasers, metal-doped crystal lasers, or metal-doped fiber lasers. For instance, the lasers may comprise one or more neodymium-doped yttrium aluminum garnet (Nd:YAG) lasers, neodymium/chromium doped yttrium aluminum garnet (Nd/Cr:YAG) lasers, erbium-doped yttrium aluminum garnet (Er:YAG) lasers, neodymium-doped yttrium lithium fluoride (Nd:YLF) lasers, neodymium-doped yttrium orthovanadate (ND:YVO₄) lasers, neodymium-doped yttrium calcium oxoborate (Nd:YCOB) lasers, neodymium glass (Nd:glass) lasers, titanium sapphire (Ti:sapphire) lasers, thulium-doped ytrium aluminum garnet (Tm:YAG) lasers, ytterbium-doped ytrrium aluminum garnet (Yb:YAG) lasers, ytterbium-doped glass (Yt:glass) lasers, holmium ytrrium aluminum garnet (Ho:YAG) lasers, chromium-doped zinc selenide (Cr:ZnSe) lasers, cerium-doped lithium strontium aluminum fluoride (Ce:LiSAF) lasers, cerium-doped lithium calcium aluminum fluoride (Ce:LiCAF) lasers, erbium-doped glass (Er:glass) lasers, erbium-ytterbium-codoped glass (Er/Yt:glass) lasers, uranium-doped calcium fluoride (U:CaF₂) lasers, or samarium-doped calcium fluoride (Sm:CaF₂) lasers.

The lasers may comprise one or more semiconductor lasers or diode lasers, such as one or more gallium nitride (GaN) lasers, indium gallium nitride (InGaN) lasers, aluminum gallium indium phosphide (AlGaInP) lasers, aluminum gallium arsenide (AlGaAs) lasers, indium gallium arsenic phosphide (InGaAsP) lasers, vertical cavity surface emitting lasers (VCSELs), or quantum cascade lasers.

The lasers may emit continuous wave laser light. The lasers may emit pulsed laser light. The lasers may have a pulse length of at least about 1 femtoseconds (fs), 2 fs, 3 fs, 4 fs, 5 fs, 6 fs, 7 fs, 8 fs, 9 fs, 10 fs, 20 fs, 30 fs, 40 fs, 50 fs, 60 fs, 70 fs, 80 fs, 90 fs, 100 fs, 200 fs, 300 fs, 400 fs, 500 fs, 600 fs, 700 fs, 800 fs, 900 fs, 1 picosecond (ps), 2 ps, 3 ps, 4 ps, 5 ps, 6 ps, 7 ps, 8 ps, 9 ps, 10 ps, 20 ps, 30 ps, 40 ps, 50 ps, 60 ps, 70 ps, 80 ps, 90 ps, 100 ps, 200 ps, 300 ps, 400 ps, 500 ps, 600 ps, 700 ps, 800 ps, 900 ps, 1 nanosecond (ns), 2 ns, 3 ns, 4 ns, 5 ns, 6 ns, 7 ns, 8 ns, 9 ns, 10 ns, 20 ns, 30 ns, 40 ns, 50 ns, 60 ns, 70 ns, 80 ns, 90 ns, 100 ns, 200 ns, 300 ns, 400 ns, 500 ns, 600 ns, 700 ns, 800 ns, 900 ns, 1,000 ns, or more. The lasers may have a pulse length of at most about 1,000 ns, 900 ns, 800 ns, 700 ns, 600 ns, 500 ns, 400 ns, 300 ns, 200 ns, 100 ns, 90 ns, 80 ns, 70 ns, 60 ns, 50 ns, 40 ns, 30 ns, 20 ns, 10 ns, 9 ns, 8 ns, 7 ns, 6 ns, 5 ns, 4 ns, 3 ns, 2 ns, 1 ns, 900 ps, 800 ps, 700 ps, 600 ps, 500 ps, 400 ps, 300 ps, 200 ps, 100 ps, 90 ps, 80 ps, 70 ps, 60 ps, 50 ps, 40 ps, 30 ps, 20 ps, 10 ps, 9 ps, 8 ps, 7 ps, 6 ps, 5 ps, 4 ps, 3 ps, 2 ps, 1 ps, 900 fs, 800 fs, 700 fs, 600 fs, 500 fs, 400 fs, 300 fs, 200 fs, 100 fs, 90 fs, 80 fs, 70 fs, 60 fs, 50 fs, 40 fs, 30 fs, 20 fs, 10 fs, 9 fs, 8 fs, 7 fs, 6 fs, 5 fs, 4 fs, 3 fs, 2 fs, 1 fs, or less. The lasers may have a pulse length that is within a range defined by any two of the preceding values.

The lasers may have a repetition rate of at least about 1 hertz (Hz), 2 Hz, 3 Hz, 4 Hz, 5 Hz, 6 Hz, 7 Hz, 8 Hz, 9 Hz, 10 Hz, 20 Hz, 30 Hz, 40 Hz, 50 Hz, 60 Hz, 70 Hz, 80 Hz, 90 Hz, 100 Hz, 200 Hz, 300 Hz, 400 Hz, 500 Hz, 600 Hz, 700 Hz, 800 Hz, 900 Hz, 1 kilohertz (kHz), 2 kHz, 3 kHz, 4 kHz, 5 kHz, 6 kHz, 7 kHz, 8 kHz, 9 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, 1 megahertz (MHz), 2 MHz, 3 MHz, 4 MHz, 5 MHz, 6 MHz, 7 MHz, 8 MHz, 9 MHz, 10 MHz, 20 MHz, 30 MHz, 40 MHz, 50 MHz, 60 MHz, 70 MHz, 80 MHz, 90 MHz, 100 MHz, 200 MHz, 300 MHz, 400 MHz, 500 MHz, 600 MHz, 700 MHz, 800 MHz, 900 MHz, 1,000 MHz, or more. The lasers may have a repetition rate of at most about 1,000 MHz, 900 MHz, 800 MHz, 700 MHz, 600 MHz, 500 MHz, 400 MHz, 300 MHz, 200 MHz, 100 MHz, 90 MHz, 80 MHz, 70 MHz, 60 MHz, 50 MHz, 40 MHz, 30 MHz, 20 MHz, 10 MHz, 9 MHz, 8 MHz, 7 MHz, 6 MHz, 5 MHz, 4 MHz, 3 MHz, 2 MHz, 1 MHz, 900 kHz, 800 kHz, 700 kHz, 600 kHz, 500 kHz, 400 kHz, 300 kHz, 200 kHz, 100 kHz, 90 kHz, 80 kHz, 70 kHz, 60 kHz, 50 kHz, 40 kHz, 30 kHz, 20 kHz, 10 kHz, 9 kHz, 8 kHz, 7 kHz, 6 kHz, 5 kHz, 4 kHz, 3 kHz, 2 kHz, 1 kHz, 900 Hz, 800 Hz, 700 Hz, 600 Hz, 500 Hz, 400 Hz, 300 Hz, 200 Hz, 100 Hz, 90 Hz, 80 Hz, 70 Hz, 60 Hz, 50 Hz, 40 Hz, 30 Hz, 20 Hz, 10 Hz, 9 Hz, 8 Hz, 7 Hz, 6 Hz, 5 Hz, 4 Hz, 3 Hz, 2 Hz, 1 Hz, or less. The lasers may have a repetition rate that is within a range defined by any two of the preceding values.

The lasers may emit light having a pulse energy of at least about 1 nanojoule (nJ), 2 nJ, 3 nJ, 4 nJ, 5 nJ, 6 nJ, 7 nJ, 8 nJ, 9 nJ, 10 nJ, 20 nJ, 30 nJ, 40 nJ, 50 nJ, 60 nJ, 70 nJ, 80 nJ, 90 nJ, 100 nJ, 200 nJ, 300 nJ, 400 nJ, 500 nJ, 600 nJ, 700 nJ, 800 nJ, 900 nJ, 1 microjoule (μJ), 2 μJ, 3 μJ, 4 μJ, 5 μJ, 6 μJ, 7 μJ, 8 μJ, 9 μJ, 10 μJ, 20 μJ, 30 μJ, 40 μJ, 50 μJ, 60 μJ, 70 μJ, 80 μJ, 90 μJ, 100 μJ, 200 μJ, 300 μJ, 400 J, 500 μJ, 600 μJ, 700 μJ, 800 μJ, 900 μJ, a least 1 millijoule (mJ), 2 mJ, 3 mJ, 4 mJ, 5 mJ, 6 mJ, 7 mJ, 8 mJ, 9 mJ, 10 mJ, 20 mJ, 30 mJ, 40 mJ, 50 mJ, 60 mJ, 70 mJ, 80 mJ, 90 mJ, 100 mJ, 200 mJ, 300 mJ, 400 mJ, 500 mJ, 600 mJ, 700 mJ, 800 mJ, 900 mJ, a least 1 Joule (J), or more. The lasers may emit light having a pulse energy of at most about 1 J, 900 mJ, 800 mJ, 700 mJ, 600 mJ, 500 mJ, 400 mJ, 300 mJ, 200 mJ, 100 mJ, 90 mJ, 80 mJ, 70 mJ, 60 mJ, 50 mJ, 40 mJ, 30 mJ, 20 mJ, 10 mJ, 9 mJ, 8 mJ, 7 mJ, 6 mJ, 5 mJ, 4 mJ, 3 mJ, 2 mJ, 1 mJ, 900 μJ, 800 μJ, 700 μJ, 600 μJ, 500 μJ, 400 μJ, 300 μJ, 200 μJ, 100 μJ, 90 μJ, 80 ρJ, 70 μJ, 60 μJ, 50 μJ, 40 μJ, 30 μJ, 20 μJ, 10 μJ, 9 μJ, 8 μJ, 7 μJ, 6 μJ, 5 μJ, 4 μJ, 3 μJ, 2 μJ, 1 μJ, 900 nJ, 800 nJ, 700 nJ, 600 nJ, 500 nJ, 400 nJ, 300 nJ, 200 nJ, 100 nJ, 90 nJ, 80 nJ, 70 nJ, 60 nJ, 50 nJ, 40 nJ, 30 nJ, 20 nJ, 10 nJ, 9 nJ, 8 nJ, 7 nJ, 6 nJ, 5 nJ, 4 nJ, 3 nJ, 2 nJ, 1 nJ, or less. The lasers may emit light having a pulse energy that is within a range defined by any two of the preceding values.

The lasers may emit light having an average power of at least about 1 microwatt (μW), 2 μW, 3 μW, 4 μW, 5 μW, 6 μW, 7 μW, 8 μW, 9 μW, 10 μW, 20 μW, 30 μW, 40 μW, 50 μW, 60 μW, 70 μW, 80 μW, 90 μW, 100 μW, 200 μW, 300 μW, 400 μW, 500 μW, 600 μW, 700 μW, 800 μW, 900 μW, 1 milliwatt (mW), 2 mW, 3 mW, 4 mW, 5 mW, 6 mW, 7 mW, 8 mW, 9 mW, 10 mW, 20 mW, 30 mW, 40 mW, 50 mW, 60 mW, 70 mW, 80 mW, 90 mW, 100 mW, 200 mW, 300 mW, 400 mW, 500 mW, 600 mW, 700 mW, 800 mW, 900 mW, 1 watt (W), 2 W, 3 W, 4 W, 5 W, 6 W, 7 W, 8 W, 9 W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, 1,000 W, or more. The lasers may emit light having an average power of at most about 1,000 W, 900 W, 800 W, 700 W, 600 W, 500 W, 400 W, 300 W, 200 W, 100 W, 90 W, 80 W, 70 W, 60 W, 50 W, 40 W, 30 W, 20 W, 10 W, 9 W, 8 W, 7 W, 6 W, 5 W, 4 W, 3 W, 2 W, 1 W, 900 mW, 800 mW, 700 mW, 600 mW, 500 mW, 400 mW, 300 mW, 200 mW, 100 mW, 90 mW, 80 mW, 70 mW, 60 mW, 50 mW, 40 mW, 30 mW, 20 mW, 10 mW, 9 mW, 8 mW, 7 mW, 6 mW, 5 mW, 4 mW, 3 mW, 2 mW, 1 mW, 900 μW, 800 μW, 700 μW, 600 μW, 500 μW, 400 μW, 300 μW, 200 μW, 100 μW, 90 μW, 80 μW, 70 μW, 60 μW, 50 μW, 40 μW, 30 μW, 20 μW, 10 μW, 9 μW, 8 μW, 7 μW, 6 μW, 5 μW, 4 μW, 3 μW, 2 μW, 1 μW, or more. The lasers may emit light having a power that is within a range defined by any two of the preceding values.

The lasers may emit light comprising one or more wavelengths in the ultraviolet (UV), visible, or infrared (IR) portions of the electromagnetic spectrum. The lasers may emit light comprising one or more wavelengths of at least about 200 nm, 210 nm, 220 nm, 230 nm, 240 nm, 250 nm, 260 nm, 270 nm, 280 nm, 290 nm, 300 nm, 310 nm, 320 nm, 330 nm, 340 nm, 350 nm, 360 nm, 370 nm, 380 nm, 390 nm, 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, 1,010 nm, 1,020 nm, 1,030 nm, 1,040 nm, 1,050 nm, 1,060 nm, 1,070 nm, 1,080 nm, 1,090 nm, 1,100 nm, 1,110 nm, 1,120 nm, 1,130 nm, 1,140 nm, 1,150 nm, 1,160 nm, 1,170 nm, 1,180 nm, 1,190 nm, 1,200 nm, 1,210 nm, 1,220 nm, 1,230 nm, 1,240 nm, 1,250 nm, 1,260 nm, 1,270 nm, 1,280 nm, 1,290 nm, 1,300 nm, 1,310 nm, 1,320 nm, 1,330 nm, 1,340 nm, 1,350 nm, 1,360 nm, 1,370 nm, 1,380 nm, 1,390 nm, 1,400 nm, or more. The lasers may emit light comprising one or more wavelengths of at most about 1,400 nm, 1,390 nm, 1,380 nm, 1,370 n, 1,360 nm, 1,350 nm, 1,340 nm, 1,330 nm, 1,320 nm, 1,310 nm, 1,300 nm, 1,290 nm, 1,280 nm, 1,270 n, 1,260 nm, 1,250 nm, 1,240 nm, 1,230 nm, 1,220 nm, 1,210 nm, 1,200 nm, 1,190 nm, 1,180 nm, 1,170 n, 1,160 nm, 1,150 nm, 1,140 nm, 1,130 nm, 1,120 nm, 1,110 nm, 1,100 nm, 1,090 nm, 1,080 nm, 1,070 n, 1,060 nm, 1,050 nm, 1,040 nm, 1,030 nm, 1,020 nm, 1,010 nm, 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, 390 nm, 380 nm, 370 nm, 360 nm, 350 nm, 340 nm, 330 nm, 320 nm, 310 nm, 300 nm, 290 nm, 280 nm, 270 nm, 260 nm, 250 nm, 240 nm, 230 nm, 220 nm, 210 nm, 200 nm. The lasers may emit light comprising one or more wavelengths that are within a range defined by any two of the preceding values.

The lasers may emit light having a bandwidth of at least about 1×10⁻¹⁵ nm, 2×10⁻¹⁵ nm, 3×10⁻¹⁵ nm, 4×10⁻¹⁵ nm, 5×10⁻¹⁵ nm, 6×10⁻¹⁵ nm, 7×10⁻¹⁵ nm, 8×10⁻¹⁵ nm, 9×10⁻¹⁵ nm, 1×10⁻¹⁴ nm, 2×10⁻¹⁴ nm, 3×10⁻¹⁴ nm, 4×10⁻¹⁴ nm, 5×10⁻¹⁴ nm, 6×10⁻¹⁴ nm, 7×10⁻¹⁴ nm, 8×10⁻¹⁴ nm, 9×10⁻¹⁴ nm, 1×10⁻¹³ nm, 2×10⁻¹³ nm, 3×10⁻¹³ nm, 4×10⁻¹³ nm, 5×10⁻¹³ nm, 6×10⁻¹³ nm, 7×10⁻¹³ nm, 8×10⁻¹³ nm, 9×10⁻¹³ nm, 1×10⁻¹² nm, 2×10⁻¹² nm, 3×10⁻¹² nm, 4×10⁻¹² nm, 5×10⁻¹² nm, 6×10⁻¹² nm, 7×10⁻¹² nm, 8×10⁻¹² nm, 9×10⁻¹² nm, 1×10⁻¹¹ nm, 2×10⁻¹¹ nm, 3×10⁻¹¹ nm, 4×10⁻¹¹ nm, 5×10⁻¹¹ nm, 6×10⁻¹¹ nm, 7×10⁻¹¹ nm, 8×10⁻¹¹ nm, 9×10⁻¹¹ nm, 1×10⁻¹⁰ nm, 2×10⁻¹⁰ nm, 3×10⁻¹⁰ nm, 4×10⁻¹⁰ nm, 5×10⁻¹⁰ nm, 6×10⁻¹⁰ nm, 7×10⁻¹⁰ nm, 8×10⁻¹⁰ nm, 9×10⁻¹⁰ nm, 1×10⁻⁹ nm, 2×10⁻⁹ nm, 3×10⁻⁹ nm, 4×10⁻⁹ nm, 5×10⁻⁹ nm, 6×10⁻⁹ nm, 7×10⁻⁹ nm, 8×10⁻⁹ nm, 9×10⁻⁹ nm, 1×10⁻⁸ nm, 2×10⁻⁸ nm, 3×10⁻⁸ nm, 4×10⁻⁸ nm, 5×10⁻⁸ nm, 6×10⁻⁸ nm, 7×10⁻⁸ nm, 8×10⁻⁸ nm, 9×10⁻⁸ nm, 1×10⁻⁷ nm, 2×10⁻⁷ nm, 3×10⁻⁷ nm, 4×10⁻⁷ nm, 5×10⁻⁷ nm, 6×10⁻⁷ nm, 7×10⁻⁷ nm, 8×10⁻⁷ nm, 9×10⁻⁷ nm, 1×10⁻⁶ nm, 2×10⁻⁶ nm, 3×10⁻⁶ nm, 4×10⁻⁶ nm, 5×10⁻⁶ nm, 6×10⁻⁶ nm, 7×10⁻⁶ nm, 8×10⁶ nm, 9×10⁻⁶ nm, 1×10⁻⁵ nm, 2×10⁻⁵ nm, 3×10⁻⁵ nm, 4×10⁻⁵ nm, 5×10⁻⁵ nm, 6×10⁻⁵ nm, 7×10⁻⁵ nm, 8×10⁻⁵ nm, 9×10⁻⁵ nm, 1×10⁻⁴ nm, 2×10⁻⁴ nm, 3×10⁻⁴ nm, 4×10⁻⁴ nm, 5×10⁻⁴ nm, 6×10⁻⁴ nm, 7×10⁻⁴ nm, 8×10⁻⁴ nm, 9×10⁻⁴ nm, 1×10⁻³ nm, or more. The lasers may emit light having a bandwidth of at most about 1×10⁻³ nm, 9×10⁻⁴ nm, 8×10⁻⁴ nm, 7×10⁻⁴ nm, 6×10⁻⁴ nm, 5×10⁻⁴ nm, 4×10⁻⁴ nm, 3×10⁻⁴ nm, 2×10⁻⁴ nm, 1×10⁻⁴ nm, 9×10⁻⁵ nm, 8×10⁻⁵ nm, 7×10⁻⁵ nm, 6×10⁻⁵ nm, 5×10⁻⁵ nm, 4×10⁻⁵ nm, 3×10⁻⁵ nm, 2×10⁵ nm, 1×10⁻⁵ nm, 9×10⁻⁶ nm, 8×10⁻⁶ nm, 7×10⁻⁶ nm, 6×10⁻⁶ nm, 5×10⁻⁶ nm, 4×10⁻⁶ nm, 3×10⁻⁶ nm, 2×10⁻⁶ nm, 1×10⁻⁶ nm, 9×10⁻⁷ nm, 8×10⁻⁷ nm, 7×10⁻⁷ nm, 6×10⁻⁷ nm, 5×10⁻⁷ nm, 4×10⁻⁷ nm, 3×10⁻⁷ nm, 2×10⁻⁷ nm, 1×10⁻⁷ nm, 9×10⁻⁸ nm, 8×10⁻⁸ nm, 7×10⁻⁸ nm, 6×10⁻⁸ nm, 5×10⁻⁸ nm, 4×10⁻⁸ nm, 3×10⁻⁸ nm, 2×10⁻⁸ nm, 1×10⁻⁸ nm, 9×10⁻⁹ nm, 8×10⁻⁹ nm, 7×10⁻⁹ nm, 6×10⁻⁹ nm, 5×10⁻⁹ nm, 4×10⁻⁹ nm, 3×10⁻⁹ nm, 2×10⁻⁹ nm, 1×10⁻⁹ nm, 9×10⁻¹⁰ nm, 8×10⁻¹⁰ nm, 7×10⁻¹⁰ nm, 6×10⁻¹⁰ nm, 5×10⁻¹⁰ nm, 4×10⁻¹⁰ nm, 3×10⁻¹⁰ nm, 2×10⁻¹⁰ nm, 1×10⁻¹⁰ nm, 9×10⁻¹¹ nm, 8×10⁻¹¹ nm, 7×10⁻¹¹ nm, 6×10⁻¹¹ nm, 5×10⁻¹¹ nm, 4×10⁻¹¹ nm, 3×10⁻¹¹ nm, 2×10⁻¹¹ nm, 1×10⁻¹¹ nm, 9×10⁻¹² nm, 8×10⁻¹² nm, 7×10⁻¹² nm, 6×10⁻¹² nm, 5×10⁻¹² nm, 4×10⁻¹² nm, 3×10⁻¹² nm, 2×10⁻¹² nm, 1×10⁻¹² nm, 9×10⁻¹³ nm, 8×10⁻¹³ nm, 7×10⁻¹³ nm, 6×10⁻¹³ nm, 5×10⁻¹³ nm, 4×10⁻¹³ nm, 3×10⁻¹³ nm, 2×10⁻¹³ nm, 1×10⁻¹³ nm, 9×10⁻¹⁴ nm, 8×10⁻¹⁴ nm, 7×10⁻¹⁴ nm, 6×10⁻¹⁴ nm, 5×10⁻¹⁴ nm, 4×10⁻¹⁴ nm, 3×10⁻¹⁴ nm, 2×10⁻¹⁴ nm, 1×10⁻¹⁴ nm, 9×10⁻¹⁵ nm, 8×10⁻¹⁵ nm, 7×10⁻¹⁵ nm, 6×10⁻¹⁵ nm, 5×10⁻¹⁵ nm, 4×10⁻¹⁵ nm, 3×10⁻¹⁵ nm, 2×10⁻¹⁵ nm, 1×10⁻¹⁵ nm, or less. The lasers may emit light having a bandwidth that is within a range defined by any two of the preceding values.

The light sources may be configured to emit light tuned to one or more magic wavelengths corresponding to the plurality of atoms. A magic wavelength corresponding to an atom may comprise any wavelength of light that gives rise to equal or nearly equal polarizabilities of the first and second atomic states. The magic wavelengths for a transition between the first and second atomic states may be determined by calculating the wavelength-dependent polarizabilities of the first and second atomic states and finding crossing points. Light tuned to such a magic wavelength may give rise to equal or nearly equal differential light shifts in the first and second atomic states, regardless of the intensity of the light emitted by the light sources. This may effectively decouple the first and second atomic states from motion of the atoms. The magic wavelengths may utilize one or more scalar or tensor light shifts. The scalar or tensor light shifts may depend on magnetic sublevels within the first and second atomic states.

For instance, group III atoms and metastable states of alkaline earth or alkaline earth-like atoms may possess relatively large tensor shifts whose angle relative to an applied magnetic field may be tuned to cause a situation in which scalar and tensor shifts balance and give a zero or near zero differential light shift between the first and second atomic states. The angle θ may be tuned by selecting the polarization of the emitted light. For instance, when the emitted light is linearly polarized, the total polarizability a may be written as a sum of the scalar component α_{scalar} and the tensor component αₜₑₙₛₒᵣ.

$$α = {α}_{s c a l a r} + ( 3 cos {θ}^{2} - 1 ) {α}_{t e n s o r}$$

By choosing θ appropriately, the polarizability of the first and second atomic states may be chosen to be equal or nearly equal, corresponding to a zero or near zero differential light shift and the motion of the atoms may be decoupled.

The light sources may be configured to direct light to one or more optical modulators (OMs) configured to generate the plurality of optical trapping sites. For instance, the optical trapping unit may comprise an OM 214 configured to generate the plurality of optical trapping sites. Although depicted as comprising one OM in FIG. 3A, the optical trapping unit may comprise any number of OMs, such as at least about 1, 2, 3, 4, 5, 6, 7, 8, 9, 10, or more OMs or at most about 10, 9, 8, 7, 6, 5, 4, 3, 2, or 1 OMs. The OMs may comprise one or more digital micromirror devices (DMDs). The OMs may comprise one or more liquid crystal devices, such as one or more liquid crystal on silicon (LCoS) devices. The OMs may comprise one or more spatial light modulators (SLMs). The OMs may comprise one or more acousto-optic deflectors (AODs) or acousto-optic modulators (AOMs). The OMs may comprise one or more electro-optic deflectors (EODs) or electro-optic modulators (EOMs).

The OM may be optically coupled to one or more optical element to generate a regular array of optical trapping sites. For instance, the OM may be optically coupled to optical element 219, as shown in FIG. 3A. The optical elements may comprise lenses or microscope objectives configured to re-direct light from the OMs to form a regular rectangular grid of optical trapping sites.

For instance, as shown in FIG. 3A, the OM may comprise an SLM, DMD, or LCoS device. The SLM, DMD, or LCOS device may be imaged onto the back focal plane of the microscope objectives. This may allow for the generation of an arbitrary configuration of optical trapping sites in two or three dimensions.

Alternatively or in addition, the OMs may comprise first and second AODs. The active regions of the first and second AODs may be imaged onto the back focal plane of the microscope objectives. The output of the first AOD may be optically coupled to the input of the second AOD. In this manner, the second AOD may make a copy of the optical output of the first AOD. This may allow for the generation of optical trapping sites in two or three dimensions.

Alternatively or in addition, the OMs may comprise static optical elements, such as one or more microlens arrays or holographic optical elements. The static optical elements may be imaged onto the back focal plane of the microscope objectives. This may allow for the generation of an arbitrary configuration of optical trapping sites in two or three dimensions.

The optical trapping unit may comprise one or more imaging units configured to obtain one or more images of a spatial configuration of the plurality of atoms trapped within the optical trapping sites. For instance, the optical trapping unit may comprise imaging unit 215. Although depicted as comprising a single imaging unit in FIG. 3A, the optical trapping unit may comprise any number of imaging units, such as at least about 1, 2, 3, 4, 5, 6, 7, 8, 9, 10, or more imaging units or at most about 10, 9, 8, 7, 6, 5, 4, 3, 2, or 1 imaging units. The imaging units may comprise one or more lens or objectives. The imaging units may comprise one or more PMTs, photodiodes, avalanche photodiodes, phototransistors, reverse-biased LEDs, CCDs, or CMOS cameras. The imaging unit may comprise one or more fluorescence detectors. The images may comprise one or more fluorescence images, single-atom fluorescence images, absorption images, single-atom absorption images, phase contrast images, or single-atom phase contrast images.

The optical trapping unit may comprise one or more spatial configuration artificial intelligence (AI) units configured to perform one or more AI operations to determine the spatial configuration of the plurality of atoms trapped within the optical trapping sites based on the images obtained by the imaging unit. For instance, the optical trapping unit may comprise spatial configuration AI unit 216. Although depicted as comprising a single spatial configuration AI unit in FIG. 3A, the optical trapping unit may comprise any number of spatial configuration AI units, such as at least about 1, 2, 3, 4, 5, 6, 7, 8, 9, 10, or more spatial configuration AI units or at most about 10, 9, 8, 7, 6, 5, 4, 3, 2, or 1 spatial configuration AI units. The AI operations may comprise any machine learning (ML) or reinforcement learning (RL) operations described herein.

The optical trapping unit may comprise one or more atom rearrangement units configured to impart an altered spatial arrangement of the plurality of atoms trapped with the optical trapping sites based on the one or more images obtained by the imaging unit. For instance, the optical trapping unit may comprise atom rearrangement unit 217. Although depicted as comprising a single atom rearrangement unit in FIG. 3A, the optical trapping unit may comprise any number of atom rearrangement units, such as at least about 1, 2, 3, 4, 5, 6, 7, 8, 9, 10, or more atom rearrangement units or at most about 10, 9, 8, 7, 6, 5, 4, 3, 2, or 1 atom rearrangement units.

The optical trapping unit may comprise one or more spatial arrangement artificial intelligence (AI) units configured to perform one or more AI operations to determine the altered spatial arrangement of the plurality of atoms trapped within the optical trapping sites based on the images obtained by the imaging unit. For instance, the optical trapping unit may comprise spatial arrangement AI unit 218. Although depicted as comprising a single spatial arrangement AI unit in FIG. 3A, the optical trapping unit may comprise any number of spatial arrangement AI units, such as at least about 1, 2, 3, 4, 5, 6, 7, 8, 9, 10, or more spatial arrangement AI units or at most about 10, 9, 8, 7, 6, 5, 4, 3, 2, or 1 spatial arrangement AI units. The AI operations may comprise any machine learning (ML) or reinforcement learning (RL) operations described herein.

In some cases, the spatial configuration AI units and the spatial arrangement AI units may be integrated into an integrated AI unit. The optical trapping unit may comprise any number of integrated AI units, such as at least about 1, 2, 3, 4, 5, 6, 7, 8, 9, 10, or more integrated AI units, or at most about 10, 9, 8, 7, 6, 5, 4, 3, 2, or 1 integrated AI units.

The atom rearrangement unit may be configured to alter the spatial arrangement in order to obtain an increase in a filling factor of the plurality of optical trapping sites. A filling factor may be defined as a ratio of the number of computationally active optical trapping sites occupied by one or more atoms to the total number of computationally active optical trapping sites available in the optical trapping unit or in a portion of the optical trapping unit. For instance, initial loading of atoms within the computationally active optical trapping sites may give rise to a filling factor of less than 100%, 90%, 80%, 70%, 60%, 50%, or less, such that atoms occupy fewer than 100%, 90%, 70%, 60%, 50%, or less of the available computationally active optical trapping sites, respectively. It may be desirable to rearrange the atoms to achieve a filling factor of at least about 50%, 60%, 70%, 80%, 90%, or 100%. By analyzing the imaging information obtained by the imaging unit, the atom rearrangement unit may attain a filling factor of at least about 50%, 60%, 70%, 80%, 90%, 91%, 92%, 93%, 94%, 95%, 96%, 97%, 98%, 99%, 99.1%, 99.2%, 99.3%, 99.4%, 99.5%, 99.6%, 99.7%, 99.8%, 99.9%, 99.91%, 99.92%, 99.93%, 99.94%, 99.95%, 99.96%, 99.97%, 99.98%, 99.99%, or more. The atom rearrangement unit may attain a filling factor of at most about 99.99%, 99.98%, 99.97%, 99.96%, 99.95%, 99.94%, 99.93%, 99.92%, 99.91%, 99.9%, 99.8%, 99.7%, 99.6%, 99.5%, 99.4%, 99.3%, 99.2%, 99.1%, 99%, 98%, 97%, 96%, 95%, 94%, 93%, 92%, 91%, 90%, 80%, 70%, 60%, 50%, or less. The atom rearrangement unit may attain a filling factor that is within a range defined by any two of the preceding values.

By way of example, FIG. 3C shows an example of an optical trapping unit that is partially filled with atoms. As depicted in FIG. 3C, initial loading of atoms within the optical trapping sites may give rise to a filling factor of 44.4% (4 atoms filling 9 available optical trapping sites). By moving atoms from different regions of the optical trapping unit (not shown in FIG. 3C) to unoccupied optical trapping sites or by moving atoms from an atom reservoir described herein, a much higher filling factor may be obtained, as shown in FIG. 3D.

FIG. 3D shows an example of an optical trapping unit that is completely filled with atoms. As depicted in FIG. 3D, fifth atom 212e, sixth atom 212f, seventh atom 212g, eighth atom 212h, and ninth atom 212i may be moved to fill unoccupied optical trapping sites. The fifth, sixth, seventh, eighth, and ninth atoms may be moved from different regions of the optical trapping unit (not shown in FIG. 3C) or by moving atoms from an atom reservoir described herein. Thus, the filling factor may be substantially improved following rearrangement of atoms within the optical trapping sites. For instance, a filling factor of up to 100% (such 9 atoms filling 9 available optical trapping sites, as shown in FIG. 3D) may be attained.

Atom rearrangement may be performed by (i) acquiring an image of the optical trapping unit, identifying filled and unfilled optical trapping sites, (ii) determining a set of moves to bring atoms from filled optical trapping sites to unfilled optical trapping sites, and (iii) moving the atoms from filled optical trapping sites to unfilled optical trapping sites. Operations (i), (ii), and (iii) may be performed iteratively until a large filling factor is achieved. Operation (iii) may comprise translating the moves identified in operation (ii) to waveforms that may be sent to an arbitrary waveform generator (AWG) and using the AWG to drive AODs to move the atoms. The set of moves may be determined using the Hungarian algorithm described in W. Lee et al, “Defect-Free Atomic Array Formation Using Hungarian Rearrangement Algorithm,” Physical Review A 95, 053424 (2017), which is incorporated herein by reference in its entirety for all purposes.

### Examples of Electromagnetic Delivery Units

FIG. 4 shows an example of an electromagnetic delivery unit 220. The electromagnetic delivery unit may be configured to apply electromagnetic energy to one or more atoms of the plurality of atoms, as described herein. The electromagnetic delivery unit may comprise one or more light sources, such as any light source described herein. The electromagnetic energy may comprise optical energy. The optical energy may comprise any repetition rate, pulse energy, average power, wavelength, or bandwidth described herein.

The electromagnetic delivery unit may comprise one or more microwave or radio-frequency (RF) energy sources, such as one or more magnetrons, klystrons, traveling-wave tubes, gyrotrons, field-effect transistors (FETs), tunnel diodes, Gunn diodes, impact ionization avalanche transit-time (IMPATT) diodes, or masers. The electromagnetic energy may comprise microwave energy or RF energy. The RF energy may comprise one or more wavelengths of at least about 1 millimeter (mm), 2 mm, 3 mm, 4 mm, 5 mm, 6 mm, 7 mm, 8 mm, 9 mm, 10 mm, 20 mm, 30 mm, 40 mm, 50 mm, 60 mm, 70 mm, 80 mm, 90 mm, 100 mm, 200 mm, 300 mm, 400 mm, 500 mm, 600 mm, 700 mm, 800 mm, 900 mm, 1 meter (m), 2 m, 3 m, 4 m, 5 m, 6 m, 7 m, 8 m, 9 m, 10 m, 20 m, 30 m, 40 m, 50 m, 60 m, 70 m, 80 m, 90 m, 100 m, 200 m, 300 m, 400 m, 500 m, 600 m, 700 m, 800 m, 900 m, 1 kilometer (km), 2 km, 3 km, 4 km, 5 km, 6 km, 7 km, 8 km, 9 km, 10 km, or more. The RF energy may comprise one or more wavelengths of at most about 10 km, 9 km, 8 km, 7 km, 6 km, 5 km, 4 km, 3 km, 2 km, 1 km, 900 m, 800 m, 700 m, 600 m, 500 m, 400 m, 300 m, 200 m, 100 m, 90 m, 80 m, 70 m, 60 m, 50 m, 40 m, 30 m, 20 m, 10 m, 9 m, 8 m, 7 m, 6 m, 5 m, 4 m, 3 m, 2 m, 1 m, 900 mm, 800 mm, 700 mm, 600 mm, 500 mm, 400 mm, 300 mm, 200 mm, 100 mm, 90 mm, 80 mm, 70 mm, 60 mm, 50 mm, 40 mm, 30 mm, 20 mm, 10 mm, 9 mm, 8 mm, 7 mm, 6 mm, 5 mm, 4 mm, 3 mm, 2 mm, 1 mm, or less. The RF energy may comprise one or more wavelengths that are within a range defined by any two of the preceding values.

The RF energy may comprise an average power of at least about 1 microwatt (μW), 2 μW, 3 μW, 4 μW, 5 μW, 6 μW, 7 μW, 8 μW, 9 μW, 10 μW, 20 μW, 30 μW, 40 μW, 50 μW, 60 μW, 70 μW, 80 μW, 90 μW, 100 μW, 200 μW, 300 μW, 400 μW, 500 μW, 600 μW, 700 μW, 800 μW, 900 μW, 1 milliwatt (mW), 2 mW, 3 mW, 4 mW, 5 mW, 6 mW, 7 mW, 8 mW, 9 mW, 10 mW, 20 mW, 30 mW, 40 mW, 50 mW, 60 mW, 70 mW, 80 mW, 90 mW, 100 mW, 200 mW, 300 mW, 400 mW, 500 mW, 600 mW, 700 mW, 800 mW, 900 mW, 1 Watt (W), 2 W, 3 W, 4 W, 5 W, 6 W, 7 W, 8 W, 9 W, 10 W, 20 W, 30 W, 40 W, 50 W, 60 W, 70 W, 80 W, 90 W, 100 W, 200 W, 300 W, 400 W, 500 W, 600 W, 700 W, 800 W, 900 W, 1,000 W, or more. The RF energy may comprise an average power of at most about 1,000 W, 900 W, 800 W, 700 W, 600 W, 500 W, 400 W, 300 W, 200 W, 100 W, 90 W, 80 W, 70 W, 60 W, 50 W, 40 W, 30 W, 20 W, 10 W, 9 W, 8 W, 7 W, 6 W, 5 W, 4 W, 3 W, 2 W, 1 W, 900 mW, 800 mW, 700 mW, 600 mW, 500 mW, 400 mW, 300 mW, 200 mW, 100 mW, 90 mW, 80 mW, 70 mW, 60 mW, 50 mW, 40 mW, 30 mW, 20 mW, 10 mW, 9 mW, 8 mW, 7 mW, 6 mW, 5 mW, 4 mW, 3 mW, 2 mW, 1 mW, 900 μW, 800 μW, 700 μW, 600 μW, 500 μW, 400 μW, 300 μW, 200 μW, 100 μW, 90 μW, 80 μW, 70 μW, 60 μW, 50 μW, 40 μW, 30 μW, 20 μW, 10 μW, 9 μW, 8 μW, 7 μW, 6 μW, 5 μW, 4 μW, 3 μW, 2 μW, 1 μW, or less. The RF energy may comprise an average power that is within a range defined by any two of the preceding values.

The electromagnetic delivery unit may comprise one or more light sources, such as any light source described herein. For instance, the electromagnetic delivery unit may comprise light source 221. Although depicted as comprising a single light source in FIG. 4, the electromagnetic delivery unit may comprise any number of light sources, such as at least about 1, 2, 3, 4, 5, 6, 7, 8, 9, 10, or more light sources or at most about 10, 9, 8, 7, 6, 5, 4, 3, 2, or 1 light sources.

The light sources may be configured to direct light to one or more OMs configured to selectively apply the electromagnetic energy to one or more atoms of the plurality of atoms. For instance, the electromagnetic delivery unit may comprise OM 222. Although depicted as comprising a single OM in FIG. 4, the electromagnetic delivery unit may comprise any number of OMs, such as at least about 1, 2, 3, 4, 5, 6, 7, 8, 9, 10, or more OMs or at most about 10, 9, 8, 7, 6, 5, 4, 3, 2, or 1 OMs. The OMs may comprise one or more SLMs, AODs, or AOMs. The OMs may comprise one or more DMDs. The OMs may comprise one or more liquid crystal devices, such as one or more LCOS devices.

The electromagnetic delivery unit may comprise one or more electromagnetic energy artificial intelligence (AI) units configured to perform one or more AI operations to selectively apply the electromagnetic energy to the atoms. For instance, the electromagnetic delivery unit may comprise AI unit 223. Although depicted as comprising a single AI unit in FIG. 4, the electromagnetic delivery unit may comprise any number of AI units, such as at least about 1, 2, 3, 4, 5, 6, 7, 8, 9, 10, or more AI units or at most about 10, 9, 8, 7, 6, 5, 4, 3, 2, or 1 AI units. The AI operations may comprise any machine learning (ML) or reinforcement learning (RL) operations described herein.

The electromagnetic delivery unit may be configured to apply one or more single-qubit operations (such as one or more single-qubit gate operations) on the qubits described herein. The electromagnetic delivery unit may be configured to apply one or more two-qubit operations (such as one or more two-qubit gate operations) on the two-qubit units described herein. Each single-qubit or two-qubit operation may comprise a duration of at least about 10 nanoseconds (ns), 20 ns, 30 ns, 40 ns, 50 ns, 60 ns, 70 ns, 80 ns, 90 ns, 100 ns, 200 ns, 300 ns, 400 ns, 500 ns, 600 ns, 700 ns, 800 ns, 900 ns, 1 microsecond (μs), 2 μs, 3 μs, 4 μs, 5 μs, 6 μs, 7 μs, 8 μs, 9 μs, 10 μs, 20 μs, 30 μs, 40 μs, 50 μs, 60 μs, 70 μs, 80 μs, 90 μs, 100 μs, or more. Each single-qubit or two-qubit operation may comprise a duration of at most about 100 μs, 90 μs, 80 μs, 70 μs, 60 μs, 50 μs, 40 μs, 30 μs, 20 μs, 10 μs, 9 μs, 8 μs, 7 μs, 6 μs, 5 μs, 4 μs, 3 μs, 2 μs, 1 μs, 900 ns, 800 ns, 700 ns, 600 ns, 500 ns, 400 ns, 300 ns, 200 ns, 100 ns, 90 ns, 80 ns, 70 ns, 60 ns, 50 ns, 40 ns, 30 ns, 20 ns, 10 ns, or less. Each single-qubit or two-qubit operation may comprise a duration that is within a range defined by any two of the preceding values. The single-qubit or two-qubit operations may be applied with a repetition frequency of at least 1 kilohertz (kHz), 2 kHz, 3 kHz, 4 kHz, 5 kHz, 6 kHz, 7 kHz, 8 kHz, 9 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, 1,000 kHz, or more. The single-qubit or two-qubit operations may be applied with a repetition frequency of at most 1,000 kHz, 900 kHz, 800 kHz, 700 kHz, 600 kHz, 500 kHz, 400 kHz, 300 kHz, 200 kHz, 100 kHz, 90 kHz, 80 kHz, 70 kHz, 60 kHz, 50 kHz, 40 kHz, 30 kHz, 20 kHz, 10 kHz, 9 kHz, 8 kHz, 7 kHz, 6 kHz, 5 kHz, 4 kHz, 3 kHz, 2 kHz, 1 kHz, or less. The single-qubit or two-qubit operations may be applied with a repetition frequency that is within a range defined by any two of the preceding values.

The electromagnetic delivery unit may be configured to apply one or more single-qubit operations by inducing one or more Raman transitions between a first qubit state and a second qubit state described herein. The Raman transitions may be detuned from a 3P₀ or ³P₁ line described herein. For instance, the Raman transitions may be detuned by at least about 1 kHz, 2 kHz, 3 kHz, 4 kHz, 5 kHz, 6 kHz, 7 kHz, 8 kHz, 9 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, 1 MHz, 2 MHz, 3 MHz, 4 MHz, 5 MHz, 6 MHz, 7 MHz, 8 MHz, 9 MHz, 10 MHz, 20 MHz, 30 MHz, 40 MHz, 50 MHz, 60 MHz, 70 MHz, 80 MHz, 90 MHz, 100 MHz, 200 MHz, 300 MHz, 400 MHz, 500 MHz, 600 MHz, 700 MHz, 800 MHz, 900 MHz, 1 GHz, or more. The Raman transitions may be detuned by at most about 1 GHz, 900 MHz, 800 MHz, 700 MHz, 600 MHz, 500 MHz, 400 MHz, 300 MHz, 200 MHz, 100 MHz, 90 MHz, 80 MHz, 70 MHz, 60 MHz, 50 MHz, 40 MHz, 30 MHz, 20 MHz, 10 MHz, 9 MHz, 8 MHz, 7 MHz, 6 MHz, 5 MHz, 4 MHz, 3 MHz, 2 MHz, 1 MHz, 900 kHz, 800 kHz, 700 kHz, 600 kHz, 500 kHz, 400 kHz, 300 kHz, 200 kHz, 100 kHz, 90 kHz, 80 kHz, 70 kHz, 60 kHz, 50 kHz, 40 kHz, 30 kHz, 20 kHz, 10 kHz, 9 kHz, 8 kHz, 7 kHz, 6 kHz, 5 kHz, 4 kHz, 3 kHz, 2 kHz, 1 kHz, or less. The Raman transitions may be detuned by a value that is within a range defined by any two of the preceding values.

Raman transitions may be induced on individually selected atoms using one or more spatial light modulators (SLMs) or acousto-optic deflectors (AODs) to impart a deflection angle or a frequency shift to a light beam based on an applied radio-frequency (RF) signal. The SLM or AOD may be combined with an optical conditioning system that images the SLM or AOD active region onto the back focal plane of a microscope objective. The microscope objective may perform a spatial Fourier transform on the optical field at the position of the SLM or AOD. As such, angle (which may be proportional to RF frequency) may be converted into position. For example, applying a comb of radio frequencies to an AOD may generate a linear array of spots of light at a focal plane of the objective, with each spot having a finite extent determined by the characteristics of the optical conditioning system (such as the point spread function of the optical conditioning system).

To perform a Raman transition on a single atom with a single SLM or AOD, a pair of frequencies may be applied to the SLM or AOD simultaneously. The two frequencies of the pair may have a frequency difference that matches or nearly matches the splitting energy between the first and second qubit states. For instance, the frequency difference may differ from the splitting energy by at most about 1 MHz, 900 kHz, 800 kHz, 700 kHz, 600 kHz, 500 kHz, 400 kHz, 300 kHz, 200 kHz, 100 kHz, 90 kHz, 80 kHz, 70 kHz, 60 kHz, 50 kHz, 40 kHz, 30 kHz, 20 kHz, 10 kHz, 9 kHz, 8 kHz, 7 kHz, 6 kHz, 5 kHz, 4 kHz, 3 kHz, 2 kHz, 1 kHz, 900 Hz, 800 Hz, 700 Hz, 600 Hz, 500 Hz, 400 Hz, 300 Hz, 200 Hz, 100 Hz, 90 Hz, 80 Hz, 70 Hz, 60 Hz, 50 Hz, 40 Hz, 30 Hz, 20 Hz, 10 Hz, 9 Hz, 8 Hz, 7 Hz, 6 Hz, 5 Hz, 4 Hz, 3 Hz, 2 Hz, 1 Hz, or less. The frequency difference may differ from the splitting energy by at least about 1 Hz, 2 Hz, 3 Hz, 4 Hz, 5 Hz, 6 Hz, 7 Hz, 8 Hz, 9 Hz, 10 Hz, 20 Hz, 30 Hz, 40 Hz, 50 Hz, 60 Hz, 70 Hz, 80 Hz, 90 Hz, 100 Hz, 200 Hz, 300 Hz, 400 Hz, 500 Hz, 600 Hz, 700 Hz, 800 Hz, 900 Hz, 1 kHz, 2 kHz, 3 kHz, 4 kHz, 5 kHz, 6 kHz, 7 kHz, 8 kHz, 9 kHz, 10 kHz, 20 kHz, 30 kHz, 40 kHz, 50 kHz, 60 kHz, 70 kHz, 80 kHz, 90 kHz, 100 kHz, 200 kHz, 300 kHz, 400 kHz, 500 kHz, 600 kHz, 700 kHz, 800 kHz, 900 kHz, 1 MHz, or more. The frequency difference may differ from the splitting energy by about 0 Hz. The frequency difference may differ from the splitting energy by a value that is within a range defined by any two of the preceding values. The optical system may be configured such that the position spacing corresponding to the frequency difference is not resolved and such that light at both of the two frequencies interacts with a single atom.

The electromagnetic delivery units may be configured to provide a beam with a characteristic dimension of at least about 10 nm, 50 nm, 75 nm, 100 nm, 125 nm, 150 nm, 175 nm, 200 nm, 225 nm, 250 nm, 275 nm, 300 nm, 325 nm, 350 nm, 375 nm, 400 nm, 425 nm, 450 nm, 475 nm, 500 nm, 525 nm, 550 nm, 575 nm, 600 nm, 625 nm, 650 nm, 675 nm, 700 nm, 725 nm, 750 nm, 775 nm, 800 nm, 825 nm, 850 nm, 875 nm, 900 nm, 925 nm, 950 nm, 975 nm, 1 micrometer (μm), 1.5 μm, 2 μm, 2.5 μm 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, or more. The electromagnetic delivery units may be configured to provide a beam with a characteristic dimension of at most about 10 μm, 9.5 μm, 9 μm, 8.5 μm, 8 μm, 7.5 μm, 7 μm, 6.5 μm, 6 μm, 5.5 μm, 5 μm, 4.5 μm, 4 μm, 3.5 μm, 3 μm, 2.5 μm, 2 μm, 1.5 μm, 1 μm, 975 nm, 950 nm, 925 nm, 900 nm, 875 nm, 850 nm, 825 nm, 800 nm, 775 nm, 750 nm, 725 nm, 700 nm, 675 nm, 650 nm, 625 nm, 600 nm, 575 nm, 550 nm, 525 nm, 500 nm, 475 nm, 450 nm, 425 nm, 400 nm, 375 nm, 350 nm, 325 nm, 300 nm, 275 nm, 250 nm, 225 nm, 200 nm, 175 nm, 150 nm, 125 nm, 100 nm, 75 nm, 25 nm, 10 nm, or less. The electromagnetic delivery units may be configured to provide a beam with a characteristic dimension as defined by any two of the proceeding values. For example, the beam can have a characteristic dimension of about 1.5 micrometers to about 2.5 micrometers. Examples of characteristic dimensions include, but are not limited to, a Gaussian beam waist, the full width at half maximum (FWHM) of the beam size, the beam diameter, the 1/e² width, the D4σ width, the D86 width, and the like. For example, the beam may have a Gaussian beam waist of at least about 1.5 micrometers.

The characteristic dimension of the beam may be bounded at the low end by the size of the atomic wavepacket of an optical trapping site. For example, the beam can be formed such that the intensity variation of the beam over the trapping site is sufficiently small as to be substantially homogeneous over the trapping site. In this example, the beam homogeneity can improve the fidelity of a qubit in the trapping site. The characteristic dimension of the beam may be bounded at the high end by the spacing between trapping sites. For example, a beam can be formed such that it is small enough that the effect of the beam on a neighboring trapping site/atom is negligible. In this example, the effect may be negligible if the effect can be minimized by techniques such as, for example, composite pulse engineering. The characteristic dimension may be different from a maximum achievable resolution of the system. For example, a system can have a maximum resolution of 700 nm, but the system may be operated at 1.5 micrometers. In this example, the value of the characteristic dimension may be selected to optimize the performance of the system in view of the considerations described elsewhere herein. The characteristic dimension may be invariant for different maximally achievable resolutions. For example, a system with a maximum resolution of 500 nm and a system with a maximum resolution of 2 micrometers may both be configured to operate at a characteristic dimension of 2 micrometers. In this example, 2 micrometers may be the optimal resolution based on the size of the trapping sites.

### Examples of Integrated Optical Trapping Units and Electromagnetic Delivery Units

The optical trapping units and electromagnetic delivery units described herein may be integrated into a single optical system. A microscope objective may be used to deliver electromagnetic radiation generated by an electromagnetic delivery unit described herein and to deliver light for trapping atoms generated by an optical trapping unit described herein. Alternatively or in addition, different objectives may be used to deliver electromagnetic radiation generated by an electromagnetic delivery unit and to deliver light from trapping atoms generated by an optical trapping unit.

A single SLM or AOD may allow the implementation of qubit operations (such as any single-qubit or two-qubit operations described herein) on a linear array of atoms. Alternatively or in addition, two separate SLMs or AODs may be configured to each handle light with orthogonal polarizations. The light with orthogonal polarizations may be overlapped before the microscope objective. In such a scheme, each photon used in a two-photon transition described herein may be passed to the objective by a separate SLM or AOD, which may allow for increased polarization control. Qubit operations may be performed on a two-dimensional arrangement of atoms by bringing light from a first SLM or AOD into a second SLM or AOD that is oriented substantially orthogonally to the first SLM or AOD via an optical relay. Alternatively or in addition, qubit operations may be performed on a two-dimensional arrangement of atoms by using a one-dimensional array of SLMs or AODs.

The stability of qubit gate fidelity may be improved by maintaining overlap of light from the various light sources described herein (such as light sources associated with the optical trapping units or electromagnetic delivery units described herein). Such overlap may be maintained by an optical subsystem that measures the direction of light emitted by the various light sources, allowing closed-loop control of the direction of light emission. The optical subsystem may comprise a pickoff mirror located before the microscope objective. The pickoff mirror may be configured to direct a small amount of light to a lens, which may focus a collimated beam and convert angular deviation into position deviation. A position-sensitive optical detector, such as a lateral-effect position sensor or quadrant photodiode, may convert the position deviation into an electronic signal and information about the deviation may be fed into a compensation optic, such as an active mirror.

The stability of qubit gate manipulation may be improved by controlling the intensity of light from the various light sources described herein (such as light sources associated with the optical trapping units or electromagnetic delivery units described herein). Such intensity control may be maintained by an optical subsystem that measures the intensity of light emitted by the various light sources, allowing closed-loop control of the intensity. Each light source may be coupled to an intensity actuator, such as an intensity servo control. The actuator may comprise an acousto-optic modulator (AOM) or electro-optic modulator (EOM). The intensity may be measured using an optical detector, such as a photodiode or any other optical detector described herein. Information about the intensity may be integrated into a feedback loop to stabilize the intensity.

### Examples of State Preparation Units

FIG. 5 shows an example of a state preparation unit 250. The state preparation unit may be configured to prepare a state of the plurality of atoms, as described herein. The state preparation unit may be coupled to the optical trapping unit and may direct atoms that have been prepared by the state preparation unit to the optical trapping unit. The state preparation unit may be configured to cool the plurality of atoms. The state preparation unit may be configured to cool the plurality of atoms prior to trapping the plurality of atoms at the plurality of optical trapping sites.

The state preparation unit may comprise one or more Zeeman slowers. For instance, the state preparation unit may comprise a Zeeman slower 251. Although depicted as comprising a single Zeeman slower in FIG. 5, the state preparation may comprise any number of Zeeman slowers, such as at least about 1, 2, 3, 4, 5, 6, 7, 8, 9, 10, or more Zeeman slowers or at most about 10, 9, 8, 7, 6, 5, 4, 3, 2, or 1 Zeeman slowers. The Zeeman slowers may be configured to cool one or more atoms of the plurality of atoms from a first velocity or distribution of velocities (such an emission velocity from an of an atom source, room temperature, liquid nitrogen temperature, or any other temperature) to a second velocity that is lower than the first velocity or distribution of velocities.

The first velocity or distribution of velocities may be associated with a temperature of at least about 50 Kelvin (K), 60 K, 70 K, 80 K, 90 K, 100 K, 200 K, 300 K, 400 K, 500 K, 600 K, 700 K, 800 K, 900 K, 1,000 K, or more. The first velocity or distribution of velocities may be associated with a temperature of at most about 1,000 K, 900 K, 800 K, 700 K, 600 K, 500 K, 400 K, 300 K, 200 K, 100 K, 90 K, 80 K, 70 K, 60 K, 50 K, or less. The first velocity or distribution of velocities may be associated with a temperature that is within a range defined by any two of the preceding values. The second velocity may be at least about 1 meter per second (m/s), 2 m/s, 3 m/s, 4 m/s, 5 m/s, 6 m/s, 7 m/s, 8 m/s, 9 m/s, 10 m/s, or more. The second velocity may be at most about 10 m/s, 9 m/s, 8 m/s, 7 m/s, 6 m/s, 5 m/s, 4 m/s, 3 m/s, 2 m/s, 1 m/s, or less. The second velocity may be within a range defined by any two of the preceding values. The Zeeman slowers may comprise 1D Zeeman slowers.

The state preparation unit may comprise a first magneto-optical trap (MOT) 252. The first MOT may be configured to cool the atoms to a first temperature. The first temperature may be at most about 10 millikelvin (mK), 9 mK, 8 mK, 7 mK, 6 mK, 5 mK, 4 mK, 3 mK, 2 mK, 1 mK, 0.9 mK, 0.8 mK, 0.7 mK, 0.6 mK, 0.5 mK, 0.4 mK, 0.3 mK, 0.2 mK, 0.1 mK, or less. The first temperature may be at least about 0.1 mK, 0.2 mK, 0.3 mK, 0.4 mK, 0.5 mK, 0.6 mK, 0.7 mK, 0.8 mK, 0.9 mK, 1 mK, 2 mK, 3 mK, 4 mK, 5 mK, 6 mK, 7 mK, 8 mK, 9 mK, 10 mK, or more. The first temperature may be within a range defined by any two of the preceding values. The first MOT may comprise a 1D, 2D, or 3D MOT.

The first MOT may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

The state preparation unit may comprise a second MOT 253. The second MOT may be configured to cool the atoms from the first temperature to a second temperature that is lower than the first temperature. The second temperature may be at most about 100 microkelvin (μK), 90 μK, 80 μK, 70 μK, 60 μK, 50 μK, 40 μK, 30 μK, 20 μK, 10 μK, 9 μK, 8 μK, 7 μK, 6 μK, 5 μK, 4 μK, 3 μK, 2 μK, 1 μK, 900 nanokelvin (nK), 800 nK, 700 nK, 600 nK, 500 nK, 400 nK, 300 nK, 200 nK, 100 nK, or less. The second temperature may be at least about 100 nK, 200 nK, 300 nK, 400 nK, 500 nK, 600 nK, 700 nK, 800 nK, 900 nK, 1 μK, 2 μK, 3 μK, 4 μK, 5 μK, 6 μK, 7 μK, 8 μK, 9 μK, 10 μK, 20 μK, 30 μK, 40 μK, 50 μK, 60 μK, 70 μK, 80 μK, 90 μK, 100 μK, or more. The second temperature may be within a range defined by any two of the preceding values. The second MOT may comprise a 1D, 2D, or 3D MOT.

The second MOT may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

Although depicted as comprising two MOTs in FIG. 5, the state preparation unit may comprise any number of MOTs, such as at least about 1, 2, 3, 4, 5, 6, 7, 8, 9, 10, or more MOTs or at most about 10, 9, 8, 7, 6, 5, 4, 3, 2, or 1 MOTs.

The state preparation unit may comprise one or more sideband cooling units or Sisyphus cooling units (such as a sideband cooling unit described in www.arxiv.org/abs/1810.06626 or a Sisyphus cooling unit described in www.arxiv.org/abs/1811.06014, each of which is incorporated herein by reference in its entirety for all purposes). For instance, the state preparation unit may comprise sideband cooling unit or Sisyphus cooling unit 254. Although depicted as comprising a single sideband cooling unit or Sisyphus cooling unit in FIG. 5, the state preparation may comprise any number of sideband cooling units or Sisyphus cooling units, such as at least about 1, 2, 3, 4, 5, 6, 7, 8, 9, 10, or more sideband cooling units or Sisyphus cooling units, or at most about 10, 9, 8, 7, 6, 5, 4, 3, 2, or 1 sideband cooling units or Sisyphus cooling units. The sideband cooling units or Sisyphus cooling units may be configured to use sideband cooling to cool the atoms from the second temperature to a third temperature that is lower than the second temperature. The third temperature may be at most about 10 μK, 9 μK, 8 μK, 7 μK, 6 μK, 5 μK, 4 μK, 3 μK, 2 μK, 1 μK, 900 nK, 800 nK, 700 nK, 600 nK, 500 nK, 400 nK, 300 nK, 200 nK, 100 nK, 90 nK, 80 nK, 70 nK, 60 nK, 50 nK, 40 nK, 30 nK, 20 nK, 10 nK, or less. The third temperature may be at most about 10 nK, 20 nK, 30 nK, 40 nK, 50 nK, 60 nK, 70 nK, 80 nK, 90 nK, 100 nK, 200 nK, 300 nK, 400 nK, 500 nK, 600 nK, 700 nK, 800 nK, 900 nK, 1 μK, 2 μK, 3 μK, 4 μK, 5 μK, 6 μK, 7 μK, 8 μK, 9 μK, 10 μK, or more. The third temperature may be within a range defined by any two of the preceding values.

The sideband cooling units or Sisyphus cooling units may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

The state preparation unit may comprise one or more optical pumping units. For instance, the state preparation unit may comprise optical pumping unit 255. Although depicted as comprising a single optical pumping unit in FIG. 5, the state preparation may comprise any number of optical pumping units, such as at least about 1, 2, 3, 4, 5, 6, 7, 8, 9, 10, or more optical pumping units, or at most about 10, 9, 8, 7, 6, 5, 4, 3, 2, or 1 optical pumping units. The optical pumping units may be configured to emit light to optically pump the atoms from an equilibrium distribution of atomic states to a non-equilibrium atomic state. For instance, the optical pumping units may be configured to emit light to optically pump the atoms from an equilibrium distribution of atomic states to a single pure atomic state. The optical pumping units may be configured to emit light to optically pump the atoms to a ground atomic state or to any other atomic state. The optical pumping units may be configured to optically pump the atoms between any two atomic states. The optical pumping units may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

The state preparation unit may comprise one or more coherent driving units. For instance, the state preparation unit may comprise coherent driving unit 256. Although depicted as comprising a coherent driving unit in FIG. 5, the state preparation may comprise any number of coherent driving units, such as at least about 1, 2, 3, 4, 5, 6, 7, 8, 9, 10, or more coherent driving units or at most about 10, 9, 8, 7, 6, 5, 4, 3, 2, or 1 coherent driving units. The coherent driving units may be configured to coherently drive the atoms from the non-equilibrium state to the first or second atomic states described herein. Thus, the atoms may be optically pumped to an atomic state that is convenient to access (for instance, based on availability of light sources that emit particular wavelengths or based on other factors) and then coherently driven to atomic states described herein that are useful for performing quantum computations. The coherent driving units may be configured to induce a single photon transition between the non-equilibrium state and the first or second atomic state. The coherent driving units may be configured to induce a two-photon transition between the non-equilibrium state and the first or second atomic state. The two-photon transition may be induced using light from two light sources described herein (such as two lasers described herein).

The coherent driving units may comprise one or more light sources (such as any light source described herein) configured to emit light. The light may comprise one or more wavelengths of at least about 400 nm, 410 nm, 420 nm, 430 nm, 440 nm, 450 nm, 460 nm, 470 nm, 480 nm, 490 nm, 500 nm, 510 nm, 520 nm, 530 nm, 540 nm, 550 nm, 560 nm, 570 nm, 580 nm, 590 nm, 600 nm, 610 nm, 620 nm, 630 nm, 640 nm, 650 nm, 660 nm, 670 nm, 680 nm, 690 nm, 700 nm, 710 nm, 720 nm, 730 nm, 740 nm, 750 nm, 760 nm, 770 nm, 780 nm, 790 nm, 800 nm, 810 nm, 820 nm, 830 nm, 840 nm, 850 nm, 860 nm, 870 nm, 880 nm, 890 nm, 900 nm, 910 nm, 920 nm, 930 nm, 940 nm, 950 nm, 960 nm, 970 nm, 980 nm, 990 nm, 1,000 nm, or more. The light may comprise one or more wavelengths of at most about 1,000 nm, 990 nm, 980 nm, 970 nm, 960 nm, 950 nm, 940 nm, 930 nm, 920 nm, 910 nm, 900 nm, 890 nm, 880 nm, 870 nm, 860 nm, 850 nm, 840 nm, 830 nm, 820 nm, 810 nm, 800 nm, 790 nm, 780 nm, 770 nm, 760 nm, 750 nm, 740 nm, 730 nm, 720 nm, 710 nm, 700 nm, 690 nm, 680 nm, 670 nm, 660 nm, 650 nm, 640 nm, 630 nm, 620 nm, 610 nm, 600 nm, 590 nm, 580 nm, 570 nm, 560 nm, 550 nm, 540 nm, 530 nm, 520 nm, 510 nm, 500 nm, 490 nm, 480 nm, 470 nm, 460 nm, 450 nm, 440 nm, 430 nm, 420 nm, 410 nm, 400 nm, or less. The light may comprise one or more wavelengths that are within a range defined by any two of the preceding values. For instance, the light may comprise one or more wavelengths that are within a range from 400 nm to 1,000 nm, 500 nm to 1,000 nm, 600 nm to 1,000 nm, 650 nm to 1,000 nm, 400 nm to 900 nm, 400 nm to 800 nm, 400 nm to 700 nm, 400 nm to 600 nm, 400 nm to 500 nm, 500 nm to 700 nm, or 650 nm to 700 nm.

The coherent driving units may be configured to induce an RF transition between the non-equilibrium state and the first or second atomic state. The coherent driving units may comprise one or more electromagnetic radiation sources configured to emit electromagnetic radiation configured to induce the RF transition. For instance, the coherent driving units may comprise one or more RF sources (such as any RF source described herein) configured to emit RF radiation. The RF radiation may comprise one or more wavelengths of at least about 10 centimeters (cm), 20 cm, 30 cm, 40 cm, 50 cm, 60 cm, 70 cm, 80 cm, 90 cm, 1 meter (m), 2 m, 3 m, 4 m, 5 m, 6 m, 7 m, 8 m, 9 m, 10 m, or more. The RF radiation may comprise one or more wavelengths of at most about 10 m, 9 m, 8 m, 7 m, 6 m, 5 m, 4 m, 3 m, 2 m, 1 m, 90 cm, 80 cm, 70 cm, 60 cm, 50 cm, 40 cm, 30 cm, 20 cm, 10 cm, or less. The RF radiation may comprise one or more wavelengths that are within a range defined by any two of the preceding values. Alternatively or in addition, the coherent driving units may comprise one or more light sources (such as any light sources described herein) configured to induce a two-photon transition corresponding to the RF transition.

### Examples of Controllers

The optical trapping units, electromagnetic delivery units, entanglement units, readout optical units, vacuum units, imaging units, spatial configuration AI units, spatial arrangement AI units, atom rearrangement units, state preparation units, sideband cooling units, optical pumping units, coherent driving units, electromagnetic energy AI units, atom reservoirs, atom movement units, or Rydberg excitation units may include one or more circuits or controllers (such as one or more electronic circuits or controllers) that is connected (for instance, by one or more electronic connections) to the optical trapping units, electromagnetic delivery units, entanglement units, readout optical units, vacuum units, imaging units, spatial configuration AI units, spatial arrangement AI units, atom rearrangement units, state preparation units, sideband cooling units, optical pumping units, coherent driving units, electromagnetic energy AI units, atom reservoirs, atom movement units, or Rydberg excitation units. The circuits or controllers may be configured to control the optical trapping units, electromagnetic delivery units, entanglement units, readout optical units, vacuum units, imaging units, spatial configuration AI units, spatial arrangement AI units, atom rearrangement units, state preparation units, sideband cooling units, optical pumping units, coherent driving units, electromagnetic energy AI units, atom reservoirs, atom movement units, or Rydberg excitation units.

### Examples of Non-Classical Computers

In some cases, the present disclosure provides a non-classical computer comprising: a plurality of qubits comprising greater than 60 atoms, each atom trapped within an optical trapping site of a plurality of spatially distinct optical trapping sites, wherein the plurality of qubits comprise at least a first qubit state and a second qubit state, wherein the first qubit state comprises a first atomic state and the second qubit state comprises a second atomic state; one or more electromagnetic delivery units configured to apply electromagnetic energy to one or more qubits of the plurality of qubits, thereby imparting a non-classical operation to the one or more qubits, which non-classical operation includes a superposition between at least the first qubit state and the second qubit state; one or more entanglement units configured to quantum mechanically entangle at least a subset of the plurality of qubits in the superposition with at least another qubit of the plurality of qubits; and one or more readout optical units configured to perform one or more measurements of the one or more qubits, thereby obtaining a non-classical computation.

In some cases, the present disclosure provides a non-classical computer comprising a plurality of qubits comprising greater than 60 atoms each trapped within an optical trapping site of a plurality of spatially distinct optical trapping sites.

### Examples of Methods for Performing a Non-Classical Computation

In some cases, the present disclosure provides a method for performing a non-classical computation, comprising: (a) generating a plurality of spatially distinct optical trapping sites, the plurality of optical trapping sites configured to trap a plurality of atoms, the plurality of atoms comprising greater than 60 atoms; (b) applying electromagnetic energy to one or more atoms of the plurality of atoms, thereby inducing the one or more atoms to adopt one or more superposition states of a first atomic state and at least a second atomic state that is different from the first atomic state; (c) quantum mechanically entangling at least a subset of the one or more atoms in the one or more superposition states with at least another atom of the plurality of atoms; and (d) performing one or more optical measurements of the one or more superposition state to obtain the non-classical computation.

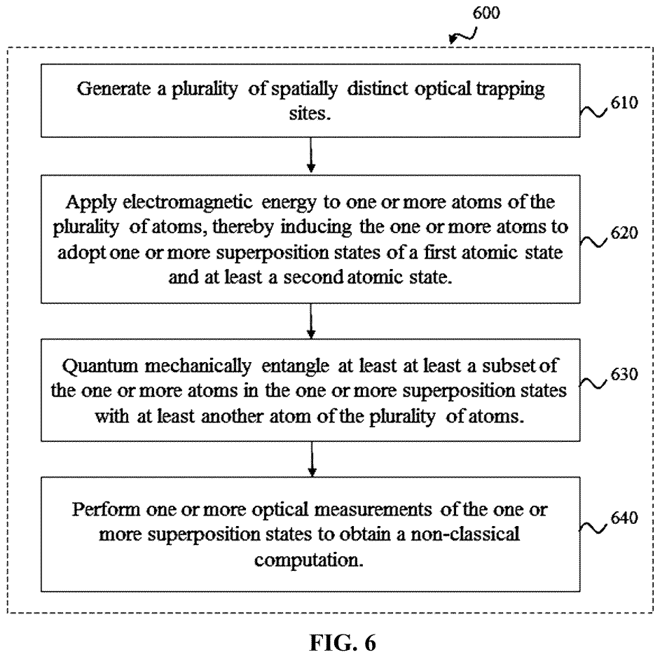

FIG. 6 shows a flowchart for an example of a first method 600 for performing a non-classical computation.

In a first operation 610, the method 600 may comprise generating a plurality of spatially distinct optical trapping sites. The plurality of optical trapping sites may be configured to trap a plurality of atoms. The plurality of atoms may comprise greater than 60 atoms. The optical trapping sites may comprise any optical trapping sites described herein. The atoms may comprise any atoms described herein.

In a second operation 620, the method 600 may comprise applying electromagnetic energy to one or more atoms of the plurality of atoms, thereby inducing the one or more atoms to adopt one or more superposition states of a first atomic state and at least a second atomic state that is different from the first atomic state. The electromagnetic energy may comprise any electromagnetic energy described herein. The first atomic state may comprise any first atomic state described herein. The second atomic state may comprise any second atomic state described herein.

In a third operation 630, the method 600 may comprise quantum mechanically entangling at least a subset of the one or more atoms in the one or more superposition states with at least another atom of the plurality of atoms. The atoms may be quantum mechanically entangled in any manner described herein (for instance, as described herein with respect to FIG. 2).

In a fourth operation 640, the method 600 may comprise performing one or more optical measurements of the one or more superposition state to obtain the non-classical computation. The optical measurements may comprise any optical measurements described herein.

In some cases, the present disclosure provides a method for performing a non-classical computation, comprising: (a) providing a plurality of qubits comprising greater than 60 atoms, each atom trapped within an optical trapping site of a plurality of spatially distinct optical trapping sites, wherein the plurality of qubits comprise at least a first qubit state and a second qubit state, wherein the first qubit state comprises a first atomic state and the second qubit state comprises a second atomic state; (b) applying electromagnetic energy to one or more qubits of the plurality of qubits, thereby imparting a non-classical operation to the one or more qubits, which non-classical operation includes a superposition between at least the first qubit state and the second qubit state; (c) quantum mechanically entangling at least a subset of the plurality of qubits in the superposition with at least another qubit of the plurality of qubits; and (d) performing one or more optical measurements of the one or more qubits, thereby obtaining said the-classical computation.

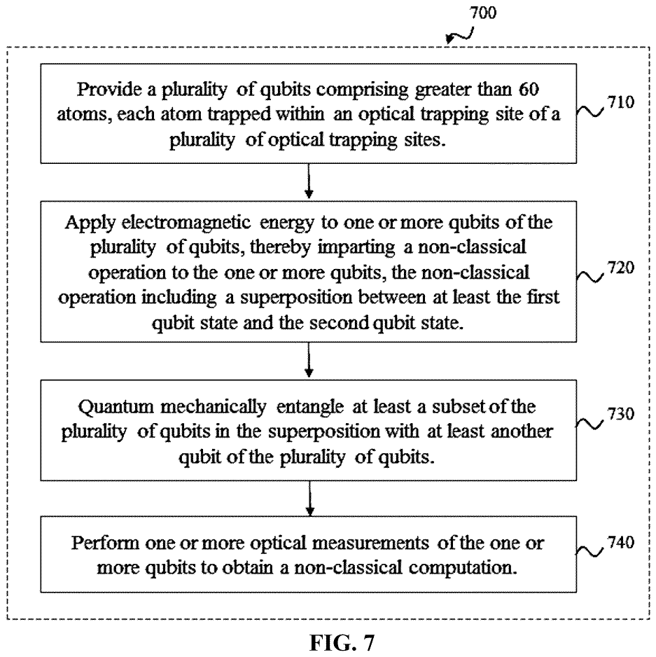

FIG. 7 shows a flowchart for an example of a second method 700 for performing a non-classical computation.

In a first operation 710, the method 700 may comprise providing a plurality of qubits comprising greater than 60 atoms, each atom trapped within an optical trapping site of a plurality of spatially distinct optical trapping sites, wherein the plurality of qubits comprise at least a first qubit state and a second qubit state, wherein the first qubit state comprises a first atomic state and the second qubit state comprises a second atomic state. The optical trapping sites may comprise any optical trapping sites described herein. The qubits may comprise any qubits described herein. The atoms may comprise any atoms described herein. The first qubit state may comprise any first qubit state described herein. The second qubit state may comprise any second qubit state described herein. The first atomic state may comprise any first atomic state described herein. The second atomic state may comprise any second atomic state described herein.

In a second operation 720, the method 700 may comprise applying electromagnetic energy to one or more qubits of the plurality of qubits, thereby imparting a non-classical operation to the one or more qubits, which non-classical operation includes a superposition between at least the first qubit state and the second qubit state. The electromagnetic energy may comprise any electromagnetic energy described herein.

In a third operation 730, the method 700 may comprise quantum mechanically entangling at least a subset of the plurality of qubits in the superposition with at least another qubit of the plurality of qubits. The qubits may be quantum mechanically entangled in any manner described herein (for instance, as described herein with respect to FIG. 2).

In a fourth operation 740, the method 700 may comprise performing one or more optical measurements of the one or more qubits, thereby obtaining the non-classical computation. The optical measurements may comprise any optical measurements described herein.

In some cases, the present disclosure provides a method for performing a non-classical computation, comprising: (a) providing a plurality of qubits comprising greater than 60 atoms each trapped within an optical trapping site of a plurality of spatially distinct optical trapping sites, and (b) using at least a subset of the plurality of qubits to perform the non-classical computation.

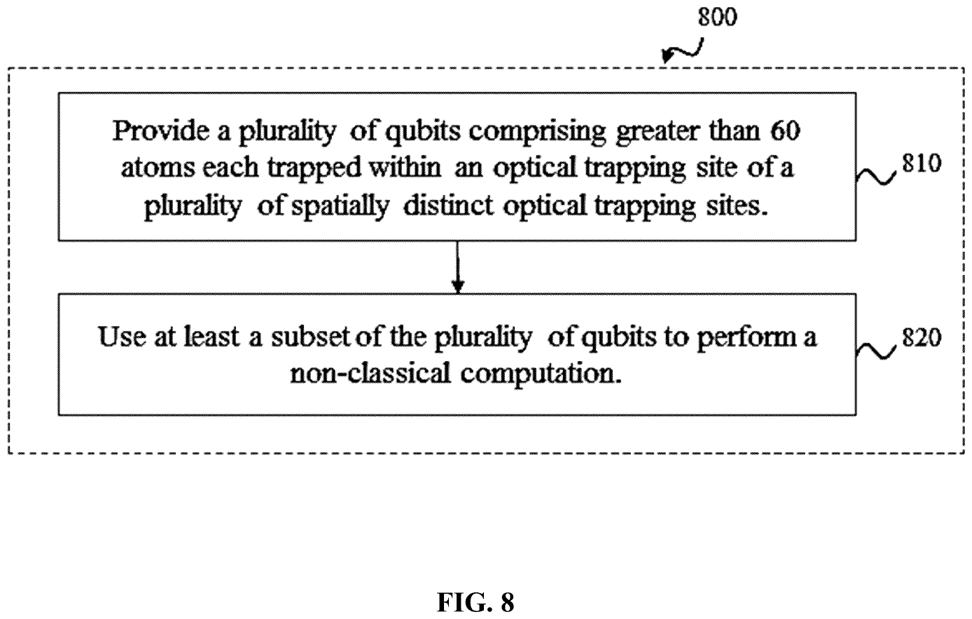

FIG. 8 shows a flowchart for an example of a third method 800 for performing a non-classical computation.

In a first operation 810, the method 800 may comprise providing a plurality of qubits comprising greater than 60 atoms each trapped within an optical trapping site of a plurality of spatially distinct optical trapping sites. The qubits may comprise any qubits described herein. The atoms may comprise any atoms described herein. The optical trapping sites may comprise any optical trapping sites described herein.

In a second operation 820, the method 800 may comprise using at least a subset of the plurality of qubits to perform a non-classical computation.

### Examples of Parallel Addressing of Multi-Qubit Units

Direct excitation of strontium-87 from the ground state to Rydberg levels may require a laser with a wavelength of approximately 218 nm. Alternatively, the Rydberg excitation operation can be performed using two-photon excitation combining 689 nm and 319 nm light, each detuned from the intermediate ³P₁ state. The approximately 7 kHz width of the ³P₁ state provides an effective balance between the two-photon effective Rabi rate and scattering via spontaneous decay from the ³P₁. FIG. 14 shows an energy level structure for single-qubit and multi-qubit operations in strontium-87.

The optical system for single-qubit operations is also designed to work well for multi-qubit gates. One of the single-qubit beams is used as one leg of the two-photon excitation scheme that drives transitions to the Rydberg electronic manifold. To satisfy the spatially-dependent frequency and phase matching condition, AODs are also used for the UV light. Importantly, the optical systems are matched so that the frequency shift of the UV light from one site to another is identical to that of the 689 nm light. The consequence of this constraint is that the performance of state-of-the-art UV AODs dictate the accessible field of view (FOV) for multi-qubit operations. Further, because one of the single-qubit beams is being used for multi-qubit operations (and the two single-qubit beams are matched), the FOV for single-qubit operations will be the same. A figure of merit for UV AODs is the product of the active aperture and the RF bandwidth of the device. For a fixed beam size in the back focal plane of the objective, increasing either of these quantities results in a larger scan angle of the beams, and thus a larger FOV in the plane of the qubit array. An FOV of approximately 100 μm×100 μm was achieved, which is sufficient to address an array of approximately 1,000 atoms with a trapping site spacing of 3 μm.

### Examples of Methods for Error Corrected Quantum Computation

The systems, the methods, the computer-readable media, and the techniques disclosed herein may relate to qubit loss during error correction. Within qubit loss during error correction, there may be at least two general pieces. The systems, the methods, the computer-readable media, and the techniques disclosed herein may be directed to detecting qubit loss without destroying the data stored on the qubits. Instead of appearing as a gate measurement error, if a qubit is lost, the data that would otherwise be there is absent rather than incorrect. The systems, the methods, the computer-readable media, and the techniques disclosed herein may be directed to identifying when an error is caused by a missing qubit. The systems, the methods, the computer-readable media, and the techniques disclosed herein may also be directed to modifying the decoder to handle loss events. For example, the error correcting code may be directed to updating the calculation to address for error. In some cases, knowing about the error may be needed in order to implement error correcting code. However, in other cases, the error correcting code may be modified to account for missing data without explicit knowledge that qubit is lost.

The systems, the methods, the computer-readable media, and the techniques disclosed herein may not modify the topology of the underlying surface code. The systems, the methods, the computer-readable media, and the techniques disclosed herein may improve upon methods of detecting atom loss by compressing the underlying protocol. The systems, the methods, the computer-readable media, and the techniques disclosed herein may allow for loss detection between cycles (or possibly less frequently) rather than after every gate. The systems, the methods, the computer-readable media, and the techniques disclosed herein may address un-induced erasure errors in addition to or alternatively to gate induced erasure errors.

The systems, the methods, the computer-readable media, and the techniques disclosed herein may improve upon other procedures at least because the systems, the methods, the computer-readable media, and the techniques disclosed herein may not comprise or require operations that modify the topology of the underlying surface code. In some cases, the underlying surface code may be unchanged. Instead, a matching graph passed to a decoder algorithm may be updated to account for a predicted probability distribution of a lost qubit. Because the matching graph passed to the decoder is updated, the underlying decoder may also be unchanged. Because the decoder is unchanged, the error correcting code may also not be changed. Accordingly, the systems, the methods, the computer-readable media, and the techniques disclosed herein may be used without changing the underlying surface code. Similarly, because changes to the underlying decoder and surface code are not needed, the systems, the methods, the computer-readable media, and the techniques disclosed herein may be used with a wide variety of decoders and surface codes.

In some cases, tracking syndrome measurements may be used to detect loss events (e.g., defects). See, e.g., Siegel, A. et al., Adaptive Surface Code for Quantum Error Correction in the Presence of Temporary or Permanent Defects, arXiv: 2211.08468v1 [quant-ph] 15 Nov. 2022, available at https://arxiv.org/pdf/2211.08468.pdf, which is incorporated by reference herein in its entirety.

In some cases, gate induced erasure errors may be addressed by error correction. See e.g., Wu, Y., et al., Erasure conversion for fault-tolerant quantum computing in alkaline earth Rydberg atom arrays, Nat. Comms. Vol 13, P. 4657 (2022), which is incorporated by reference herein in its entirety. In the above, the atoms may still be present. Rather than addressing missing atoms or qubits, the above referenced application may turn gate errors into erasure errors.

In some cases, noise structure in the hardware may be used for error correction. See e.g., Shay, K., et al., High threshold codes for neutral atom qubits with biased erasure errors, arXiv: 2302.03063v1 [quant-ph] 6 Feb. 2023), which is incorporated by reference herein in its entirety. Similar to Wu, the atoms may still be present. Rather than addressing missing atoms or qubits, the above referenced application may turn gate errors into erasure errors.

### Error Correction

Quantum error correction is a procedure for encoding quantum information in a distributed manner across many quantum systems in such a way that the information to be stored is protected from localized errors on the constituent systems, provided that these errors are sufficiently sparse. In some cases, the information to be stored and the constituent systems are both two-level quantum systems, or qubits. The information to be protected is encoded across many physical qubits, forming one or more logical qubits.

The process of detecting and correcting errors on the logical qubits amounts to measuring parities of a predetermined set of operators that act on the physical qubits and using the measured parities to diagnose and correct errors. In a simple example, a parity measurement checks the equality of two qubits to return a true or false answer, which can be used to determine whether a correction needs to occur. Additional measurements can be made for a system greater than two qubits. Since the physical qubits cannot be measured directly without collapsing the state of the logical system, these parities are measured using ancillary qubits (i.e., ancilla). Thus, there may be two types of physical qubits: data qubits on which the logical information is stored and ancilla qubits which are used to extract the desired parity checks.

In practice, an error correction cycle consists of a sequence of gates to transfer parity values onto the ancilla qubits followed by measurement of the ancilla qubits. This process may be referred to as syndrome extraction. Errors can occur at any point during the syndrome extraction process, including during readout of the ancilla qubits.

One method of error correction (Shor style) uses repeated rounds of syndrome extraction to overcome readout error and build confidence about the state of the system. The extracted syndrome information is then passed to a decoder to determine which errors have occurred and which corrections need to be applied. The decoding problem is commonly represented as a weighted graph or hypergraph. In this setting, each node in the graph corresponds to a collection of syndrome measurements. Such a collection of syndrome measurements is called a detector. Edges or hyperedges in the graph correspond to errors, and the weight of an edge corresponds to the likelihood of that error occurring. The occurrence of a given error may be expected cause the parity of all associated detectors to flip. The decoding problem can then be stated as follows: given a set of detectors (nodes) whose parities differ from those expected in the absence of error, determine the most likely set of physical errors (edges) that could cause the observed detections.

Error Correction with Atom Loss

Quantum computers based on trapped atoms may be subject to errors generated by loss of qubit. In trapped atom quantum computers, a qubit may comprise atom in an array. That atom may be a neutral atom or an ion. Error correcting code may employ repeated implementations of the circuit implementing the quantum computation. As the circuit is implemented and re-implemented statistics may be generated on what errors occurred. However, error correcting code implemented on systems with qubit loss may differ from other systems. For example, a non-qubit loss error may be a gate error. Similarly, loss of coherence may be expressed as a gate error. In a gate error or an error that is similar to a gate error, there is a comparatively smaller set of possible error values because the result of a gate error is like a measurement of the system. In some cases, the atom loss rate may be similar or larger than the gate error rate, thus it may be helpful to provide improved methods of correcting for atom loss.

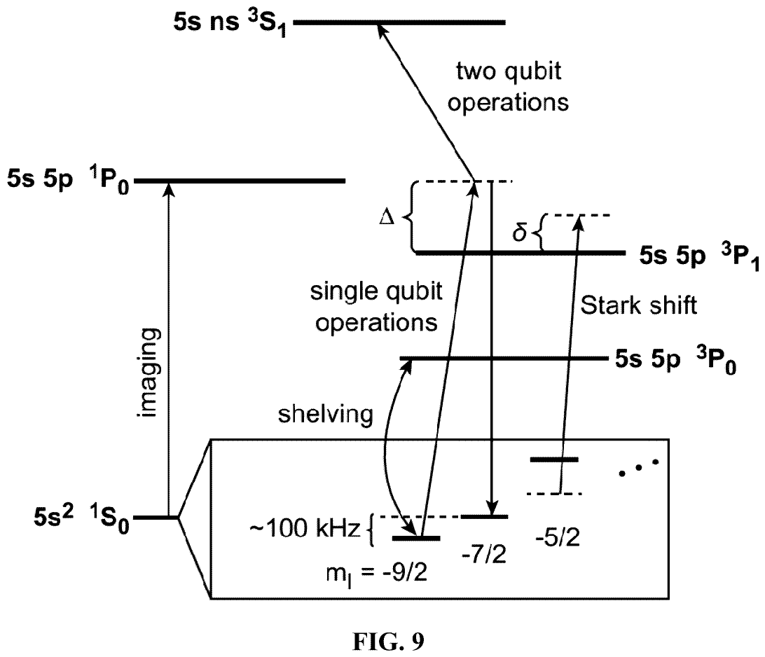

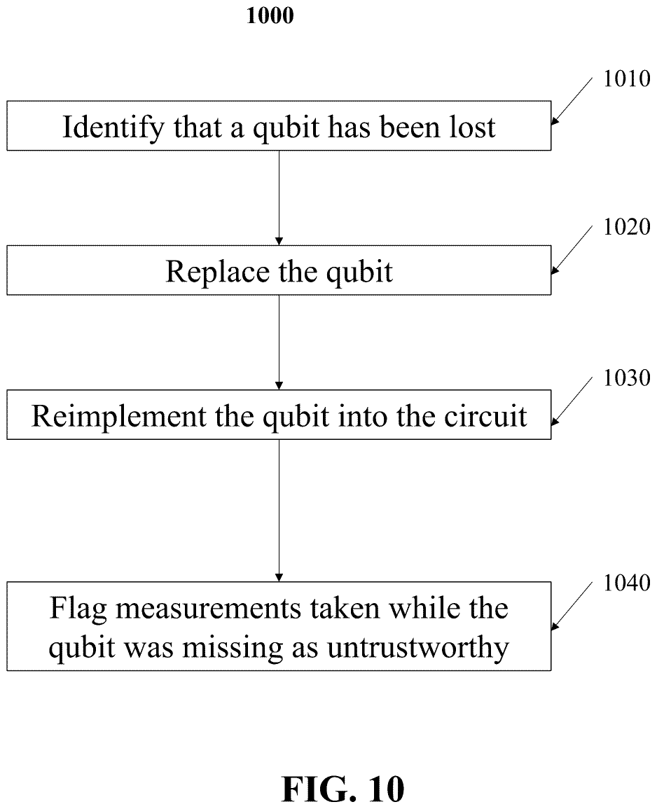

FIG. 10 is a flowchart of an example method 1000 for error corrected quantum computation. In some cases, an error correcting code which accounts for qubit loss may comprise identifying that a qubit has been lost (1010); replacing the qubit (1020); reimplementing the qubit into the circuit which may be in the wrong state when it is replaced 1030; and flagging measurements taken while the qubit was missing as untrustworthy (1040).

Referring to FIG. 10, at an operation 1010 of a method 1000 of error correction with atom loss, atom loss can be detected. For example, atom loss may be detected at the end of each syndrome extraction cycle. Methods of detecting atom loss are described herein. At an operation 1020 of a method 1000 of error correction with atom loss, once a qubit is identified as lost it may be replaced with a new qubit. The new qubit may be, at least initially, in a random state.

At an operation 1030 of a method 1000 of error correction with atom loss, the qubit may be reimplemented into the circuit. In some cases, operation 1030 comprises use of a decoder algorithm. The decoder algorithm may take in a graph and determine a set of edges. In some cases, operation 1030 comprises prior implementing the decoder algorithm, updating a matching graph passed to the decoder algorithm based on a predicted probability distribution of a lost qubit replaced in operation 1020. Methods of updating the decoder algorithm are described herein.

In systems not subject to atom loss, the errors may be discrete Pauli errors on physical qubits. But when qubits are stored on atoms, the atoms- and therefore the qubits they contain—can be lost. The effect on syndrome extraction in the presence of loss depends on hardware details. For neutral atoms using Rydberg gates, the effect of atom loss manifests as a non-interaction instead of a two-qubit gate. Practically, two-qubit interactions between a lost and present atom may be treated as affecting an Identity gate on the present atom.

In an example, the systems, the methods, the computer-readable media, and the techniques disclosed herein may comprise a case in which a two-qubit interaction between a qubit and a lost qubit has an effect of a Pauli operation or identity operation on the qubit, as described in International Application PCT/US2024/018180, which is incorporated by reference in its entirety herein in its entirety for all purposes. In such a case, a first atom A and second atom B may be neighboring qubits. The qubits may be trapped ion qubits. The qubits may be trapped atom qubits. In some cases, one qubit acquires a phase conditioned on state-selective excitation of the other. In some cases, the state selective excitation is from a state |1> to a state |r>.

In some cases, a state |r> is a Rydberg state. In some cases, a state |r> is a Rydberg state of a neutral atom qubit. If at A is excited to a Rydberg state, then Atom B (if present) experiences a shift due to the Rydberg interaction. In some cases, an optical excitation may be tuned to a frequency difference between the |1> state and the Rydberg state. If Atom A is in state |1>, then Atom A is at least transiently driven to the Rydberg state and Atom B (if present) experiences a shift due to the Rydberg interaction. If Atom B is not present and Atom A is in state |1>, there is no Shift to Atom B. If Atom A is in state |0> and Atom B is present, then the energy gap is too large, and nothing happens to Atom A or Atom B. If Atom A is in state |0> and Atom B is not present, then the energy gap is still too large, and nothing happens to Atom A or Atom B (which isn't present). Accordingly, two-qubit interactions between a lost and present atom may be treated as affecting an Identity gate on the present atom. While this example describes a case where the two-qubit interaction with a lost atom affects the Identity operation, the systems, the methods, the computer-readable media, and the techniques disclosed herein also work when the two-qubit interaction with a lost atom affects a Pauli operation. A Pauli operation may comprise a Pauli-X gate, a Pauli-Y gate, or a Pauli-Z gate. For example, the Pauli-X gate is a single-qubit rotation the pi radians around the X-axis. For example, the Pauli-Y gate is a single-qubit rotation the pi radians around the Y-axis. For example, the Pauli-Z gate is a single-qubit rotation the pi radians around the Z-axis. A rotation about an axis of two pi radians is an Identity operation.

The above works similarly if Atom A is also a lost qubit. In some cases, the qubit is a non-lost qubit. In some cases, the qubit is a lost qubit. For example, when the qubit is a lost qubit, a two-qubit gate between two lost qubits similarly affects the identity. Because the two-qubit operation between an atom a lost atom affects the identity. The protocol does not propagate errors (to first order) forward in time. For example, if the two-qubit operation is imperfect. The operation may propagate forward higher order errors in time.

### Examples of Identifying Qubit Loss

In some cases, the present disclosure provides at least two methods of identifying qubit loss; however, various methods of identifying qubit loss may be integrated into the systems, the methods, the computer-readable media, and the techniques disclosed herein. An example method of implementing an error correcting code which accounts for atom loss may comprise implementing a plurality of SWAP gates. Another example method of implementing an error correcting code which accounts for atom loss may comprise a modified knock-knock protocol. The systems, the methods, the computer-readable media, and the techniques disclosed herein for the implementation of a plurality of SWAP gates and modified knock-knock protocols may be the same as or similar to those described in International Application PCT/US2024/018180, which is incorporated by reference herein in its entirety for all purposes.

### Examples of Qubit Replacement

The systems, the methods, the computer-readable media, and the techniques disclosed herein may replace qubits into a quantum circuit after a vacancy has been identified. In some cases, the qubit is an atomic qubit. In some cases, the qubit is atom trapped in a spatially distinct optical trapping site. Examples presented herein may be recite qubits comprising neutral atoms; however, the systems, the methods, the computer-readable media, and the techniques disclosed herein may be combined with various types of qubits.

In some examples, present techniques may be combined with methods for probabilistic, deterministic, or near-deterministic loading of optical or other traps, such as those disclosed herein. In some cases, atoms within the science region may or may not be rearranged as the science array is replenished. In some cases, atoms can be transferred between sites by optical tweezers. In some cases, atoms can be transferred between sites by optical lattices. In some cases, atoms can be transferred between sites by tunneling/hopping between sites. In some cases, atoms can be transferred between sites by autonomous stabilization techniques.

In some cases, atom replacement is performed using one or both of a moving optical trap (e.g., moving optical lattice) or one or more optical tweezers. In some cases, an optical tweezer may be used to move a single atom (e.g., pick and place) or a subset of atoms between arrays or within an array. In some cases, a moving optical trap can be used to translate or compress an array. A moving optical trap (e.g., moving optical lattice) may implement a tone to sweep atoms from one location to another. The atom movement units may be configured to move the one or more replacement atoms from the one or more atoms reservoirs to the one or more optical trapping sites. For instance, the one or more atom movement units may comprise one or more electrically tunable lenses, acousto-optic deflectors (AODs), or spatial light modulators (SLMs).

The atom rearrangement unit may be configured to alter the spatial arrangement in order to obtain an increase in a filling factor of the plurality of optical trapping sites. A filling factor may be defined as a ratio of the number of computationally active optical trapping sites occupied by one or more atoms to the total number of computationally active optical trapping sites available in the optical trapping unit or in a portion of the optical trapping unit. For instance, initial loading of atoms within the computationally active optical trapping sites may give rise to a filling factor of less than 100%, 90%, 80%, 70%, 60%, 50%, or less, such that atoms occupy fewer than 100%, 90%, 70%, 60%, 50%, or less of the available computationally active optical trapping sites, respectively. It may be desirable to rearrange the atoms to achieve a filling factor of at least about 50%, 60%, 70%, 80%, 90%, or 100%. By analyzing the imaging information obtained by the imaging unit, the atom rearrangement unit may attain a filling factor of at least about 50%, 60%, 70%, 80%, 90%, 91%, 92%, 93%, 94%, 95%, 96%, 97%, 98%, 99%, 99.1%, 99.2%, 99.3%, 99.4%, 99.5%, 99.6%, 99.7%, 99.8%, 99.9%, 99.91%, 99.92%, 99.93%, 99.94%, 99.95%, 99.96%, 99.97%, 99.98%, 99.99%, or more. The atom rearrangement unit may attain a filling factor of at most about 99.99%, 99.98%, 99.97%, 99.96%, 99.95%, 99.94%, 99.93%, 99.92%, 99.91%, 99.9%, 99.8%, 99.7%, 99.6%, 99.5%, 99.4%, 99.3%, 99.2%, 99.1%, 99%, 98%, 97%, 96%, 95%, 94%, 93%, 92%, 91%, 90%, 80%, 70%, 60%, 50%, or less. The atom rearrangement unit may attain a filling factor that is within a range defined by any two of the preceding values.

### Examples of Modifying Decoding Algorithms

The systems, the methods, the computer-readable media, and the techniques disclosed herein may be used in connection with error correction methodologies for quantum computing systems. An error correcting scheme (e.g., an implementation of an error correcting code) of the present disclosure may comprise a decoder and an error correcting code. A decoder may decode which errors occurred on which qubits. Once identified, these errors can be tracked and the information used to correct any subsequent measurement outcomes using the classical control software. The methods of updating the decoder described herein may not depend on the type of atom, the type of qubit, the type of error correction code, or the specific decoder used in the error correcting code. In some cases, an error correcting code may be of the class of stabilizer codes. If the two qubit-gate operation affects the Identity or a Pauli operation, then the matching graph passed to the decoder may be updated as described herein.

The systems, the methods, the computer-readable media, and the techniques disclosed herein may be used with various error correcting codes. An error correcting code may be a Shor style code. For example, in a Shor style code, repeated rounds of syndrome extraction may be implemented to overcome readout error and build confidence about the state of the system. The extracted syndrome information is then passed to a decoder to determine which errors have occurred and which corrections need to be applied.

The systems, the methods, the computer-readable media, and the techniques disclosed herein may be used with various stabilizer codes. A stabilizer code may be an error correcting code which uses stabilizers. A stabilizer code may be a class of error correcting code. The class of stabilizer codes may include toric codes, surface codes, etc. By repeatedly measuring a quantum system using a complete set of commuting stabilizers, the system may be forced into a simultaneous and unique eigenstate of all the stabilizers. One can measure the stabilizers without perturbing the system; when the measurement outcomes change, this corresponds to one or more qubit errors, and the quantum state is projected by the measurements onto a different stabilizer eigenstate.

An error correcting code may comprise a topological code. The class of topological codes may overlap with the class of stabilizer codes. A topological code may comprise a surface code, a color code, a toric code, etc. A topological code may also be referred to as a homological code. A topological code may comprise an array or lattice of qubits arranged on a surface (or higher dimensional structure). The systems, the methods, the computer-readable media, and the techniques disclosed herein may not change the underlying topology of a topological code.

The systems, the methods, the computer-readable media, and the techniques disclosed herein may be used with various surface codes. A surface code may be implemented as a stabilizer code. For example, in the surface code literature, surface codes may comprise two types of qubits data qubits and measurement qubits (e.g., ancilla qubits). The data qubits may contain the information carried by the quantum circuit, whose error is to be corrected. The measurement qubits may be used to stabilize and manipulate the quantum state of the data qubit. In a surface code, the measurement qubits may comprise two types: measure-Z qubits and measure-X qubits. These two types of qubits may be called Z syndrome qubits and X-syndrome qubits respectively. The measure Z-qubits may measure the Z stabilizer. The measure X-qubits may measure the X stabilizer. In some cases, a surface code may be implemented with a decoder. In some cases, a surface code can address errors that occur during a surface code cycle as long as the errors that occur during each surface code cycle can be identified.

The systems, the methods, the computer-readable media, and the techniques disclosed herein may employ surface codes. Surface codes disclosed herein may include, for example, variations upon the minimum-weight perfect matching algorithm to decode the surface code. However, many surface codes may be applicable to the systems, the methods, the computer-readable media, and the techniques disclosed herein. A description of surface codes is provided for example at Fowler, A. G., et al., Surface codes: Towards Practical Large-scale Quantum Computation, arXiv: 1208.0928 [quant-ph] 4 Aug. 2012, available at https://arxiv.org/pdf/1208.0928.pdf, which is incorporated by reference herein in its entirety.

The systems, the methods, the computer-readable media, and the techniques disclosed herein may be used with various color codes. A color code may be implemented as a stabilizer code. For example, a color code may comprise a Steane code, etc. The systems, the methods, the computer-readable media, and the techniques disclosed herein may be used with various Shor style codes, for example, a Bacon-shor code. A Shor style code may be implemented as a stabilizer code. The systems, the methods, the computer-readable media, and the techniques disclosed herein may be used with various qLDPC codes, for example, hypergraph product codes. A qLDPC code may be implemented as a stabilizer code.

The systems, the methods, the computer-readable media, and the techniques disclosed herein may be used with various decoders. An error correcting scheme (e.g., an implementation of an error correcting code) of the present disclosure may comprise a decoder and an error correction code. A decoder may decode which errors occurred on which qubits. Once identified, these errors can be tracked and the information used to correct subsequent measurement outcomes using the classical control software. Decoder algorithms may include, for example, minimum-weight perfect matching, union find, tensor network decoder, belief propagation with ordered statistics decoder, maximum likelihood decoder, and look up table decoders. The systems, the methods, the computer-readable media, and the techniques disclosed herein may be integrated with variations on the minimum-weight perfect matching such as sparse bloom and fusion blossom. A decoder may take in a matching graph. The systems, the methods, the computer-readable media, and the techniques disclosed herein may update the matching graph passed to the decoder to account for a lost qubit.

In some cases, qubit loss may involve modification to surface code techniques that do not experience qubit loss errors. For example, error correcting code which does not account for qubit loss errors may keep track of a particular qubit changing from 1 to 0 or 0 to 1 unexpectedly. If a qubit has been lost, there is no change in state; instead, there is no value to measure.

Modifying the decoding algorithm may be a sub-operation of an operation for reimplementing the qubit into the circuit. A qubit reimplementing operation may comprise an embodiment, variation, or example of operation 1030 of the method 1000. In some cases, modifying the decoding algorithm may be performed subsequent to or during a reimplementing operation such as operation 1030 of a method 1000.

To augment the decoding algorithm, the systems, the methods, the computer-readable media, and the techniques disclosed herein may update existing decoders to incorporate the change in error type. In some cases, the systems, the methods, the computer-readable media, and the techniques disclosed herein may update the matching graph passed to a decoder. In some cases, the systems, the methods, the computer-readable media, and the techniques disclosed herein may update the matching graph passed to a minimum-weight perfect matching decoder algorithm or any other decoder algorithm which takes in a matching graph.

In some examples, to update the matching graph, each node in the graph corresponds to a change-of-value of a particular stabilizer. Certain nodes are connected by edges corresponding to possible physical errors. These edges are weighted based on the likelihood of that particular error occurring. When an atom is lost and then replaced, the loss may be treated like a gate error that occurs with a probability of 50%. The procedure may change slightly if data vs. ancilla qubits are lost.

The systems, the methods, the computer-readable media, and the techniques disclosed herein may be implement approaches for reimplementing a qubit, such as, as described in International Application PCT/US2024/018180, which is incorporated by reference herein in its entirety for all purposes.

### Examples of Measurement Operation

At an operation 1040 of a method 1000 of error correction with atom loss, measurements taken while the qubit was missing may be flagged as untrustworthy. In some cases, operation 1040 comprises flagging measurement taken during a window of time that includes a time when the qubit was missing as untrustworthy. For example, a window of time may comprise a round of syndrome measurements. It may not be necessary to know exactly which measurements were taken while the atom was lost, only what set of measurements were taken during a window of time that includes a lost atom. A flagging operation may comprise, prior to flagging a measurement, performing a measurement of one more qubits. The measurement may result in an emission of a photon. In some cases, the measurement may be state selective. For example, a measurement may selectively probe either a |0> state or a |1> state. After a round of measurement, it may be possible to know whether a measured atom is lost. In some cases, measurement of ancilla atoms during an error correction protocol may indicate whether an ancilla atom is lost. An identification operation in 1010 (e.g., swap gates, a knock-knock protocol, etc.) may be performed in order to determine if a qubit is missing within a set of qubits including a data qubit without measurement of the data qubit.

In the systems, the methods, the computer-readable media, and the techniques disclosed herein, the fact of a missing qubit may not be immediately heralded. For example, it may become apparent that qubit is lost after completing a round of syndrome extraction, rather than immediately upon taking a measurement implicating a lost qubit. Once the round of syndrome extraction is complete, it may become apparent that there was a qubit loss, in order to proceed with the calculation in may be beneficial to flag a series of measurements taken during a window of time that includes a time when the qubit was missing. Each of these measurements may be flagged as untrustworthy. In some cases, the series of time which includes the flagged qubit may not be limited to the time in which the qubit is definitively lost. The series of time which includes the flagged qubit may include at least the time with the qubit was lost.

Advantageously, a qubit loss may be identified before measurement of the data qubits (and after a round of syndrome extraction). Since the data qubits have not yet been measured, it may be possible to continue on with a quantum circuit after replacing a lost qubit. The circuit may be adapted to retake or restart portions of the calculation implicating the lost qubit. As a consequence, the systems, the methods, the computer-readable media, and the techniques disclosed herein may allow for loss detection between cycles (or possibly less frequently) rather than after every gate.

For example, the error correcting code may be directed to updating the calculation to address for error. In some cases, knowing about the error may be needed in order to implement error correcting code. However, in other cases, the error correcting code may be modified to account for missing data without explicit knowledge that qubit is lost.

### Examples of Systems for Error Corrected Quantum Computing

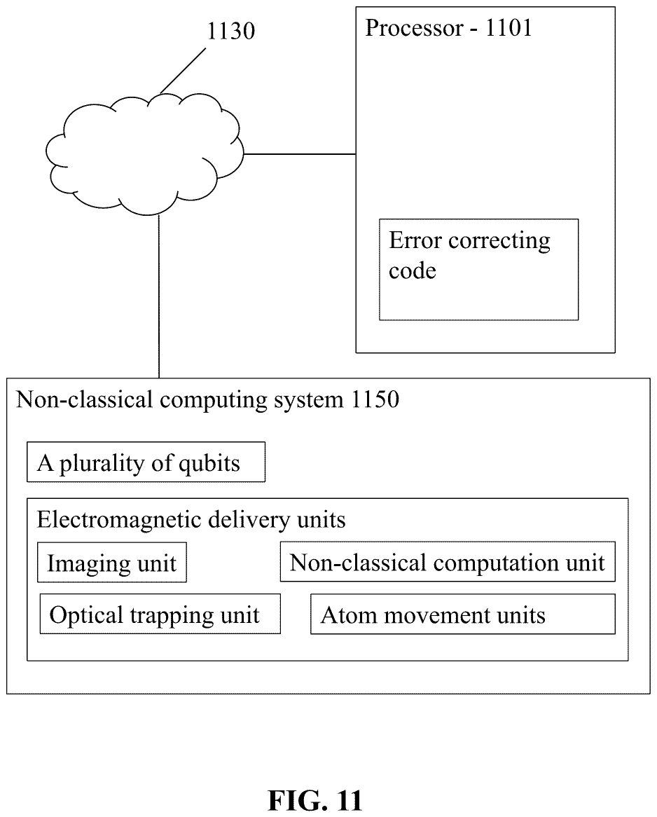

FIG. 11 shows a system for error corrected quantum computing that is programmed or otherwise configured to implement methods provided herein. A system for error corrected computing may comprise an error correcting code. The present disclosure provides systems for error corrected quantum computing. The system may comprise an error correction code. An implementation of the error correcting code may comprise a decoder. The decoder may be configured to receive a matching graph and to determine a set of edges, and the matching graph received by the decoder may be updated based on a predicted probability distribution of a lost qubit. In some cases, the error correction code comprises an operation in which a two-qubit interaction between a qubit and a lost qubit has an effect of a Pauli operation or an identity operation on the qubit. In some cases, the qubit is a non-lost qubit. In some cases, the qubit is a lost qubit.

In some cases, a system for error corrected quantum computing may comprise a non-classical computing system 1150. The non-classical computing system may be quantum computing system. The non-classical computing system may be a trapped atom quantum computing system. The trapped atom quantum computing system may comprise: an atom movement unit, an atom rearrangement unit, an optical trapping unit, an imaging unit, an optical pumping unit, an entanglement unit, a Rydberg unit, a non-classical computation unit, an electromagnetic deliver unit, or any combination thereof.

In some cases, the non-classical computing system may comprise a plurality of qubits.

In some cases, the non-classical computing system may comprise one or more electromagnetic delivery units. The electromagnetic delivery units may be configured to produce electromagnetic excitations to perform various operations, such as for example, atom movement, atom rearrangement, optical trapping, imaging, and various operations on atoms that may comprises portions of a nonclassical computation. Portions of a non-classical computation on trapped atoms may comprise optical pumping, entanglement operations, Rydberg operations, gate operations (e.g., one qubit operations, two qubit operations, etc.). In some cases, an atom movement unit may comprise an atom rearrangement unit. The components of a non-classical computing system are discussed herein above with respect to the operations they implement.

In some cases, the system further comprises a non-classical computing system, wherein the non-classical computing system comprises trapped atom qubits. In some cases, the trapped atom qubits comprise neutral atom qubits. In some cases, the neutral atom qubits comprise a Group II element or a Group II-like element. In some cases, the Group II element or a Group II-like element comprises Ytterbium, Rubidium, Cesium, or Strontium. In some cases, the plurality of qubits comprises qubit states comprising nuclear spin states on the ¹S₀ manifold. In some cases, the two-qubit interaction comprises an excitation of a nuclear spin state of a neutral atom to a Rydberg state of the neutral atom.

In some cases, the system further comprises a non-classical computing system, wherein the non-classical computing system comprises a plurality of qubits, wherein the plurality of qubits comprises atomic qubits, and wherein an atom replacement operation is implemented using optical tweezers.

In some cases, the non-classical computing system may be configured to interact with a processor 1101. The processor may be classical processing system. The processor may be digital processing system.

In some cases, the system further comprises a processor configured to implement an error correcting code. In some cases, the processor is further configured to provide instructions to a non-classical computing system, wherein the non-classical computing system is configured to implement the instructions to: (i) identify that a qubit has been lost; (ii) replace the qubit; and (iii) reimplement the qubit into the circuit. In some cases, the processor is further configured to (iv) flag measurements taken while the qubit was missing as untrustworthy. In some cases, (i) comprises using a plurality of swap gates. In some cases, a swap gate within the plurality of swap gates is implemented as a plurality of CNOT gates. In some cases, the processor is further configured to provide instructions to the non-classical computing system to measure alternating atoms in a lattice; perform the plurality of swap gates to transfer data stored on data qubits to ancilla qubits; and measure the swapped data qubits to identify one or more lost atoms.

In some cases, (i) comprises using a modified knock-knock protocol, wherein the modified knock-knock protocol comprises: providing a first atom to be probed using a second atom, wherein the second atom is an ancilla qubit; preparing the second atom in a |+> state; applying a modified control-Z gate between the first atom and the second atom based on a Rydberg interaction; and rotating the second qubit back to a computational basis and performing a measurement. In some cases, (iii) comprises (A) use of a decoder algorithm, wherein the decoder algorithm takes in a graph and determines a set of edges. In some cases, prior to (A) the processor is further configured to update a matching graph passed to the decoder algorithm based on a predicted probability distribution of a lost qubit replaced in (ii). In some cases, (iii) comprises use of a minimum-weight perfect matching decoder algorithm. In some cases, the processor is further configured to update a matching graph passed to the minimum-weight perfect matching decoder algorithm based on a predicted probability distribution of a lost qubit replaced in (ii). In some cases, the processor is further configured to: if an ancilla qubit is lost, update the matching graph so that a node involving the ancilla qubit is connected by edges corresponding to the predicted probability distribution; and if a data qubit is lost, update the matching graph by assigning the predicted probability distribution to each node involving the data qubit. In some cases, each node involving the ancilla qubit is updated.

In some cases, the error correcting code is configured to be implemented during a quantum computation circuit. In some cases, the error correcting code is configured to be implemented without measurement of each or a plurality of data qubits. In some cases, the error correcting code is configured to be implemented substantially without loss of coherence of each or a plurality of data qubits. In some cases, processor is further configured to flag measurements taken during a window of time that includes a time when the lost qubit was missing as untrustworthy.

In some cases, the decoder comprises union find, tensor network decoder, belief propagation with ordered statistics decoder, maximum likelihood decoder, or a look up table decoder. In some cases, the decoder comprises minimum weight perfect matching. In some cases, the decoder comprises sparse blossom or fusion blossom. In some cases, the error correcting code comprises a topological code. In some cases, the topological code is a stabilizer code. In some cases, the error correcting code is a surface code, a color code, a toric code, a shor style code, or a qLDPC code. In some cases, the color code is a Steane code. In some cases, the shor style code is a Bacon-shor code. In some cases, the qLDPC code is a hypergraph product code. In some cases, each node in the matching graph corresponds to a change-of-value of a particular stabilizer and wherein pairs of nodes are connected by edges corresponding to possible physical errors. In some cases, the edges are weighted based on the likelihood of a particular error occurring. In some cases, atom loss is treated as a gate error that occurs with a probability of 50%.

In some cases, the processor is further configured to provide instructions to the non-classical computing system to perform a measurement operation, wherein the measurement operation is state selective. In some cases, the measurement operation comprises applying electromagnetic energy to a qubit to be measured, wherein the electromagnetic energy is configured to selectively drive the qubit to be measured from an initial state to an excited state in a presence of an applied magnetic field, wherein a selectivity of a transition to the excited state is based at least in part on a strength of the applied magnetic field. In some cases, the processor is further configured to determine that the qubit to be measured was in the initial state based at least in part on the qubit returning to the initial state by emission of a photon in response to the electromagnetic energy.

### Examples of Processes for Performing Continuous, Non-Classical Computations

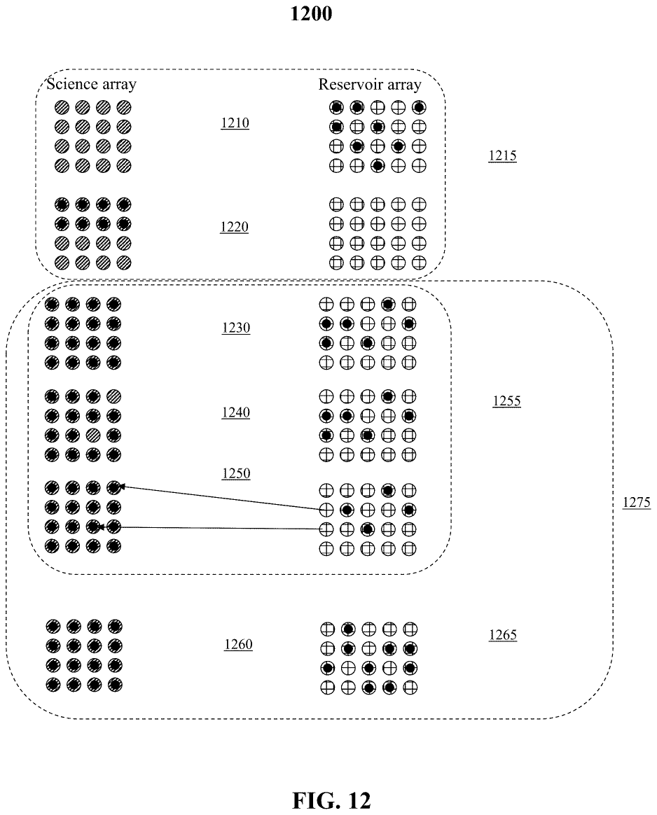

FIG. 12 illustrates an example process 1200 for performing continuous, non-classical computation. In some examples, the process 1200 may be implemented with the science region and the reservoir region being sufficiently distinct to enable loading of the reservoir region with sufficiently low disturbance of atoms within the science region. One way to accomplish this is for the reservoir and science regions to not be sub-regions of the same array, but rather to be distinct arrays in the sense that they may be formed using different lasers or different optical elements. Further, in some embodiments, the reservoir may be loaded from a third “transport” array, rather than from a MOT. This last technique may eliminate a use for near-resonant light, and so may allow for continuous coherent operations to be performed during the reloading process.

At a high level, the process 1200 may comprise: loading a reservoir array, transferring atoms to a science array from the reservoir array, performing a computation/simulation using the science array, atomic loss occurring in the science array, refilling the science array from the reservoir array, and reloading the reservoir array. A science array may comprise atoms that are actively being used for the application (e.g., quantum computing, optical clocks, sensing, or any other application disclosed herein). A science array in a quantum computer may comprise data qubits and ancilla qubits. A reservoir array may comprise atoms that are not actively in use but which may be used at a later time to replace atoms lost from the science array, e.g., a lost ancilla qubit from a quantum computer.

In some cases, the process 1200 may begin with both the reservoir array and the science array being empty. Once atoms are loaded into the reservoir array, the atoms in the reservoir may then be imaged. In some examples, at least some of the atoms in the reservoir array may then transferred into the science array (for example using optical tweezers). The reservoir array can be reloaded to achieve a full or fuller reservoir array and enable further transfer of more atoms from the reservoir array into the science array. Once the science array is fully occupied (or occupied to a desired/predetermined amount), the computation/simulation may begin. During the computation/simulation, the science array may be periodically imaged to determine if and where atom loss has occurred. If an atom has been lost from a site in the science array, an atom from the reservoir array may be transferred to fill the site. This may continue provided there are sufficient atoms in the reservoir array. When there are not, new atoms may be loaded into the reservoir array, and the process continues. As illustrated in FIG. 12, the process 1200 may be iterative or repetitive in some examples, with potential repetition of one or more operations of the process 1200.

FIG. 12 shows an example method and system for performing continuous, non-classical computations. The method 1200 may comprise an operation 1210. Operation 1210 may comprise loading a plurality of atoms into a reservoir array that includes a first plurality of spatially distinct optical trapping sites. The first plurality of optical trapping sites may be configured to trap the plurality of atoms. In some cases, the plurality of atoms are qubits in a non-classical computational system, such as a quantum computer, a quantum annealer, etc. In some cases, the plurality of atoms comprises atoms in an atomic clock.

The method 1200 may comprise an operation 1220. Operation 1220 may comprise transferring a first subset of the plurality of atoms from the reservoir array into a science array. The science array may include a second plurality of spatially distinct optical trapping sites. The second plurality of optical trapping sites may be configured to trap a plurality of atoms.

In some cases, at operation 1215, operations 1210 and 1220 may be repeated a number of times. The operations may be repeated until a science array comprises a sufficient fill factor for quantum computation, quantum simulation, clock operations, metrology operations, sensing operations, etc.

The method 1200 may comprise an operation 1230. Operation 1230 may comprise performing a first application using at least some of the first subset of the plurality of atoms in the science array. The application may be quantum computation, quantum simulation, clock operations, metrology operations, sensing operations, etc.

The method 1200 may comprise an operation 1240. Operation 1240 may comprise determining an atomic loss in one or more of the arrays. The operation may comprise determining an atomic loss number representing a difference between (i) a number of atoms in the first subset of the plurality of atoms and (ii) a number of atoms in a remaining subset of the first subset of the plurality of atoms that remain in the science array following the performing of the first non-classical computation. Atom loss may occur due to collisions with residual background gas, to leakage into un-trapped or otherwise undesirable internal states, due to heating associated with laser interactions, or other processes.

The method 1200 may comprise an operation 1250. Operation 1250 may comprise transferring a second subset of the plurality of atoms from the reservoir array into the science array. Operation 1250 may comprise a reloading operation. In some cases, the second subset of the plurality of atoms includes at least a number of atoms equal to the atomic loss number. In some cases, the second subset of the plurality of atoms includes a number of atoms less than the atomic loss number. The second subset may be transferred substantially without loss of a coherence of the plurality of atoms in the science array. The second subset may be transferred substantially without stopping an application in the science array.

In some cases, at operation 1255, operations 1230, 1240, and 1250 may be repeated a number of times. The operations may be repeated until a quantum computation, quantum simulation, clock operation, metrology operation, etc. is complete. The operations may be repeated while there are atoms in a reservoir to be filed into the science array.

The method 1200 may comprise an operation 1260. Operation 1260 may comprise reloading the reservoir array with additional atoms. The reservoir may be reloaded from an atom source. The atom source may be cooled atom source. In some examples, reservoir regions may be filled from a magneto-optical trap (MOT), from an atomic beam, from a thermal atomic gas, from another optical or other form of electromagnetic trap, or from any other source of atoms. In some examples, the initial loading of the science region may be direct (from any atomic source other than the reservoir array), from the reservoir array, or from a separate reservoir array than the one used for replenishing. In some examples, the reservoir region may be smaller, larger, or the same size/number of sites as the science region and similar techniques may be used to maintain an arbitrary number of atoms within each site of the science array.

In some cases, at operation 1265, operation 1260 may be repeated a number of times. Operation 1260 may be refilled a number of times to fill a reservoir array. The operation may be repeated such that an application in operation 1230 may be performed continuously.

In some cases, at operation 1275, operations 1255 and 1265 may be both be repeated in order to maintain a fill factor in the science array. In some cases, the method may comprise performing a second non-classical computation using at least some of one or both of (i) the remaining subset of the first subset of the plurality of atoms and (ii) the second subset of the plurality of atoms.

The present disclosure comprises various sub-operations of the method 1200. For example, one or more of the operations of the method 1200 may be removed. For example, one or more of the operations of the method 1200 may be repeated.

### Examples of Continuous Loading

A useful error-corrected quantum computer should remove entropy faster than it can enter. One source of entropy in a trapped atom quantum computer may be atom loss. Accordingly, it may be useful to conditionally refill sites in a trapped atom quantum computer continuously with the calculation. Continuous operation during a non-classical computation may comprise refilling a lost atom during operations of computation. For example, continuation operation in a gate-model quantum computer may comprise refilling lost atoms “mid-circuit” or between gate operations in a quantum computation. Continuous operation in a quantum simulator may comprise refilling an atom during the simulation. Continuous operation in a clock operation may comprise refilling an atom during operation of the clock. For example, continuous operation may comprise refilling an atom during the time in which the application is being implemented.

Continuous operation may comprise refilling an atom substantially without stopping the application. Substantially without stopping may comprise not performing recovery operations, such as repeating previous operations, to account for the atom loss. Such recovery operations may comprise repeating a calculation or a portion of a calculation to replace a “lost” portion.

Similarly, since each of quantum computation, quantum simulation, clock operations, metrology, and quantum sensing may utilize phenomena such as quantum coherence, it may be useful to maintain coherence while refilling atoms in an atom-based implementation of these applications (e.g., an atomic clock, a neutral atom quantum computer, etc.). For example, atoms may be refilled substantially without loss of coherence of atoms in the array. Substantially without loss of coherence may comprise contrast loss on the order of 10% or better on seconds time scale. E.g., less than 10% loss of contrast over 2 seconds, about 5% contrast loss over two seconds or better. Substantially without loss of coherence may comprise a contrast of better than 0.8 (maximum of 1) over 1 second.

The present disclosure provides systems, methods, computer-readable media, and techniques for continuous atom reloading. The systems, the methods, the computer-readable media, and the techniques disclosed herein may distinguish the science array and the reservoir array during atom transfer.

For example, the arrays may be physically distinguished. The systems, the methods, the computer-readable media, and the techniques disclosed herein may employ distinct sets or subsets of atoms within an array. For example, FIG. 12 and FIG. 14 show a science array and a reservoir array. In some cases, the science array is distinct from the reservoir array. In some cases, the science array is spatially distinct from the reservoir array. For example, the science array may be physically separated from the reservoir array. For example, the science array may be energetically separated from the reservoir array during atom movement. In some cases, both physical and energetic separation methods may be used to facilitate atom movement without disruption of the science array.

Physical separation of the science array and the reservoir array may be useful in at least some respects for example. If the science array and the reservoir array are physically distinct, the reservoir array can be more easily spatially separated from the science region. This can allow loading into the reservoir array without disturbing atoms in the science region while the reservoir region is being loaded. For example, a disturbance may occur from unwanted scattering, unwanted light shifts, etc. during transfer. In some cases, a separate optical system from the trap excitation may be used to move atoms from a first array to a second array disclosed herein. For example, the reservoir array may be loaded from a separate optical potential or array, which may disturb atoms in the science region if the reservoir and science arrays were too close. Using separate optical systems to generate the two arrays may be helpful for separating the science array and the reservoir array arrays. Using a separate (e.g., a third) optical system, for atom movement may further insulate the arrays.

In some cases, the reservoir and science regions may be separated either parallel or transverse to the axis along which imaging is performed. If the separation is parallel to the imaging axis, atoms may be transferred from reservoir to science region by means of translating the focus of focused trapping lasers, or by shifting the phase of a trapping optical lattice. In some cases, the transfer of the at least one atom that is from the reservoir array into the science array is a long-range transfer. The systems, the methods, the computer-readable media, and the techniques disclosed herein may be combined with approaches for long range transport, such as those described in International Applications PCT/US2023/026595 and PCT/US2023/075948, which are incorporated herein in their entirety.

Electronic separation of the science array and the reservoir array may be useful in at least some respects for example. In some examples, the reservoir and science regions are distinguished by the internal or motional state occupied by the atoms (perhaps instead of being spatially separated). In some examples, the traps may be formed with spatially or temporally incoherent or coherent light, or by non-optical electromagnetic fields.

In some cases, coherence may be protected by applying a “hiding” excitations during or partially during atom reloading into the science array. A hiding excitation may comprise placing an atom being transferred or an atom already in an array into a dark state, a clock state, or another state forbidden by selection rules from an optical excitation used for the transferring. In some examples, hiding excitations may be applied to atoms in the science array during imaging or excitation of atoms to be moved into the science portion of the array. In some cases, the at least one atom that is transferred from the reservoir array into the science array is in a dark state. In some cases, an atom that is transferred from the reservoir array into the science array is in a dark state, a clock state, or another state forbidden by selection rules from an optical excitation used for the transferring. The systems, the methods, the computer-readable media, and the techniques disclosed herein may be combined with approaches for state selective movement, such as, as described in International Application PCT/US2023/075948 which is incorporated herein in its entirety.

### Examples of Methods and Systems for Alignment of Modules

Trapping arrays of atoms using laser beams may have various applications in the field of atomic physics. However, increasing the size of these arrays may be accompanied by more laser power or multiplying effective laser power with an optical cavity. Some optical cavities comprise two mirrors facing one another, e.g., a linear cavity, a folded cavity, a bowtie cavity, etc., while others may comprise a plurality of mirrors arranged to direct a beam in closed loop, e.g., a ring cavity. Optical cavities may allow a power to build up over multiple reflection within the cavity.

Optical cavities may be sensitive to alignment. For example, if a mirror is mispositioned, subsequent passes of the beam may not traverse the same optical path leading to leakage, divergence, and loss of amplification. In some cases, the beam directing elements may be fixed during manufacturing. While fixing beam directing elements decreases likelihood that an aligned optical cavity will fall out of alignment, it may be important to align the cavity optics precisely before fixing the optical elements in place.

In some cases, a spacer may hold several optical elements, e.g., mirrors, prisms, etc., in about the correct position and orientation. During manufacturing, they may be aligned before being affixed to the spacer. In the case of an optical cavity where the optical axis has a point of intersection, the optical alignment may create an overlap of multiple laser beams or optical passes of the same laser beam (either from multiple cavities or inside a single cavity). In the case of trapped array of atoms, micrometer precision or better may be advantageous. It may be advantageous to 1) measure the relative positions between beams with a high degree of precision, and to 2) adjust mirror positions to compensate for imperfect overlap.

The systems, the methods, the computer-readable media, and the techniques disclosed herein may be directed to measuring the relative positions between beams with a high degree of precision. This may allow for adjustment of mirror positions to compensate for imperfect overlap. The systems, the methods, the computer-readable media, and the techniques disclosed herein may improve upon existing methods for cavity alignment in at least some cases. Methods of alignment that involve moving an obstruction may lack adequate precision or may not be scalable to multiple beams.

For example, moving slit methods can be used to align two cavity beams. In a moving slit alignment, a slit may be placed around the beams, and transmission of each cavity through the slit as the slit is moved up and down may be monitored. When the slit moves too far to either side it clips and finally completely blocks the cavity beam. When the transmission is maximized, the slit is exactly centered on the cavity beam, and if this maximum occurs at the same slit position for both cavity beams, then the beams are aligned in the direction of slit movement.

This measurement may be relatively simple for two beams, because as long as they lie in a single plane, two beams are guaranteed to intersect. However, it is difficult to extend this method to more than two beams (which do not necessarily have a single intersection point), multiple beams inside a single cavity (where the obstruction can unintentionally clip multiple beams at once), or beam arrangements that do not lie in a single plane. Also, it is slow to mechanically move a slit while monitoring transmission, and additionally clipping the modes can change their shape, altering the measurement. Some of these problems can be addressed by replacing the moving slit with a fine tip, see for example Cai (incorporated by reference above), but it remains difficult to infer the exact 3D geometry of the beams from the response of the cavity transmission to a moving obstruction.

The systems, the methods, the computer-readable media, and the techniques disclosed herein may use direct imaging of Rayleigh scattering from the beams onto one or more cameras. In some cases, the position of intracavity laser beams can be directly measured by imaging Rayleigh scattering from the beams onto one or more cameras. A beam propagating through air scatters a small amount of light outside the beam path, which can be collected by a standard imaging system. The amount of scattered light is relatively small, but it may be multiplied by the power buildup factor of an optical cavity, accordingly the method may be suitable for cavities.

In some cases, a cavity of the present disclosure may be used in combination with a frequency stabilized (alternatively, a wavelength stabilized) laser. A frequency stabilized laser may in some cases also be phase stabilized; however, some frequency stabilized lasers may not be phase stabilized. In some cases, a frequency stabilized laser may be an optical clock. In an optical clock, the frequency stability may be less than sub-Hertz. In some cases, a laser may be actively frequency stabilize. In some cases, a laser may be passively frequency stabilized.

In some cases, a frequency-stabilized laser may be resonant with a cavity of the present disclosure.

In some cases, a camera is used in combination with the cavity to monitor the Rayleigh scattered light. In some cases, a single camera may measure the projection of all beams onto a 2D plane. In some examples, imaging from at least one other angle allows extraction of the beam paths in 3D space. The combination of the two cameras may provide complete information about the cavity beams. This method may be nonintrusive. The method may not involve blocking any of the beams. In some cases, all beams can be measured simultaneously, in 3D space, within a single image exposure time.

### Cavity Spacers

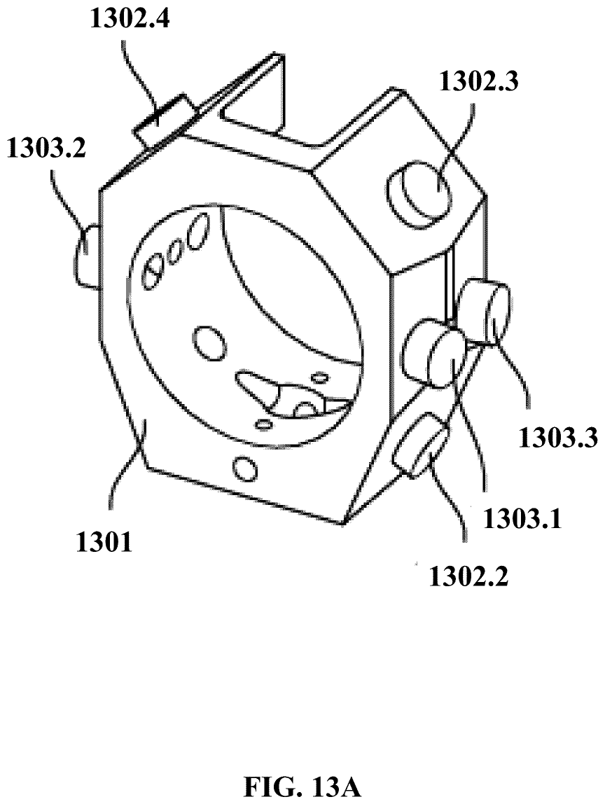

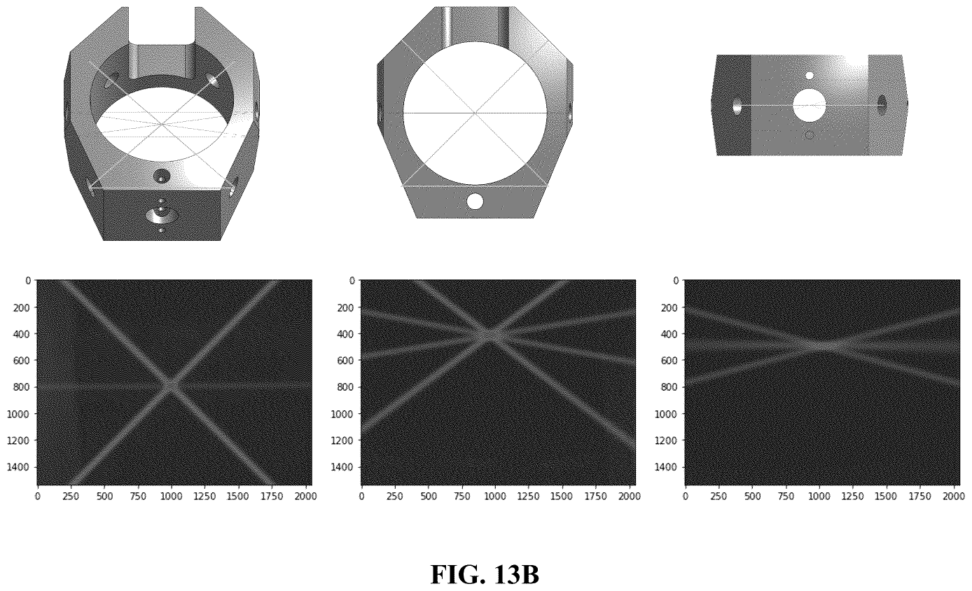

FIG. 13A shows different views of a plurality of mirrors to provide a plurality of optical cavities, according to some embodiments. The plurality of mirrors may be contained or held in place within a cavity spacer 1301. The cavity spacer 1301 may be constructed such that the plurality of mirrors may be oriented in one operable configuration. The cavity spacer 1301 may be constructed such that the plurality of mirrors may be oriented in at least two or more operable configurations. In some cases, the plurality of mirrors may comprise fold end mirrors 1302.1 and 1302.2 and two end mirrors 1302.3 and 1302.4 of a standing wave cavity. A plurality of mirrors 1303.1 and 1303.2 may be in an operable configuration to enable the generation of a three optical trap interaction propagating within the standing wave cavity and light propagating within the running wave cavity at interaction that may lie at the center of the cavity or cavity spacer.

In some examples, FIG. 13A shows different views of a plurality of mirrors configured to provide a plurality of optical cavities, according to some embodiments. A cavity spacer 1301 may be configured to hold a plurality of mirrors 1302.1-1302.4 and 1303.1-1303.3. The cavity spacer can be a low thermal expansion glass, thereby maintaining the configuration of the mirrors. The mirrors 1302.1-1302.4 can be configured to provide a first standing wave pattern (e.g., the mirrors can be configured to form a cavity configured to form a first standing wave pattern). The mirrors 1303.1-1303.3 can be configured to provide a second standing wave pattern. While not shown, there may be a fourth mirror of the mirrors 1303.1-1303.3 that is opposite the mirror 1303.3. The combination of the mirrors 1302.1-1302.4 and 1303.1-1303.3 can provide a plurality of optical traps as described elsewhere herein.

FIG. 13A show different views of a plurality of mirrors to provide a plurality of optical cavities, according to some embodiments. Any mirror among a plurality of mirrors may independently comprise an optical substrate. Any mirror among a plurality of mirrors may independently comprise an optical substrate and a coating. Optical substrates may include but are not limited to α-BBO, barium fluoride, calcite, calcium fluoride, F2, germanium, magnesium fluoride, N-BK7, N-F2, N-SF11, potassium bromide, PTFE, rutile, sapphire, silicon, UV fused silica, YVO₄, ZERODUR®, zinc selenide, or any combination thereof. Optical substrates may comprise a crystalline component. Optical substrates may comprise an amorphous component. Optical coatings may include but are not limited to glass (e.g., glass with a dielectric coating), silver, aluminum, gold, nickel, anti-reflective coatings, dielectric coatings, highly reflective coatings and any combination thereof. Optical coatings may comprise a crystalline component. Optical coatings may comprise an amorphous component. The selection of optical substrate and optical coating may consider the wavelength of light to be utilized. The selection of optical substrate and optical coating may consider the operating temperature or operating pressure of a mirror or optical cavity that they may comprise. An optical substrate may be selected for having a low coefficient of thermal expansion. An optical coating may be selected for having a low coefficient of thermal expansion.

In some cases, FIG. 13A show different views of a plurality of mirrors to provide a plurality of optical cavities, according to some embodiments. The plurality of mirrors may be contained or held in place within a cavity spacer 1301. The cavity spacer 1301 may comprise a single piece of material. The cavity spacer 1301 may comprise two or more pieces of material. The material used to construct the cavity spacer 1301 may include but is not limited to glass, borosilicate glass, ultra low expansion glass, silicon, germanium, ZERODUR®, silicon carbide, silicon nitride, diamond, or any combination thereof. The selection of a material to construct a cavity spacer 1301 may consider the operating temperature or operating pressure of a device that the cavity spacer may comprise. A material to construct a cavity spacer 1301 may be selected for having a low coefficient of thermal expansion.

The physical size of the cavity spacer 1301 may be on the order of millimeters, in some examples. For example, the footprint of the cavity spacer 1301 may be approximated as about a 10 mm cube, about a 20 mm cube, about a 30 mm cube, about a 40 mm cube, about a 50 mm cube, about a 60 mm cube, about a 70 mm cube, about an 80 mm cube, about a 90 mm cube, about a 100 mm cube, etc. For example, the cavity spacer 1301 may be about 65×58×30 mm (thickness). The mirrors 1302.1-1302.4 and 1303.1-1303.3 may also be on the order of millimeters, in some examples. For example, the mirrors 1302.1-1302.4 and 1303.1-1303.3 may be about 4 mm thick with about 10 mm diameter. The mirrors 1302.1-1302.4 and 1303.1-1303.3 may be optically bonded on the outer surface of the cavity spacer 1301, such that the overall cavity profile becomes larger in the transverse plane. In some examples, the exact dimensions of the cavity spacer 1301 or the mirrors 1302.1-1302.4 and 1303.1-1303.3 may be dictated by other apparatuses, such as the size of the vacuum chamber in which the cavity spacer 1301 is installed. In some examples, once the cavity lengths have been designed (e.g., based on the available space), the cavity spacer 1301 dimensions may be designed and implemented to be quite accurate, e.g., including both the surface-normal and the angular tolerances of the surfaces, since light bounces off these mirrors and the slightest offset can deflect the light elsewhere. In some cases, machining tolerance for the surface-normals may be a few microns and 20 arcseconds for more stringent angular tolerances. In some examples, flatness for the mirrors 1302.1-1302.4 and 1303.1-1303.3 may be specified to λ/10. In some examples, surface quality of the mirrors may be specified to a couple angstroms.

### Cavity Alignment

FIG. 13B shows an example of a complicated set of cavities to be aligned. In the illustrated example, there are two cavities, each with multiple beams, where 4 beams lie in two planes and intersect at a single point. As shown, where two cavities, each containing two beams intersecting in an X, each in a different plane, are to be aligned at a single point.

FIG. 13B additionally shows modeled views from three different camera angles, as well as actual images of Rayleigh scattered light taken from each view. The combination of views may provide full information about the alignment. As shown in the top images, three modeled views of the modes of the cavity are shown. The bottom three images show measured Rayleigh scattering from these three views, clearly showing all laser beams, allowing full knowledge of the beam positions in 3D space.

In some cases, a single intersection point is of interest. If a single intersection point is of interest, the camera depth of may not be limiting. However, if multiple points of intersection are of interest, the camera depth of focused can be varied by changing the aperture of the camera. If there is a blur from limited resolution of the camera the systematic blur pattern can be fit to extract the beam center position.

The angles into which light is Rayleigh scattered may be affected by polarization of the light. Accordingly, some camera angles may see little light for certain polarizations. In some cases, both polarization states of the laser are coupled into the cavity sequentially.

Often optical cavities are placed into vacuum, where there is no Rayleigh scattering. In some cases, the alignment of the mirrors can be fixed during construction in air by epoxy, optical contacting, hydroxide catalysis bonding, or similar methods using alignment in air, and the alignment may be maintained after the air is evacuated.

The procedure disclosed herein may be used in combination with line-fitting algorithms to extract beam positions. For example, images of the beams in the camera may be fit to a line and a line may be superimposed on the image. In some cases, the array of lines may be used to direct the alignment of the cavity optics. Similarly, a line-fitting algorithm may be used to measure an overlap between free-space beams. This may include folded beams that are reflected back to intersect with themselves.

In some cases, cavity mirrors may be manufactured to reflect strongly at a short “alignment wavelength,” in addition to the wavelengths of interest for other applications. Because short wavelengths have stronger Rayleigh scattering, an alignment wavelength may be useful.

In some cases, the magnifications and apertures of the cameras may be chosen to improve signal-to-noise, depth of field, and resolution.

In some cases, higher-order spatial modes of the cavity may be imaged to optimize focus, by examining the fine structure of these modes.

In some cases, a depth of field of a camera may be intentionally limited to extract 3D information from a single image, using the blur from out-of-focus points.

In some cases, a telecentric lens may be used to eliminate perspective error in images.

In some cases, the images may be used to extract other properties of the beam such as beam size and intensity, which reflect properties of the cavity mode and build-up factor.

These techniques may be used to align optical cavities for purposes besides trapping atoms, such as laser interferometers, ring-laser gyroscopes, and enhancement cavities for nonlinear optics. In some cases, trapping atoms may be useful for generating a neutral atom quantum computer or other non-classical computation.

### Examples of Computer Systems

FIG. 1 shows a computer system 101 that is programmed or otherwise configured to operate any method or system described herein (such as systems, methods, computer-readable media, or techniques for non-classical computing, disclosed herein). The computer system 101 may regulate the systems, the methods, the computer-readable media, and the techniques disclosed herein. The computer system 101 can be an electronic device of a user or a computer system that is remotely located with respect to the electronic device. The electronic device can be a mobile electronic device.

The computer system 101 includes a central processing unit (CPU, also “processor” and “computer processor” herein) 105, which can be a single core or multi core processor, or a plurality of processors for parallel processing. The computer system 101 also includes memory or memory location 110 (e.g., random-access memory, read-only memory, flash memory), electronic storage unit 115 (e.g., hard disk), communication interface 120 (e.g., network adapter) for communicating with one or more other systems, and peripheral devices 125, such as cache, other memory, data storage or electronic display adapters. The memory 110, storage unit 115, interface 120 and peripheral devices 125 are in communication with the CPU 105 through a communication bus (solid lines), such as a motherboard. The storage unit 115 can be a data storage unit (or data repository) for storing data. The computer system 101 can be operatively coupled to a computer network (“network”) 130 with the aid of the communication interface 120. The network 130 can be the Internet, an internet or extranet, or an intranet or extranet that is in communication with the Internet. The network 130 in some cases is a telecommunication or data network. The network 130 can include one or more computer servers, which can enable distributed computing, such as cloud computing. The network 130, in some cases with the aid of the computer system 101, can implement a peer-to-peer network, which may enable devices coupled to the computer system 101 to behave as a client or a server.

The CPU 105 can execute a sequence of machine-readable instructions, which can be embodied in a program or software. The instructions may be stored in a memory location, such as the memory 110. The instructions can be directed to the CPU 105, which can subsequently program or otherwise configure the CPU 105 to implement methods of the present disclosure. Examples of operations performed by the CPU 105 can include fetch, decode, execute, and writeback.

The CPU 105 can be part of a circuit, such as an integrated circuit. One or more other components of the system 101 can be included in the circuit. In some cases, the circuit is an application specific integrated circuit (ASIC).

The storage unit 115 can store files, such as drivers, libraries and saved programs. The storage unit 115 can store user data, e.g., user preferences and user programs. The computer system 101 in some cases can include one or more additional data storage units that are external to the computer system 101, such as located on a remote server that is in communication with the computer system 101 through an intranet or the Internet.

The computer system 101 can communicate with one or more remote computer systems through the network 130. For instance, the computer system 101 can communicate with a remote computer system of a user. Examples of remote computer systems include personal computers (e.g., portable PC), slate or tablet PC's (e.g., Apple® iPad, Samsung® Galaxy Tab), telephones, Smart phones (e.g., Apple® iphone, Android-enabled device, Blackberry®), or personal digital assistants. The user can access the computer system 101 via the network 130.

Methods as described herein can be implemented by way of machine (e.g., computer processor) executable code stored on an electronic storage location of the computer system 101, such as, for example, on the memory 110 or electronic storage unit 115. The machine executable or machine-readable code can be provided in the form of software. During use, the code can be executed by the processor 105. In some cases, the code can be retrieved from the storage unit 115 and stored on the memory 110 for ready access by the processor 105. In some situations, the electronic storage unit 115 can be precluded, and machine-executable instructions are stored on memory 110.

The code can be pre-compiled and configured for use with a machine having a processor adapted to execute the code or can be compiled during runtime. The code can be supplied in a programming language that can be selected to enable the code to execute in a pre-compiled or as-compiled fashion.

In some cases, the systems, the methods, the computer-readable media, and the techniques disclosed herein, such as the computer system 101, can be embodied in programming. In some cases, the systems, the methods, the computer-readable media, and the techniques disclosed herein may be thought of as “products” or “articles of manufacture” typically in the form of machine (or processor) executable code or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code or data. Many of these forms of computer readable media may be involved in carrying one or more sequences of one or more instructions to a processor for execution.

The computer system 101 can include or be in communication with an electronic display 135 that comprises a user interface (UI) 140. Examples of UI's include, without limitation, a graphical user interface (GUI) and web-based user interface.

The systems, the methods, the computer-readable media, and the techniques disclosed herein can be implemented by way of one or more algorithms. An algorithm can be implemented by way of software upon execution by the central processing unit 105. The algorithm can, for example, implement methods for performing a non-classical computation described herein.

### Certain Definitions and Additional Considerations

As used in this specification and the appended claims, the singular forms “a,” “an,” and “the” include plural references unless the context clearly dictates otherwise. Any reference to “or” herein is intended to encompass “and/or” unless otherwise stated.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” “less than or equal to,” or “at most” precedes the first numerical value in a series of two or more numerical values, the term “no more than,” “less than,” “less than or equal to,” or “at most” applies to each of the numerical values in that series of numerical values. For example, less than or equal to 3, 2, or 1 is equivalent to less than or equal to 3, less than or equal to 2, or less than or equal to 1.

Where values are described as ranges, it will be understood that such disclosure includes the disclosure of all possible sub-ranges within such ranges, as well as specific numerical values that fall within such ranges irrespective of whether a specific numerical value or specific sub-range is expressly stated.

As used herein, like characters refer to like elements.

As used herein, the terms “non-classical computation,” “non-classical procedure,” “non-classical operation,” any “non-classical computer” generally refer to any method or system for performing computational procedures outside of the paradigm of classical computing. A non-classical computation, non-classical procedure, non-classical operation, or non-classical computer may comprise a quantum computation, quantum procedure, quantum operation, or quantum computer.

As used herein, the terms “quantum computation,” “quantum procedure,” “quantum operation,” and “quantum computer” generally refer to any method or system for performing computations using quantum mechanical operations (such as unitary transformations or completely positive trace-preserving (CPTP) maps on quantum channels) on a Hilbert space represented by a quantum device. As such, quantum and classical (or digital) computation may be similar in the following aspects: both computations may comprise sequences of instructions performed on input information to then provide an output. Various paradigms of quantum computation may break the quantum operations down into sequences of basic quantum operations that affect a subset of qubits of the quantum device simultaneously. The quantum operations may be selected based on, for instance, their locality or their ease of physical implementation. A quantum procedure or computation may then consist of a sequence of such instructions that in various applications may represent different quantum evolutions on the quantum device. For example, procedures to compute or simulate quantum chemistry may represent the quantum states and the annihilation and creation operators of electron spin-orbitals by using qubits (such as two-level quantum systems) and a universal quantum gate set (such as the Hadamard, controlled-not (CNOT), and rotations) through the so-called Jordan-Wigner transformation or Bravyi-Kitaev transformation.

Additional examples of quantum procedures or computations may include procedures for optimization such as quantum approximate optimization algorithm (QAOA) or quantum minimum finding. QAOA may comprise performing rotations of single qubits and entangling gates of multiple qubits. In quantum adiabatic computation, the instructions may carry stochastic or non-stochastic paths of evolution of an initial quantum system to a final one.

Quantum-inspired procedures may include simulated annealing, parallel tempering, master equation solver, Monte Carlo procedures and the like. Quantum-classical or hybrid algorithms or procedures may comprise such procedures as variational quantum eigensolver (VQE) and the variational and adiabatically navigated quantum eigensolver (VanQver).

A quantum computer may comprise one or more adiabatic quantum computers, quantum gate arrays, one-way quantum computers, topological quantum computers, quantum Turing machines, quantum annealers, Ising solvers, or gate models of quantum computing.

As used herein, the term “adiabatic” refers to any process performed on a quantum mechanical system in which the parameters of the Hamiltonian are changed slowly in comparison to the natural timescale of evolution of the system.

As used herein, the term “non-adiabatic” refers to any process performed quantum mechanical system in which the parameters of the Hamiltonian are changed quickly in comparison to the natural timescale of evolution of the system or on a similar timescale as the natural timescale of evolution of the system.

While preferred embodiments of the present disclosure have been shown and described herein, it will be obvious to those skilled in the art that such embodiments are provided by way of example only. Numerous variations, changes, and substitutions will now occur to those skilled in the art without departing from the disclosure. It should be understood that various alternatives to the embodiments of the disclosure described herein may be employed in practicing the disclosure. It is intended that the following claims define the scope of the disclosure and that methods and structures within the scope of these claims and their equivalents be covered thereby.

1.-105. (canceled)

106. A system comprising:
a first array of optical cavities comprising a first atom;
a second array of optical cavities comprising a second atom; and
an optical assembly in optical communication with the first array of optical cavities comprising the first atom and the second array of optical cavities comprising the second atom and arranged to form an entangled state between a first cavity of the first array of optical cavities comprising the first atom and a second cavity of the second array of optical cavities comprising the second atom.

107. The system of claim 106, wherein the optical assembly comprises a plurality of prisms or a plurality of mirrors.

108. The system of claim 106, wherein the optical assembly comprises one or more of a corner cube, a cat's eye retroreflector, a porro prism, a pentaprism, a right angle prism, a roof pentaprism, an amici prism, or a beam splitter cube.

109. The system of claim 106, wherein the entangled state is formed via pitch-and-catch entanglement.

110. The system of claim 109, wherein the entangled state is formed by coupling a first output of the first cavity to a second output of the second cavity.

111. The system of claim 110, wherein the optical assembly comprises a prism and the prism has a 180 degree deviation.

112. The system of claim 111, wherein the prism is a single porro prism, a corner cube or cat's eye retroreflector, or a pentaprism and a right-angle prism.

113. The system of claim 110, wherein the optical assembly comprises a mirror or a plurality of mirrors.

114. The system of claim 113, wherein the mirror or the plurality of mirrors has a 180 degree deviation.

115. The system of claim 110, wherein the optical assembly comprises a fiber optic or a plurality of fiber optics configured to direct the first output into the second output.

116. The system of claim 110, wherein the first array of optical cavities and the second array of optical cavities are not parallel and the optical assembly is aligned to directly couple the first array of optical cavities to the second array of optical cavities.

117. The system of claim 106, wherein the entangled state is formed via coincident photon detection entanglement.

118. The system of claim 117, wherein the entangled state is formed by interfering a first output of the first cavity with a second output of the second cavity and directing the subsequently generated beams onto two photodetectors.

119. The system of claim 118, wherein the optical assembly comprises a prism and a beam splitter and the prism has a 90 degree deviation.

120. The system of claim 119, wherein the prism comprises a roof pentaprism; an amici prism; a pentaprism; or a right-angle prism.

121. The system of claim 118, wherein the optical assembly is a mirror or a plurality of mirrors and a beam splitter.

122. The system of claim 121, wherein the mirror or the plurality of mirrors has a 90 degree deviation.

123. The system of claim 118, wherein the optical assembly comprises a fiber optic or a plurality of fiber optics configured to interfere the first output with the second output.

124. The system of claim 106, wherein the first array of optical cavities and the second array of optical cavities are not parallel and the optical assembly is aligned to interfere a first output of the first array of optical cavities and a second output of the second array of optical cavities.

125. The system of claim 106, wherein the entanglement between the first cavity and the second cavity comprises pairwise entanglement between the first array of optical cavities and the second array of optical cavities.

126. The system of claim 106, wherein the first array of optical cavities, the second array of optical cavities, or both is coupled to an optic fiber or fiber bundle and transported over a distance.

127. The system of claim 106, wherein the first array of optical cavities and the second array of optical cavities are in separate vacuum chambers or are in separate quantum computers.

128. The system of claim 106, wherein the first atom and the second atom are qubits.

129. The system of claim 106, further comprising an array of spatially distinct optical trapping sites, wherein a first optical trapping site of the array of optical trapping sites comprises the first atom, and wherein a second optical trapping site of the array of optical trapping sites comprises the second atom.

130. The system of claim 129, wherein the first cavity comprises a first longitudinal mode, wherein the first longitudinal mode, when excited, forms the first optical trapping site of the array of optical trapping sites.

131. The system of claim 129, wherein the first optical trapping site and the second optical trapping site are located at a focal plane of the first array of optical cavities or the second array of optical cavities.

132. The system of claim 129, wherein a fluorescence emitted by at least one atom trapped in an optical trapping site of the array of optical trapping sites is transmitted through an output optical element of the first array of optical cavities or the second array of optical cavities.

133. The system of claim 106, wherein the optical assembly is arranged to form in parallel a plurality of entangled states in a plurality of atoms between the first array of optical cavities and the second array of optical cavities.
